(19) United States
(12) Patent Application Publication
(10) Pub. No.: US 2014/0035115 A1
(43) Pub. Date: Feb. 6, 2014

(54) SEMICONDUCTOR DEVICE

(71) Applicant: SUMITOMO BAKELITE CO., LTD., Tokyo (JP)

(72) Inventors: Shin-ichi ZENBUTSU, Tokyo (JP); Shingo ITOH, Tokyo (JP)

(73) Assignee: SUMITOMO BAKELITE CO., LTD., Tokyo (JP)

(21) Appl. No.: 14/043,877

(22) Filed: Oct. 2, 2013

Related U.S. Application Data
(62) Division of application No. 12/999,062, filed on Dec. 15, 2010.

(30) Foreign Application Priority Data
Oct. 10, 2008 (JP) 2008-263917
Jan. 9, 2009 (JP) 2009-003694
Jan. 9, 2009 (JP) 2009-003700

(51) Int. Cl. H01L 23/495

(52) U.S. Cl. CPC H01L 23/495
USPC 257/676

(57) ABSTRACT

A semiconductor device includes any one of a lead frame having a die pad portion and a circuit board, one or more semiconductor elements, a copper wire, an encapsulating member. The one or more semiconductor elements are mounted on any one of the die pad portion of the lead frame and the circuit board. The copper wire electrically connects electrical joints provided on any one of the lead frame and the circuit board to an electrode pad provided on the semiconductor element. The encapsulating member encapsulates the semiconductor element and the copper wire. The electrode pad provided on the semiconductor element is formed from palladium. The copper wire has a copper purity of 99.99% by mass or more and an elemental sulfur content of 5 ppm by mass or less.

### CROSS-REFERENCE TO RELATED APPLICATIONS

The present application is a divisional application of the U.S. patent application Ser. No. 12/999,062, filed Dec. 15, 2010, which in turn is a national stage application of International Application No. PCT/JP2009/067396, filed Oct. 6, 2009, which claims priority to Japanese Patent Application No. 2008-263917, filed on Oct. 10, 2008, to Japanese Patent Application No. 2009-003694, filed on Jan. 9, 2009, and to Japanese Patent Application No. 2009-003700, filed on Jan. 9, 2009. The contents of these applications are incorporated herein by reference in their entirety.

### BACKGROUND OF THE INVENTION

1. Field of the Invention

The present invention relates to a semiconductor device, and more particularly to a semiconductor device comprising a lead frame or a circuit board, a semiconductor element mounted on the lead frame or the circuit board, a copper wire that electrically connects electrical joints provided on the lead frame or the circuit board to an electrode pad provided on the semiconductor element, and an encapsulating member which encapsulates the semiconductor element and the copper wire.

2. Discussion of the Background

Conventionally, electronic parts such as diodes, transistors, and integrated circuits are largely encapsulated by a cured product of an epoxy resin composition. Especially for the integrated circuits, epoxy resin compositions with excellent thermal and moisture resistance are used, the epoxy resin compositions containing epoxy resins, phenol resin-based curing agents, and inorganic fillers such as fused silica and crystalline silica. In recent years, however, in the market trends of downsizing, reducing the weight of, and sophisticating electronic equipment, higher integration of semiconductor elements is increasing every year and surface mounting of semiconductor devices is facilitated, and thus the requirements on the epoxy resin compositions used for encapsulation of semiconductor elements are becoming stricter. Furthermore, because the demand for cost reduction on semiconductor devices is also strict and the cost of the conventional gold wire connection is high, joining with use of metals such as aluminum, a copper alloy, and copper is employed in part.

For example, in a semiconductor device comprising a lead frame having a die pad portion or a circuit board and at least one semiconductor element mounted on the die pad portion of the lead frame or on the circuit board, electrical joints such as wire bonding portions of the lead frame and electrode pads of the circuit board are electrically joined with the electrode pads of the semiconductor element by bonding wires. Conventionally, for those bonding wires, expensive gold wires have often been used, but in recent years, cost reduction on semiconductor devices has been strongly demanded, and an aluminum wire, a copper wire, and a copper alloy wire and the like are proposed as cheap bonding wires to replace the gold wires (for example, in Japanese Unexamined Patent Application Publication No. 2007-12776 and Japanese Unexamined Patent Application Publication No. 2008-85319).

However, the semiconductor devices using such bonding wires made of metals other than gold are still insufficient in the high temperature storage life and high temperature operating life under the high temperature environment having a temperature exceeding 150° C., which are especially demanded in the automotive applications, and electric reliability such as the moisture resistance reliability under the high temperature and high humidity environment having a temperature exceeding 60° C. and a relative humidity exceeding 60% RH. Accordingly, there are problems such as migration, corrosion, and rise in electrical resistance, and thus satisfactory devices have not always been obtained.

Especially, in the semiconductor devices using copper wires, there is a problem that copper is easy to corrode in a moisture resistance reliability test and thus lacks in reliability. Therefore, although copper wires have been successfully used as wires with a large wire diameter for discrete power devices and the like, it is currently difficult to employ copper wires for ICs requiring wires with a wire diameter of 25 μm or less, especially for single-sided encapsulated packages whose wires are even affected by impurities attributable to a circuit board.

Thus, Japanese Examined Patent Application Publication No. Hei 06-017554 proposes an approach to improve the workability of copper wires themselves to increase the reliability of joints, and Japanese Unexamined Patent Application Publication No. 2007-12776 described above proposes an approach to increase the joint reliability by coating each of the copper wires with conductive metal to prevent oxidation. Although there have been proposals focusing on only the copper wire as described above, corrosion and electric reliability such as moisture resistance reliability of a package encapsulated by a resin, i.e., a semiconductor device are not accounted for, and thus the proposals have not necessarily been satisfactory.

On the other hand, with downsizing, weight reduction and sophistication of electronic equipment, miniaturization of semiconductor elements and decrease in pitch of wires are advancing. Such decrease in pitch of wires has had a problem that large capacitance is formed between the wires, which causes propagation delay of signals. Therefore, proposed has been a semiconductor device using a low dielectric insulating film as the interlayer insulating film to suppress the formation of such capacitance between the wires.

However, there has been a problem that the low dielectric insulating film generally has low mechanical strength, and in a conventional semiconductor device, cracking occurs in the low dielectric insulating film under the electrode pads provided on the semiconductor element due to impact during wire bonding, and thus they are less durable, especially under high temperature and high humidity. Accordingly, various methods have been considered to solve such a problem.

For example, Japanese Unexamined Patent Application Publication No. 2005-79432, discloses an electrode pad including an electrode placed on an interlayer insulating film and an external terminal placed on the electrode, wherein a low dielectric film layer is buried in the electrode, the low dielectric film layer causing the impact applied during wire bonding of the electrode to be dispersed, and thus preventing cracking from occurring in the interlayer insulating film under the electrode pad. Moreover, Japanese Patent Application Publication No. 2005-142553 discloses a semiconductor device including an electrode pad, a semiconductor substrate, and a multi-layer wiring formed between the electrode pad and the semiconductor substrate, the wiring layers being insulated from each other with a low dielectric insulation film, wherein a dummy wiring is formed around the electrode pad to prevent cracking from occurring in the low dielectric insulation film during wire bonding.

Also, it is known that provision of a thick electrode pad on a semiconductor element prevents the impact during wire bonding from propagating on a low dielectric insulation film. However, in the conventional semiconductor devices using copper wires, since greater thickness of an electrode pad of a semiconductor element tends to lead to degradation of the high temperature storage life, high temperature operating life, and moisture resistance reliability, the semiconductor element has generally been provided with an electrode pad having a thickness of less than 1.2 μm.

### SUMMARY OF THE INVENTION

The present invention has been made in view of the foregoing problems in the conventional arts. An object of the present invention is to provide a semiconductor device excellent in high temperature storage life, high temperature operating life, moisture resistance reliability, and the like, the semiconductor device comprising a lead frame or a circuit board, a semiconductor element, and an encapsulating member, wherein electrical joints provided on the lead frame or the circuit board and an electrode pad provided on the semiconductor element are connected by a copper wire.

The present inventors have made earnest study to achieve the above-described object. As a result, the present inventors have found the following. In a semiconductor device comprising a lead frame having a die pad portion or a circuit board, one or more semiconductor elements mounted on the die pad portion of the lead frame or on the circuit board, and an encapsulating member, when electrical joints provided on the lead frame or the circuit board and an electrode pad provided on the semiconductor element are electrically connected by a copper wire having a wire diameter of 25 μm or less, use of wires having, on a surface thereof, a coating layer formed from a metal material containing palladium as the copper wire and use of a cured product of a predetermined epoxy resin composition as the encapsulating member allow to provide a semiconductor device whose copper wire is difficult to corrode and whose solder resistance, high temperature storage life, high temperature operating life, migration resistance, and moisture resistance reliability are better balanced. This finding has led the present inventors to complete the present invention.

Specifically, a first semiconductor device of the present invention is a semiconductor device comprising any one of a lead frame having a die pad portion and a circuit board, one or more semiconductor elements mounted on any one of the die pad portion of the lead frame and the circuit board, a copper wire that electrically connects electrical joints provided on any one of the lead frame and the circuit board to an electrode pad provided on the semiconductor element, and an encapsulating member which encapsulates the semiconductor element and the copper wire, wherein the copper wire has a wire diameter of 25 μm or less, the copper wire has, on a surface thereof, a coating layer formed from a metal material containing palladium, and the encapsulating member is formed from a cured product of an epoxy resin composition comprising (A) an epoxy resin, (B) a curing agent, (C) a filler, and (D) a compound containing a sulfur atom.

In such a first semiconductor device, a concentration of chlorine ion in an extraction water extracted from the cured product of the epoxy resin composition under conditions of 125° C., relative humidity 100% RH, and 20 hours is preferably 10 ppm or less. Furthermore, a core of the copper wire preferably has a copper purity of 99.99% by mass or more. Moreover, the coating layer preferably has a thickness of from 0.001 to 0.02 μm.

In the first semiconductor device of the present invention, the (D) compound containing a sulfur atom preferably has at least one atomic group selected from the group consisting of mercapto group and sulfide bond. The (D) compound containing a sulfur atom more preferably has at least one atomic group, which is excellent in affinity with an epoxy resin matrix, selected from the group consisting of amino group, hydroxyl group, carboxyl group, mercapto group, and nitrogen-containing heterocyclic rings; and at least one atomic group, which is excellent in affinity with a metal material containing palladium, selected from the group consisting of mercapto group and sulfide bond. The (D) compound containing a sulfur atom is further preferably at least one compound selected from the group consisting of triazole-based compounds, thiazoline-based compounds, and dithiane-based compounds. The (D) compound containing a sulfur atom especially preferably has a 1,2,4-triazole ring.

The compound having a 1,2,4-triazole ring is preferably represented by the following formula (1):

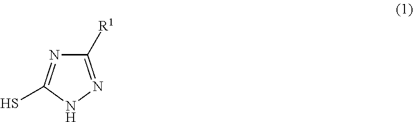

[in the formula (1), R¹ represents any one of a hydrogen atom, a mercapto group, an amino group, a hydroxy group, and a hydrocarbon group having any functional group of a mercapto group, an amino group, and a hydroxy group]. The dithiane compound is preferably represented by the following formula (2):

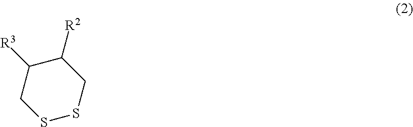

[in the formula (2), R² and R³ each independently represent any one of a hydrogen atom, a mercapto group, an amino group, a hydroxy group, and a hydrocarbon group having any functional group of a mercapto group, an amino group, and a hydroxy group].

In the first semiconductor device of the present invention, the (A) epoxy resin preferably comprises at least one epoxy resin selected from the group consisting of

epoxy resins represented by the following formula (3):

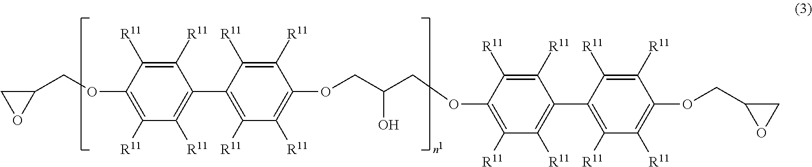

[in the formula (3), a plurality of R¹¹ each independently represent any one of a hydrogen atom and a hydrocarbon group having 1 to 4 carbon atoms, and an average value of n¹ is 0 or a positive number of 5 or less],

epoxy resins represented by the following formula (4):

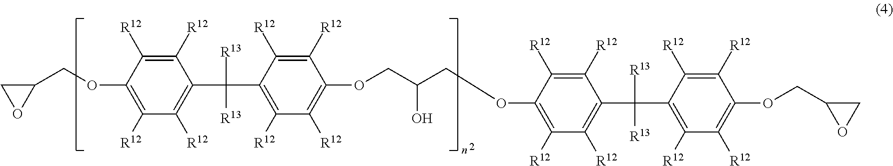

[in the formula (4), a plurality of R¹² and R¹³ each independently represent any one of a hydrogen atom and a hydrocarbon group having 1 to 4 carbon atoms, and an average value of n² is 0 or a positive number of 5 or less],

epoxy resins represented by the following formula (5):

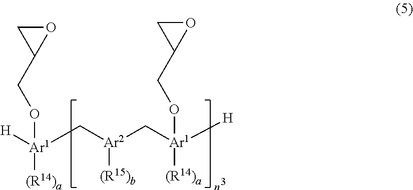

[in the formula (5), Ar¹ represents any one of a phenylene group and a naphthylene group, each binding position of the glycidyl ether groups may be any one of α-position and β-position when Ar¹ is the naphthylene group, Ar² represents any one of a phenylene group, a biphenylene group, and a naphthylene group, R¹⁴ and R¹⁵ each independently represent a hydrocarbon group having 1 to 10 carbon atoms, a is an integer of from 0 to 5, b is an integer of from 0 to 8, and an average value of n³ is a positive number between 1 and 3 both inclusive], and

epoxy resins represented by the following formula (6):

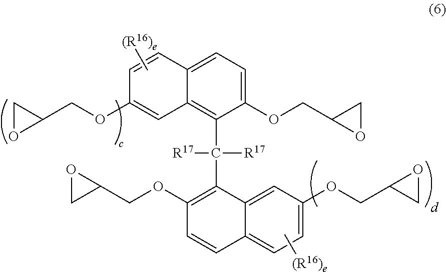

[in the formula (6), R¹⁶ represents any one of a hydrogen atom and a hydrocarbon group having 1 to 4 carbon atoms and may be the same or different when there are a plurality of R¹⁶, R¹⁷'s each independently represent any one of a hydrogen atom and a hydrocarbon group having 1 to 4 carbon atoms, c and d are each independently 0 or 1, and e is an integer of from 0 to 6].

In the first semiconductor device of the present invention, the (B) curing agent preferably comprises at least one curing agent selected from the group consisting of

novolac-type phenol resins, and

phenol resins represented by the following formula (7):

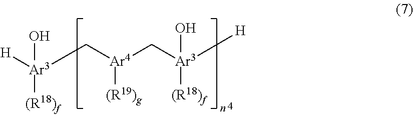

[in the formula (7), Ar³ represents any one of a phenylene group and a naphthylene group, each binding position of the hydroxyl groups may be any one of α-position and β-position when Ar³ is the naphthylene group, Ar⁴ represents any one of a phenylene group, a biphenylene group, and a naphthylene group, R¹⁸ and R¹⁹ each independently represent a hydrocarbon group having 1 to 10 carbon atoms, f is an integer of from 0 to 5, g is an integer of from 0 to 8, and an average value of n⁴ is a positive number between 1 and 3 both inclusive].

In the first semiconductor device of the present invention, the (C) filler preferably comprises a fused spherical silica whose mode diameter is between 30 μm and 50 μm both inclusive and whose content ratio of coarse particles having a diameter of 55 μm or more is 0.2% by mass or less.

Such a first semiconductor device of the present invention can be used for electronic parts which are required to reliably operate under a high temperature and high humidity environment having a temperature of 60° C. or more and a relative humidity of 60% or more, the electronic parts including electronic parts used in an automobile engine compartment, electronic parts around a power supply unit for a personal computer and a home electric appliance, electronic parts in a LAN device, and the like.

Further, the present inventors have found that the following. In a semiconductor device comprising a lead frame having a die pad portion or a circuit board, one or more semiconductor elements mounted on the die pad portion of the lead frame or on the circuit board, and an encapsulating member, use of an electrode pad formed from palladium as an electrode pad of the semiconductor element, and connection of this electrode pad with electrical joints provided on the lead frame or the circuit board by a copper wire having high purity and low elemental sulfur content allow to prevent the corrosion of a junction between the electrode pad of the semiconductor element and the copper wire, providing a semiconductor device excellent in high temperature storage life, high temperature operating life, and moisture resistance reliability. This finding has led the present inventors to complete the present invention.

Specifically, a second semiconductor device of the present invention is a semiconductor device comprising any one of a lead frame having a die pad portion and a circuit board, one or more semiconductor elements mounted on any one of the die pad portion of the lead frame and the circuit board, a copper wire that electrically connects electrical joints provided on any one of the lead frame and the circuit board to an electrode pad provided on the semiconductor element, and an encapsulating member which encapsulates the semiconductor element and the copper wire, wherein the electrode pad provided on the semiconductor element is formed from palladium, and the copper wire has a copper purity of 99.99% by mass or more and an elemental sulfur content of 5 ppm by mass or less.

In such a second semiconductor device, the encapsulating member is preferably a cured product of an epoxy resin composition. The epoxy resin composition preferably comprises at least one corrosion inhibitor selected from the group consisting of compounds containing an elemental calcium and compounds containing an elemental magnesium in a ratio of not less than 0.01% by mass and not more than 2% by mass. The epoxy resin composition more preferably comprises any one of calcium carbonate and hydrotalcite in a ratio of not less than 0.05% by mass and not more than 2% by mass.

In the second semiconductor device of the present invention, the calcium carbonate is preferably precipitated calcium carbonate synthesized by a carbon dioxide gas reaction method. The hydrotalcite is preferably a compound represented by the following formula (8):

M_{α}Al_{β}(OH)_{2α+β-2γ}(CO₃)_{γ}·δH₂O (8)

[in the formula (8), M represents a metallic element comprising at least Mg, α, β and γ are numbers meeting conditions of 2≦α≦8, 1≦β≦3, and 0.5≦γ≦2, respectively, and δ is an integer of 0 or more].
A mass loss ratio A (% by mass) at 250° C. and a mass loss ratio B (% by mass) at 200° C. of the hydrotalcite, which are measured by a thermogravimetric analysis, preferably meet a condition represented by the following formula (I):

A−B≦5% by mass (I)

In the second semiconductor device of the present invention, the epoxy resin composition preferably comprises at least one epoxy resin selected from the group consisting of

epoxy resins represented by the following formula (6):

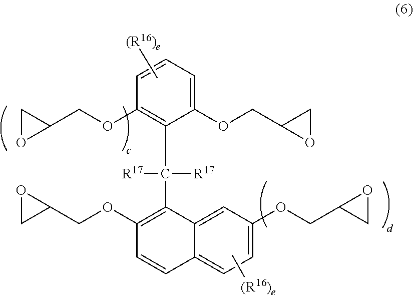

[in the formula (6), R¹⁶ represents any one of a hydrogen atom and a hydrocarbon group having 1 to 4 carbon atoms, and may be the same or different when there are a plurality of R¹⁶, R¹⁷'s each independently represent any one of a hydrogen atom and a hydrocarbon group having 1 to 4 carbon atoms, c and d are each independently 0 or 1, and e is an integer of from 0 to 6],

epoxy resins represented by the following formula (9):

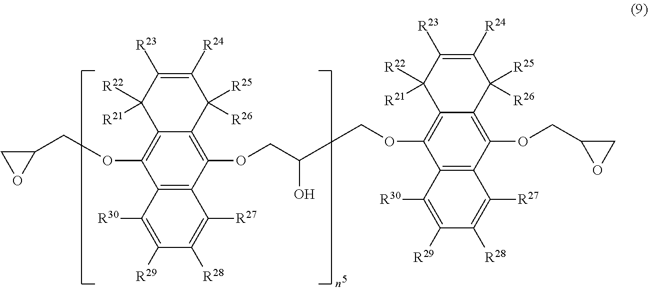

[in the formula (9), R²¹ to R³⁰ each independently represent any one of a hydrogen atom and an alkyl group having 1 to 6 carbon atoms, and n⁵ is an integer of from 0 to 5],

epoxy resins represented by the following formula (10):

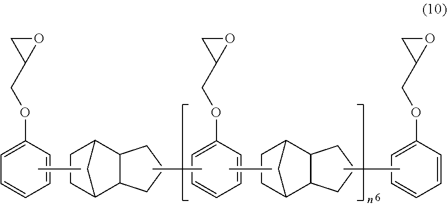

[in the formula (10), an average value of n⁶ is a positive number of from 0 to 4], and

epoxy resins represented by the following formula (5):

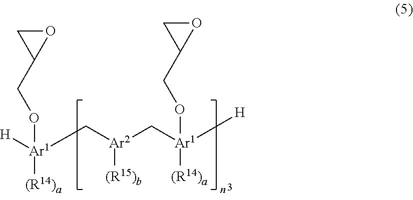

[in the formula (5), Ar¹ represents any one of a phenylene group and a naphthylene group, each binding position of the glycidyl ether groups may be any one of α-position and β-position when Ar¹ is the naphthylene group, Ar² represents any one of a phenylene group, a biphenylene group, and a naphthylene group, R¹⁴ and R¹⁵ each independently represent a hydrocarbon group having 1 to 10 carbon atoms, a is an integer of from 0 to 5, b is an integer of from 0 to 8, and an average value of n³ is a positive number between 1 and 3 both inclusive].

In the second semiconductor device of the present invention, the epoxy resin composition preferably comprises at least one curing agent selected from the group consisting of phenol resins represented by the following formula (7):

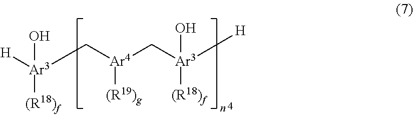

[in the formula (7), Ar³ represents any one of a phenylene group and a naphthylene group, each binding position of the hydroxyl groups may be any one of α-position and β-position when Ar³ is the naphthylene group, Ar⁴ represents any one of a phenylene group, a biphenylene group, and a naphthylene group, R¹⁸ and R¹⁹ each independently represent a hydrocarbon group having 1 to 10 carbon atoms, f is an integer of from 0 to 5, g is an integer of from 0 to 8, and an average value of n⁴ is a positive number between 1 and 3 both inclusive.

In the second semiconductor device of the present invention, the cured product of the epoxy resin composition preferably has a glass transition temperature between 135° C. and 175° C. both inclusive. Moreover, the cured product of the epoxy resin composition preferably has a linear expansion coefficient between 7 ppm/° C. and 11 ppm/° C. both inclusive in a temperature range not exceeding the glass transition temperature thereof.

Furthermore, the present inventors have found the following. In a semiconductor device comprising a lead frame having a die pad portion or a circuit board, one or more semiconductor elements mounted on the die pad portion of the lead frame or on the circuit board, and an encapsulating member, when an electrode pad provided on the semiconductor element are thickened, copper purity of a copper wire as well as elemental sulfur and elemental chlorine contained in the copper wire cause the degradation of the moisture resistance reliability and the like, and when electrical joints provided on the die pad portion of the lead frame or on the circuit board and the electrode pad provided on the semiconductor element are connected by the copper wire having high purity as well as low elemental sulfur and chlorine contents, encapsulation of the semiconductor element and the like using an encapsulating member having a predetermined glass transition temperature and linear expansion coefficient al allows to provide a semiconductor device excellent in temperature cycle property, high temperature storage life, high temperature operating life, and moisture resistance reliability, even if the thickness of the electrode pad provided on the semiconductor element is 1.2 μm or more. This finding has led the present inventors to complete the present invention.

Specifically, a third semiconductor device of the present invention is a semiconductor device comprising any one of a lead frame having a die pad portion and a circuit board, one or more semiconductor elements mounted on any one of the die pad portion of the lead frame and the circuit board, a copper wire that electrically connects electrical joints provided on any one of the lead frame and the circuit board to an electrode pad provided on the semiconductor element, and an encapsulating member which encapsulates the semiconductor element and the copper wire, wherein the electrode pad provided on the semiconductor element has a thickness of 1.2 μm or more, the copper wire has a copper purity of 99.999% by mass or more, an elemental sulfur content of 5 ppm by mass or less and an elemental chlorine content of 0.1 ppm by mass or less, and the encapsulating member has a glass transition temperature between 135° C. and 190° C. both inclusive, and a linear expansion coefficient between 5 ppm/° C. and 9 ppm/° C. both inclusive in a temperature range not exceeding the glass transition temperature thereof.

In the third semiconductor device of the present invention, the encapsulating member is preferably a cured product of an epoxy resin composition. Moreover, the epoxy resin composition preferably comprises spherical silica in an amount of 88.5% by mass or more.

The above-described third semiconductor device of the present invention is useful for a semiconductor device in which the semiconductor element is provided with a low dielectric insulating film.

According to the present invention, there can be obtained the first semiconductor device in which the copper wire electrically connecting the electrical joints provided on the lead frame or the circuit board to the electrode pad provided on the semiconductor element is difficult to corrode, and whose solder resistance, high temperature storage life, high temperature operating life, migration resistance, and moisture resistance reliability are better balanced.

There can also be obtained the second semiconductor device which comprises the lead frame or the circuit board, the semiconductor element, and the encapsulating member, wherein the electrical joints provided on the lead frame or the circuit board and the electrode pad provided on the semiconductor element are connected by the copper wire, and which is excellent in high temperature storage life, high temperature operating life, and moisture resistance reliability.

Furthermore, there can be obtained the third semiconductor device which can exhibit excellent temperature cycle property, high temperature storage life, high temperature operating life, and moisture resistance reliability, even when the semiconductor element is provided with the electrode pad having a thickness of 1.2 μm or more.

### BRIEF DESCRIPTION OF THE DRAWINGS

FIG. 1 is a cross sectional view showing an example of the semiconductor device of the present invention.

FIG. 2 is a cross sectional view showing another example of the semiconductor device of the present invention.

FIG. 3 is a cross sectional view showing another example of the semiconductor device of the present invention.

### DESCRIPTION OF THE EMBODIMENTS

Hereinafter, the present invention will be described in detail with reference to its preferred embodiments.

<First Semiconductor Device>

First, a first semiconductor device of the present invention will be described. The first semiconductor device of the present invention is a semiconductor device comprising a lead frame having a die pad portion or a circuit board, one or more semiconductor elements mounted on the die pad portion of the lead frame or on the circuit board, a copper wire that electrically connects electrical joints provided on the lead frame or the circuit board to an electrode pad provided on the semiconductor element, and an encapsulating member which encapsulates the semiconductor element and the copper wire, wherein the copper wire has a wire diameter of 25 μm or less, the copper wire has, on a surface thereof, a coating layer formed from a metal material containing palladium, and the encapsulating member is formed from a cured product of an epoxy resin composition comprising (A) an epoxy resin, (B) a curing agent, (C) a filler, and (D) a compound containing a sulfur atom.

Thus, there can be obtained a semiconductor device in which the copper wire electrically connecting the electrical joints provided on the lead frame or the circuit board to the electrode pad of the semiconductor element is difficult to corrode, and whose high temperature storage life, high temperature operating life, and moisture resistance reliability are better balanced. Now, each of the components will be described in detail.

The lead frame or circuit board used in the first semiconductor device of the present invention is not particularly limited. Examples thereof include lead frames or circuit boards used in conventionally-known semiconductor devices, such as a dual inline package (DIP), plastic leaded chip carrier (PLCC), quad flat package (QFP), low profile quad flat package (LQFP), small outline J-lead package (SOJ), thin small outline package (TSOP), thin quad flat package (TQFP), tape carrier package (TCP), ball grid array (BGA), chip size package (CSP), quad flat non-leaded package (QFN), small outline non-leaded package (SON), lead frame-BGA (LF-BGA), and mold array package type BGA (MAP-BGA). The electrical joints mean a terminal for joining the wire onto the lead frame or circuit board, for example, a wire bonding portion on the lead frame, an electrode pad on the circuit board, and the like.

The semiconductor element used in the first semiconductor device of the present invention is not particularly limited. Examples thereof include an integrated circuit, a large scale integrated circuit, a transistor, a thyristor, a diode, a solid state image sensor, and the like. Examples of the material for the electrode pad of the semiconductor element include aluminum, palladium, copper, gold, and the like.

Next, the copper wire used in the first semiconductor device of the present invention will be described. For a semiconductor device comprising a lead frame or a circuit board, one or more semiconductor elements mounted on the die pad portion of the lead frame or on the circuit board, a wire that electrically connects electrical joints provided on the lead frame or the circuit board to an electrode pad provided on the semiconductor element, and an encapsulating member which encapsulates the semiconductor element and the wire, wherein the encapsulating member is formed only on a single side of the lead frame or circuit board on which the semiconductor element is mounted (hereinafter referred to as a “single-sided encapsulated semiconductor device”), a narrow pad pitch and a small wire diameter are required in order to improve an integration degree. In the first semiconductor device of the present invention, the copper wire having a wire diameter of 25 μm or less is used, and the copper wire having a wire diameter of 23 μm or less is preferably used. When a copper wire is used as the wire, also contemplated is a method in which a junction area is increased by increasing the wire diameter, for the purpose of enhancing the connection reliability attributable to the processability of the copper wire itself, whereby the degradation of the moisture resistance reliability due to an insufficient junction is suppressed. However, the above-described approach of increasing the wire diameter cannot improve the integration degree and cannot provide a satisfactory single-sided encapsulated semiconductor device.

The copper wire used in the first semiconductor device of the present invention has, on a surface thereof, a coating layer formed from a metal material containing palladium. This allows the ball configuration of each end of the copper wire to be stable and the connection reliability of a junction part to be improved. This also achieves the effect of preventing the oxidative degradation of the copper which is in a core wire, and this allows to improve the high temperature storage life of the junction part. The thickness of such a coating layer is preferably 0.001 to 0.02 μm, and more preferably 0.005 to 0.015 μm. If the thickness of the coating layer is less than the lower limit, the oxidative degradation of the copper in the core wire cannot be sufficiently prevented, and likewise, the moisture resistance and high temperature storage life of the junction part may degrade. On the other hand, if the thickness exceeds the upper limit, the copper which is in the core wire and the metallic materials containing palladium of the coating material insufficiently melt during wire bonding, with the result that the ball configuration may become unstable and that the moisture resistance and high temperature storage life of the junction part may degrade.

The copper purity in the core of the copper wire used in the first semiconductor device of the present invention is preferably 99.99% by mass or more, and more preferably 99.999% by mass or more. In general, addition of various elements (dopants) to the copper allows to stabilize the ball configuration of each end of the copper wire during bonding. However, because addition of a large amount more than 0.01% by mass of dopants results in hardening of the copper wire, there is a tendency that the electrode pad of the semiconductor element is damaged during bonding, causing defects such as degradation of the moisture resistance reliability, decrease in the high temperature storage life, and rise in electrical resistance, which are attributable to an insufficient junction. In contrast, because the copper wire having a copper purity of 99.99% by mass or more has sufficient flexibility, the copper wire has no risk of damaging the pad during bonding. Note that for the copper wire used in the first semiconductor device of the present invention, the doping of 0.001 to 0.003% by mass of Ba, Ca, Sr, Be, Al, or a rear earth metal into the copper which is in the core wire allows to further improve the ball configuration and junction strength.

The core of the copper wire used in the first semiconductor device of the present invention can be obtained by casting a copper alloy in a melting furnace, milling an ingot thereof using a roll, wire-drawing the resultant using a die so as to give a predetermined wire diameter, and performing post-heat treatment in which the wire is heated with continuous sweep. By immersing the core of the resultant copper wire having the predetermined wire diameter in an electrolyte or electroless solution containing palladium, and plating the core wire by continuous sweep, there can be obtained the copper wire having, on a surface thereof, a coating layer formed from a metal material containing palladium. In this case, the thickness of the coating layer can be adjusted by the sweep rate. Also, the intended copper wire can be obtained by immersing the core of copper wire having a larger wire diameter than the predetermined diameter in an electrolyte or electroless solution containing palladium, forming a coating layer formed from a metal material containing palladium by continuous sweep, and then drawing the core wire having the coating layer so as to give the predetermined wire diameter.

In the first semiconductor device of the present invention, the semiconductor element and the copper wire are encapsulated by an encapsulating member. The encapsulating member used therefor is formed from a cured product of an epoxy resin composition comprising (A) an epoxy resin, (B) a curing agent, (C) a filler, and (D) a compound containing a sulfur atom.

Examples of the (A) epoxy resin used for the first semiconductor device of the present invention include monomers, oligomers, and polymers which each have two or more epoxy groups in one molecule. A molecular weight and structure thereof are not particularly limited, but examples thereof include novolac type epoxy resins such as phenol novolac type epoxy resins, cresol novolac type epoxy resins, and naphthol novolac type epoxy resins; crystalline epoxy resins such as biphenyl type epoxy resins, bisphenol type epoxy resins, stilbene type epoxy resins, and dihydroanthracenediol type epoxy resins; polyfunctional epoxy resins such as triphenol methane type epoxy resins and alkyl modified triphenol methane type epoxy resins; aralkyl type epoxy resins such as phenol aralkyl type epoxy resins having a phenylene skeleton and phenol aralkyl type epoxy resins having a biphenylene skeleton, naphthol aralkyl type epoxy resins having a phenylene skeleton, and naphthol aralkyl type epoxy resins having a biphenylene skeleton; naphthol type epoxy resins such as dihydroxynaphthalene type epoxy resins, and epoxy resins obtained by glycidyletherifing a dimmer of dihydroxynaphthalene; epoxy resins containing triazine nucleus such as triglycidyl isocyanurate, and monoallyl diglycidyl isocyanurate; and phenol type epoxy resins modified by a bridged cyclic hydrocarbon compound such as dicyclopentadiene-modified phenol type epoxy resins. They may be used singly or in combination of two or more.

Among such (A) epoxy resins, considering the moisture resistance reliability of the encapsulating member, preferred are those containing as little Cl⁻ (chlorine ion), which is an ionic impurity, as possible, and more specifically, the content ratio of the ionic impurity such as Cl⁻ (chlorine ion) is preferably 10 ppm or less, and more preferably 5 ppm or less, relative to the total amount of the (A) epoxy resin. Note that the content ratio of Cl⁻ (chlorine ion) relative to the total amount of the epoxy resin can be measured as follows: First, 5 g of a sample such as the epoxy resin and 50 g of distilled water are placed in an autoclave made of Teflon (registered trademark) and the vessel is sealed. The sample is subjected to treatment at a temperature of 125° C. and a relative humidity of 100% RH for 20 hours (pressure cooker treatment). Next, after cooling to room temperature, the extraction water is centrifuged and filtered through a 20 μm filter. The concentration of chlorine ion is measured using a capillary electrophoresis apparatus (for example, “CAPI-3300” available from Otsuka Electronics Co., Ltd.). The resultant concentration of chlorine ion (unit: ppm) is the value measured for the chlorine ion which is extracted from 5 g of the sample and diluted tenfold. Accordingly, the concentration is converted to the chlorine ion content per unit mass of the resin in accordance with the following equation:

Chlorine ion content per unit mass of the sample (unit: ppm)=(Concentration of chlorine ion measured by capillary electrophoresis apparatus)×50÷5

Further, this measurement method can also be applied to the measurement of the concentration of the chlorine ion contained in the curing agent.

In the first semiconductor device of the present invention, considering the curability of the epoxy resin composition, the epoxy equivalent of the (A) epoxy resin is preferably between 100 g/eq and 500 g/eq both inclusive.

Among those epoxy resins, the (A) epoxy resin especially preferably comprises at least one epoxy resin selected from the epoxy resins represented by the formulas (3) (4), (5), and (6) as described below.

Now, the epoxy resins represented by the formulas (3) to (6) will be described. Both of epoxy resins represented by the following formula (3):

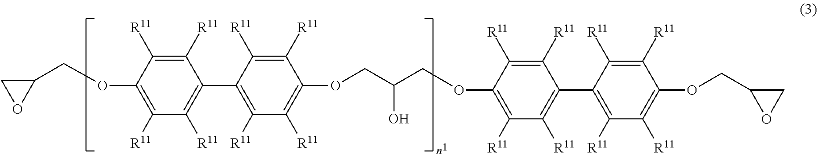

[in the formula (3), a plurality of R¹¹ each independently represent a hydrogen atom or a hydrocarbon group having 1 to 4 carbon atoms, and n¹ represents a polymerization degree and an average value thereof is 0 or a positive number of 5 or less], and
epoxy resins represented by the following formula (4):

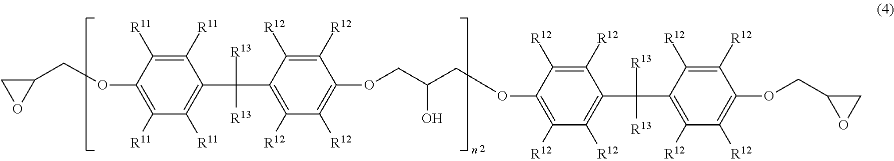

[in the formula (4), a plurality of R¹² and R¹³ each independently represent a hydrogen atom or a hydrocarbon group having 1 to 4 carbon atoms, and n² represents a polymerization degree and an average value thereof is 0 or a positive number of 5 or less]
are crystalline epoxy resins, and they have the features of being solid and excellent in handling property at ordinary temperature and having very low melt viscosity in molding. The low melt viscosity of these epoxy resins permit high fluidization of the epoxy resin composition and high filling of an inorganic filler. This allows to improve the solder resistance and moisture resistance reliability of the semiconductor device.

The content ratio of each of the epoxy resins represented by the above formulas (3) and (4) is preferably 15% by mass or more, more preferably 30% by mass or more, and especially preferably 50% by mass or more, based on the total amount of the (A) epoxy resin. If the content ratio is within the above range, the fluidity of the epoxy resin composition can be improved.

Epoxy resins represented by the following formula (5):

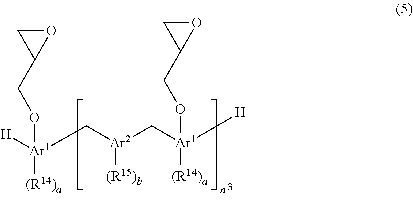

[in the formula (5), Ar¹ represents a phenylene group or a naphthylene group, a binding position of the glycidyl ether groups may be α-position or β-position when Ar¹ is the naphthylene group, Ar² represents a phenylene group, a biphenylene group, or a naphthylene group, R¹⁴ and R¹⁵ are groups introduced to Ar¹ and Ar², respectively, and each independently represent a hydrocarbon group having 1 to 10 carbon atoms, a is an integer of from 0 to 5, b is an integer of from 0 to 8, and an average value of n³ is a positive number between 1 and 3 both inclusive]
have an aralkyl group (—CH₂—Ar²—CH₂—) including a hydrophobic phenylene, biphenylene, or naphthylene skeleton between the phenylene or naphthylene groups (—Ar¹—) to which the glycidyl ether groups each bond. Consequently, the distance between the crosslinks thereof is long compared to that of phenol novolac type epoxy resins, cresol novolac type epoxy resins, or the like. Thus, the cured product of the epoxy resin composition using the epoxy resin has a low moisture absorption ratio and exhibits reduction of elastic modulus at high temperature, and can contribute to improvement of the solder resistance of the semiconductor device. The cured product of the epoxy resin composition using the epoxy resin has characteristics of excellent flame resistance and high heat resistance in spite of low crosslink density. Additionally, in the epoxy resins having an aralkyl group containing a naphthylene skeleton, rise in Tg caused by the rigidity due to the naphthalene ring, and reduction in a linear expansion coefficient caused by the interaction between molecules due to their planar structure allow to significantly reduce the warpage of the single-sided encapsulated semiconductor device such as an area surface mounted device.

When Ar¹ in the formula (5) is the naphthylene group, the binding position of the glycidyl ether groups may be α-position or β-position. Furthermore, when Ar¹ is the naphthylene group, as well as the above epoxy resins having an aralkyl group containing a naphthylene skeleton, rise in Tg and reduction in a linear expansion coefficient allow to significantly reduce the warpage of an area surface mounted semiconductor device. In addition, the improvement of heat resistance can also be achieved because the epoxy resin contains a lot of carbon atoms forming aromatic rings.

Examples of the epoxy resin represented by the formula (5) include phenol aralkyl type epoxy resins having a phenylene skeleton, phenol aralkyl type epoxy resins having a biphenylene skeleton, and naphthol aralkyl type epoxy resins having a phenylene skeleton, but the epoxy resins are not limited thereto.

The softening point of such an epoxy resin represented by the formula (5) is preferably between 40° C. and 110° C. both inclusive, and more preferably between 50° C. and 90° C. both inclusive. The epoxy equivalent is preferably between 200 and 300 both inclusive.

The content ratio of the epoxy resin represented by the formula (5) is preferably 30% by mass or more, more preferably 50% by mass or more, and especially preferably 70% by mass or more, based on the total amount of the (A) epoxy resin. If the content ratio is within the above range, the solder resistance, flame resistance, and the like of the semiconductor device can be improved.

Epoxy resins represented by the following formula (6):

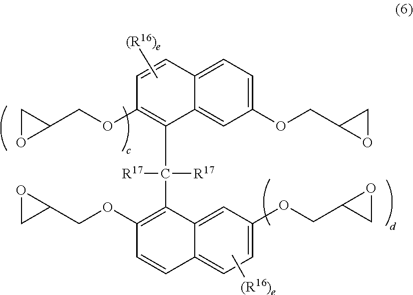

[in the formula (6), R¹⁶ represents a hydrogen atom or a hydrocarbon group having 1 to 4 carbon atoms and may be the same or different when there are a plurality of R¹⁶, R¹⁷'s each independently represent a hydrogen atom or a hydrocarbon group having 1 to 4 carbon atoms, c and d are each independently 0 or 1, and e is an integer of from 0 to 6]
have a naphthalene skeleton in the molecules, thus have high bulkiness and high rigidity. Consequently, the cure shrinkage ratio of the cured product of the epoxy resin composition using the above epoxy resin is reduced, and thereby an area surface mounted semiconductor device having significantly reduced warpage can be produced.

The content ratio of the epoxy resin represented by the formula (6) is preferably 20% by mass or more, more preferably 30% by mass, and especially preferably 50% by mass, based on the total amount of the (A) epoxy resins. If the content ratio is within the above range, the warpage of the semiconductor device can be significantly improved.

In the epoxy resin composition used for the first semiconductor device of the present invention, the lower limit of the content ratio of the overall (A) epoxy resin is not particularly limited, but is preferably 3% by mass or more, and more preferably 5% by mass or more, based on the total amount of the epoxy resin composition. When the content ratio of the overall (A) epoxy resin is equal to or more than the above lower limit, there is less possibility that degradation of solder resistance and the like is caused. Meanwhile, the upper limit of the content ratio of the overall epoxy resin is not particularly limited, but is preferably 15% by mass or less, and more preferably 13% by mass or less, based on the total amount of the epoxy resin composition. When the content ratio of the overall (A) epoxy resin is equal to or less than the above upper limit, there is less possibility that degradation of solder resistance, reduction of fluidity, and the like are caused

The epoxy resin composition used for the first semiconductor device of the present invention comprises (B) a curing agent. Such (B) a curing agent is not particularly limited as long as reacting with the epoxy resin to form a cured product. For example, any of polyaddition type, catalyst type, and condensation type curing agents may be used.

Examples of the polyaddition type curing agent include aliphatic polyamines such as diethylenetriamine (DETA), triethylenetetramine (TETA), and metaxylenediamine (MXDA); and aromatic polyamines such as diaminodiphenyl methane (DDM), m-phenylenediamine (MPDA), and diaminodiphenylsulfone (DDS); as well as polyamine compounds such as dicyandiamide (DICY), and organic acid dihydrazide; acid anhydrides including alicyclic acid anhydrides such as hexahydrophthalic anhydride (HHPA) and methyltetrahydrophthalic anhydride (MTHPA), and aromatic acid anhydrides such as trimellitic anhydride (TMA), pyromellitic dianhydride (PMDA), and benzophenone-tetracarboxylic acid (BTDA); polyphenol compounds such as novolac type phenol resins and phenol polymers; polymercaptan compounds such as polysulfide, thioester, and thioether; isocyanate compounds such as isocyanate prepolymers, blocked isocyanates; and organic acids such as polyester resins containing a carboxylic acid.

Examples of the catalyst type curing agent include tertiary amine compounds such as benzyldimethylamine (BDMA), and 2,4,6-tris(dimethylaminomethyl)phenol (DMP-30); imidazole compounds such as 2-methylimidazole and 2-ethyl-4-methylimidazole (EMI24); and Lewis acids such as BF3 complexes.

Examples of the condensation type curing agent include phenol resin-based curing agents such as novolac type phenol resins and resol type phenol resins; urea resins such as urea resins containing a methylol group; melamine resins such as melamine resins containing a methylol group.

Among them, the phenol resin-based curing agents are preferred from the viewpoint of the balance among flame resistance, moisture resistance, electric characteristics, curability, storage stability and the like. Examples of the phenol resin-based curing agent include monomers, oligomers, and polymers having two or more phenolic hydroxyl groups in one molecule, and the molecular weight and structure thereof are particularly not limited. Examples thereof include novolac type epoxy resins such as phenol novolac type epoxy resins and cresol novolac type epoxy resins; polyfunctional phenol resins such as triphenol methane type phenol resins; modified phenol resins such as terpene-modified phenol resins and dicyclopentadiene-modified phenol resins; aralkyl type resins such as phenol aralkyl resins having at least one of a phenylene skeleton and a biphenylene skeleton and naphthol aralkyl resins having at least one of a phenylene skeleton and a biphenylene skeleton; and bisphenol compounds such as bisphenol A and bisphenol F. They may be used singly or in combination of two or more.

Among such (B) curing agents, considering the moisture resistance reliability of the encapsulating member, preferred are those containing as little Cl⁻ ion, which is an ionic impurity, as possible, and more specifically, the content ratio of the ionic impurity such as Cl⁻ (chlorine ion) is preferably 10 ppm or less, and more preferably 5 ppm or less, relative to the total amount of the (B) curing agent. Note that the content ratio of Cl⁻ (chlorine ion) to the total amount of the curing agent can be measured as the same manner as in the case of the epoxy resin described above.

In the first semiconductor device of the present invention, considering the curability of the epoxy resin composition, the hydroxyl equivalent of the (B) curing agent is preferably between 90 g/eq and 250 g/eq both inclusive.

Among these curing agents, especially preferred are those containing at least one curing agent selected from the novolac type phenol resins and the phenol resins represented by the formula (7), as described below.

Now, the novolac type phenol resins and the phenol resins represented by the formula (7) will be described. The novolac type phenol resin used for the first semiconductor device of the present invention is not particularly limited as long as obtained by polymerization of phenols with formalin in the presence of an acid catalyst. The novolac type phenol resins having lower viscosity are preferred, specifically, those having a softening point of 90° C. or lower are preferred, and those having a softening point of 55° C. or lower are more preferred. Such novolac type phenol resins have the feature that they do not impair the fluidity of the epoxy resin composition, and that they have excellent curability because of low viscosity thereof. The novolac type phenol resins have the advantage that they can improve the high temperature storage life of the resultant semiconductor device. They may be used singly or in combination of two or more.

The content ratio of the novolac type phenol resin is preferably 20% by mass or more, more preferably 30% by mass or more, and especially preferably 50% by mass or more, based on the total amount of the (B) curing agent. If the content ratio is within the above range, the high temperature storage life can be improved.

Phenol resins represented by the following formula (7):

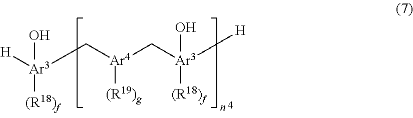

[in the formula (7), Ar³ represents a phenylene group or a naphthylene group, a binding position of the hydroxyl groups may be α-position or β-position when Ar³ is the naphthylene group, Ar⁴ represents a phenylene group, a biphenylene group, or a naphthylene group, R¹⁸ and R¹⁹ each independently represent a hydrocarbon group having 1 to 10 carbon atoms, f is an integer of from 0 to 5, g is an integer of from 0 to 8, and n⁴ represents a polymerization degree and an average value thereof is a positive number between 1 and 3 both inclusive] have an aralkyl group (—CH₂—Ar₄-CH₂—) including a hydrophobic phenylene, biphenylene, or naphthylene skeleton between the phenolic hydroxyl groups. Consequently, the distance between the crosslinks thereof is long compared to that of phenol novolac type epoxy resins, cresol novolac type epoxy resins, or the like. Thus, the cured product of the epoxy resin composition using the phenol resin has a low moisture absorption ratio and exhibits reduction of elastic modulus at high temperature, and can contribute to improvement of the solder resistance of the semiconductor device. The cured product of the epoxy resin composition using the phenol resin has characteristics of excellent flame resistance and high heat resistance in spite of low crosslink density. Additionally, in the phenol resins having an aralkyl group containing a naphthylene skeleton, rise in Tg caused by the rigidity due to the naphthalene ring, and reduction in a linear expansion coefficient caused by the interaction between molecules due to their planar structure allow to significantly reduce the warpage of the single-sided encapsulated semiconductor device such as an area surface mounted device.

When Ar³ in the formula (7) is the naphthylene group, the binding position of the phenolic hydroxyl groups may be α-position or β-position. Furthermore, when Ar³ is the naphthylene group, as well as the above phenol resins having an aralkyl group containing a naphthylene skeleton, rise in Tg and reduction in a linear expansion coefficient allow to decrease the molding shrinkage ratio and to significantly reduce the warpage of an area surface mounted semiconductor device. In addition, the improvement of heat resistance can also be achieved because the phenol resin contains a lot of carbon atoms forming aromatic rings.

Examples of the phenol resins represented by the formula (7) include phenol aralkyl resins having a phenylene skeleton, phenol aralkyl resins Navin a biphenylene skeleton, and naphthol aralkyl resins having a phenylene skeleton, but the phenol resins are not limited thereto.

The content ratio of the phenol resin represented by the formula (7) is preferably 20% by mass or more, more preferably 30% by mass or more, and especially preferably 50% by mass, based on the total amount of the (B) curing agent. If the content ratio is within the above range, the solder resistance, flame resistance, and the like of the semiconductor device can be improved.

In the epoxy resin composition used for the first semiconductor device of the present invention, the lower limit of the content ratio of the overall (B) curing agent is not particularly limited, but is preferably 0.8% by mass or more, and more preferably 1.5% by mass or more, based on the total amount of the epoxy resin composition. When the content ratio of the overall (B) curing agent is equal to or more than the above lower limit, sufficient fluidity can be achieved. Meanwhile, the upper limit of the content ratio of the overall (B) curing agent is not particularly limited, but is preferably 10% by mass or less, and more preferably 8% by mass or less, based on the total amount of the epoxy resin composition. When the content ratio of the overall (B) curing agent is equal to or less than the above upper limit, good solder resistance can be achieved.

Moreover, in the first semiconductor device of the present invention, when phenol resin-based curing agent is used as the curing agent (B), the blend ratio of the epoxy resin to the phenol resin-based curing agent is more preferably an equivalent ratio of the number of the epoxy groups (EP) of the overall epoxy resin to the number of the phenolic hydroxyl groups (OH) of the overall phenol resin-based curing agent, i.e., (EP)/(OH), of between 0.8 and 1.3 both inclusive. When the equivalent ratio is within the above range, there is less possibility that decrease in curability of the epoxy resin composition or degradation of physical properties of the cured product of the epoxy resin composition and the like is caused.

The epoxy resin composition used for the first semiconductor device of the present invention comprises the (C) filler. As such (C) a filler, those used generally in the epoxy resin compositions for encapsulating members can be used, and examples thereof include fused silica, crystalline silica, secondary aggregate silica, talc, alumina, titanium white, silicon nitride, aluminum hydroxide, glass fiber, and the like. These fillers may be used singly or in combination of two or more. Among them, the fused silica is especially preferred from the viewpoint of the excellent moisture resistance and ability of further decreasing the linear expansion coefficient. The shape of the (C) filler is also not particularly limited. For example, any of crashed and spherical fillers can be used. From the viewpoint of improvement of fluidity, however, it is preferred that the filler has as high sphericity as possible and has a broad particle size distribution, and fused spherical silica is especially preferred. Furthermore, the (C) filler may be surface-treated with a coupling agent or may be previously treated with an epoxy or phenol resin. Examples of such a treatment method include the method in which the filler is mixed with the coupling agent or the epoxy or phenol resin using a solvent and then the solvent is removed, the method in which the coupling agent or the epoxy or phenol resin is directly added to the (C) filler and the mixing treatment is carried out using a mixer, and the like.

A particle diameter of the (C) filler used for the first semiconductor device of the present invention is, in a mode diameter equivalent, preferably between 30 μm and 50 μm both inclusive, and more preferably between 35 μm and 45 μm both inclusive. The use of the filler having the mode diameter within the above range allows to apply the present invention to a single-sided encapsulated semiconductor having a narrow wire pitch. The content of coarse particles having a diameter of 55 μm or more is preferably 0.2% by mass or less, and more preferably 0.1% by mass or less. When the content of the coarse particle is within the above range, the defect that the coarse particles are sandwiched between the wires and push down the wires, i.e., wire sweep, can be prevented. Such a filler having a predetermined particle size distribution can be the commercial filler as it is or can be obtained by mixing the plural kinds of the fillers or sieving the filler. Note that the mode diameter of the filler used for the present invention can be measured using a commercial laser particle size distribution analyzer (for example, SALD-7000 available from Shimadzu Corp., or the like).

In the epoxy resin composition used for the first semiconductor device of the present invention, the lower limit of the content ratio of the (C) filler is preferably 84% by mass or more, and more preferably 87% by mass or more, based on the total amount of the epoxy resin composition, from the viewpoint of the reliability. When the content ratio of (C) filler is equal to or more than the above lower limit, low hygroscopicity and low thermal expansivity are achieved and thus there is less possibility that solder resistance is insufficient. Meanwhile, the upper limit of the content ratio of the (C) filler is preferably 92% by mass or less, and more preferably 89% by mass or less, based on the total amount of the epoxy resin composition, from the viewpoint of the moldability. When the content ratio of the (C) filler is equal to or less than the above upper limit, there is less possibility that reduction of the fluidity causes the insufficient filling during molding or that defect such as wire sweep in the semiconductor device due to rise in viscosity is generated.

The epoxy resin composition used for the first semiconductor device of the present invention comprises the (D) compound containing a sulfur atom. This improves an affinity with a metal. Such (D) a compound containing a sulfur atom is not particularly limited, but preferred are compounds having at least one atomic group selected from the group consisting of mercapto group and sulfide bond, the atomic group having excellent affinity with a metal material containing palladium. Among such (D) a compound containing a sulfur atoms, more preferred are compounds having at least one atom group selected from the group consisting of amino group, hydroxy group, carboxyl group, mercapto group, and nitrogen-containing heterocyclic rings, the atomic group having excellent affinity with epoxy resin matrix; and at least one atomic group selected from the group consisting of mercapto group and sulfide bond, the atomic group having excellent affinity with a metal material containing palladium. This allows the increase in the affinity between the surface of the encapsulating member formed from the cured product of the epoxy resin composition and the metal material containing palladium with which the surface of the copper wire is coated, and thereby delamination on the interface can be reduced. Accordingly, the solder resistance and moisture resistance reliability of the semiconductor device can be improved. Such (D) a compound containing a sulfur atom is not particularly limited, but is preferably a nitrogen-containing heterocyclic aromatic compound or a sulfur-containing heterocyclic compound.

As such a nitrogen-containing heterocyclic aromatic compound, preferred are triazole-based compounds, thiazoline-based compounds, triazole-based compounds, thiadiazole-based compounds, triazine-based compounds, and pyrimidine-based compounds, and the like, more preferred are triazol-based compounds, especially preferred are compounds having a 1,2,4-triazole ring, and most preferred are compounds represented by the following formula (1):

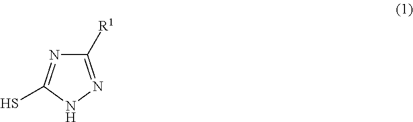

[in the formula (1), R¹ represents a hydrogen atom, a mercapto group, an amino group, a hydroxy group, or a hydrocarbon group having any functional group of them].
In the first semiconductor device of the present invention, use of the compound represented by the formula (1) as the (D) compound containing a sulfur atom allows to further improve the reliability of the semiconductor device, because of the higher affinity with the metal material containing palladium with which the surface of the copper wire is coated.

As the sulfur containing heterocyclic compound, preferred are dithiane-based compounds, more preferred are compounds represented by the following formula (2):

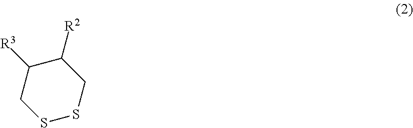

[in the formula (2), R² and R³ each independently represent a hydrogen atom, a mercapto group, an amino group, a hydroxy group, or a hydrocarbon group having any functional group of them], and
especially preferred are compounds represented by the formula (2) wherein at least one of R² and R³ is a hydroxy group or a hydrocarbon group having a hydroxy group. In the first semiconductor device of the present invention, use of the compound represented by the formula (2) as the (D) compound containing a sulfur atom allows to further improve the reliability of the semiconductor device, because of the higher affinity with the metal material containing palladium with which the surface of the copper wire is coated.

In the epoxy resin composition used for the first semiconductor device of the present invention, the lower limit of the content ratio of the (D) compound containing a sulfur atom is preferably 0.01% by mass or more, more preferably 0.02% by mass or more, and especially preferably 0.03% by mass or more, based on the total amount of the epoxy resin composition. When the content ratio of the (D) compound containing a sulfur atom is equal to or more than the above lower limit, the affinity with the metal material containing palladium can be improved. Meanwhile, the upper limit of the content ratio of the (D) compound containing a sulfur atom is preferably 0.5% by mass or less, more preferably 0.3% by mass or less, and especially preferably 0.2% by mass or less, based on the total amount of the epoxy resin composition. When the content ratio of the (D) compound containing a sulfur atom is equal to or less than the above upper limit, there is less possibility that the fluidity of the epoxy resin composition is reduced.

A curing accelerator is preferably added to the epoxy resin composition used for the first semiconductor device of the present invention. Such a curing accelerator may be any of those accelerating the crosslinking reaction of the epoxy group of the epoxy resin with a functional group of the curing agent (for example, the phenolic hydroxyl group of phenol resin-based curing agent), and those generally used for epoxy resin encapsulating members can be used. Examples thereof include diazabicycloalkenes such as 1,8-diazabicyclo(5,4,0)undecene-7 and derivatives thereof; organic phosphines such as triphenylphosphine and methyldiphenylphosphine; imidazole compounds such as 2-methylimidazole; tetra-substituted phosphonium tetra-substituted borates such as tetraphenylphosphonium tetraphenylborate; the adducts of a phosphine compound with a quinone compound; and the like. They may be used singly or in combination of two or more.

Among such curing accelerators, more preferred are the adducts of a phosphine compound with a quinone compound from the viewpoint of the fluidity. Examples of the phosphine compound include triphenylphosphine, tri-p-tolylphosphine, diphenylcyclohexylphosphine, tricyclohexylphosphine, tributyl phosphine, and the like. Examples of the quinone compound include 1,4-benzoquinone, methyl-1,4-benzoquinone, methoxy-1,4-benzoquinone, phenyl-1,4-benzoquinone, 1,4-naphthoquinone, and the like. Among such adducts of a phosphine compound with a quinone compound, more preferred is the adduct of the triphenylphosphine with the 1,4-benzoquinone. The method for producing the adduct of a phosphine compound with a quinone compound is not particularly limited, but the adduct can be produced, for example, by addition reaction between a phosphine compound and a quinone compound, which are used as raw materials, in an organic solvent which dissolves both, and by isolation of the resultant.

In the epoxy resin composition used for the first semiconductor device of the present invention, the lower limit of the content ratio of the curing accelerator is not particularly limited, but is preferably 0.05% by mass or more, and more preferably 0.1% by mass or more, based on the total amount of the epoxy resin composition. When the content ratio of the curing accelerator is equal to or more than the above lower limit, there is less possibility that decrease in curability is caused. Meanwhile, the upper limit of the content ratio of the curing accelerator is not particularly limited, but is preferably 1% by mass or less, and more preferably 0.5% by mass or less, based on the total amount of the epoxy resin composition. When the content ratio of the curing accelerator is equal to or less than the above upper limit, there is less possibility that reduction of fluidity is caused.

In the epoxy resin composition used for the first semiconductor device of the present invention, where further necessary, various additives including aluminum corrosion inhibitors such as zirconium hydroxide; inorganic ion exchangers such as bismuth oxide hydrate; coupling agents such as γ-glycidoxypropyltrimethoxysilane, 3-mercaptopropyltrimethoxysilane, and 3-aminopropyltrimethoxysilane; coloring agents such as carbon black and colcothar; components for reducing stress such as silicone rubber; natural waxes such as carnauba wax; synthetic waxes; higher fatty acids such as zinc stearate, and metal salts thereof; and mold release agents such as paraffin; antioxidants; and the like may be appropriately added.

The epoxy resin composition used for the first semiconductor device of the present invention can be produced by mixing each of the above-mentioned components at ordinary temperature using, for example, a mixer and the like, or after that by melt-kneading the resultant using a kneading machine such as a roll, a kneader, or a extruder, and grinding it after cooling, and in addition, appropriately adjusting degree of dispersion, fluidity, and the like, where necessary.

In the epoxy resin composition used for the first semiconductor device of the present invention, the content ratio of Cl⁻ (chlorine ion) to the total amount of the cured product of the epoxy resin composition is preferably 10 ppm or less, more preferably 5 ppm or less, and further preferably 3 ppm or less. This can achieve more excellent moisture resistance reliability and high temperature operating life. Note that the content ratio of Cl⁻ (chlorine ion) to the total amount of the cured product of the epoxy resin composition can be measured as follows. Specifically, first, the cured product of the epoxy resin composition forming the encapsulating member in the semiconductor device is ground using a grinding mill for 3 minutes, the resultant is sieved using a 200 mesh sieve, and the passed particles are prepared as a sample. The resultant sample 5 g and distilled water 50 g are placed in an autoclave made of Teflon (registered trademark) and the vessel is sealed. The sample is subjected to treatment at a temperature of 125° C. and a relative humidity of 100% RH for 20 hours (pressure cooker treatment). Next, after cooling to room temperature, the extraction water is centrifuged and filtered through a 20 μm filter. The concentration of the chlorine ion is measured using a capillary electrophoresis apparatus (for example, “CAPI-3300” available from Otsuka Electronics Co., Ltd.). The resultant concentration of chlorine ion (unit: ppm) is a value measured for the chlorine ion which is extracted from 5 g of the sample and diluted tenfold. Accordingly, the concentration is converted to the chlorine ion content per unit mass of the resin composition in accordance with the following equation:

Chlorine ion content per unit mass of the sample (unit: ppm)=(Chlorine ion concentration measured by capillary electrophoresis apparatus)×50÷5

<Second Semiconductor Device>

Next, a second semiconductor device of the present invention will be described. The second semiconductor device of the present invention is a semiconductor device comprising a lead frame having a die pad portion or a circuit board, one or more semiconductor elements mounted on the die pad portion of the lead frame or on the circuit board, a copper wire that electrically connects electrical joints provided on the lead frame or the circuit board to an electrode pad provided on the semiconductor element, and an encapsulating member which encapsulates the semiconductor element and the copper wire, wherein the electrode pad provided on the semiconductor element is formed from palladium, and the copper wire has a copper purity of 99.99% by mass or more and an elemental sulfur content of 5 ppm by mass or less.

Use of the electrode pad formed from palladium as the electrode pad of the semiconductor device and wire-bonding by use of the copper wire having a high copper purity and a low elemental sulfur content as described above allow to prevent corrosion at the junction between the electrode pad of the semiconductor element and the copper wire. Consequently, the semiconductor device excellent in high temperature storage life, high temperature operating life, and moisture resistance reliability can provided.

The lead flame or circuit board used in the second semiconductor device of the present invention is not particularly limited, but examples thereof include those as used in the first semiconductor device.

The semiconductor element used in the second semiconductor device of the present invention is not particularly limited as long as comprising an electrode pad formed from palladium. Examples thereof include an integrated circuit, a large scale integrated circuit, a transistor, a thyristor, a diode, a solid state image sensor, and the like.

A conventional semiconductor element provided with the aluminum electrode pad is inferior in corrosion resistance of the aluminum, and especially, has a possibility that pitting corrosion (local corrosion in the form of holes having a size of from a few dozen micron meters to a few dozen millimeters, the local corrosion occurring on the surface of a metal material) due to chlorine ion deriving from the circuit board and/or the encapsulating member and the like; however, the problem arising from corrosion of the electrode pad of the semiconductor element can be avoided by using, as the electrode pad of the semiconductor element, the electrode pad formed from palladium, which is a metal having large ionization energy.

Furthermore, because palladium is harder than aluminum, damage of the circuit under the electrode pad of the semiconductor element can be prevented during bonding by the copper wire which are harder than a conventional gold wire. Additionally, application of junction pressure enough for joining improves junction strength, and thereby, the semiconductor device excellent in high temperature storage life, high temperature operating life, and moisture resistance reliability can be provided. The purity of the palladium used in the electrode pad of the semiconductor element is not particularly limited, but is preferably 99.5% by mass or more.

Such an electrode pad of the semiconductor element formed from palladium can be produced by applying a general method for forming an electrode pad of a semiconductor element, such as the method of forming a general titanium barrier layer on the surface of the copper circuit terminal formed on the lower layer and then depositing, sputtering, or electrolessly plating palladium.

The copper purity of the copper wire used in the second semiconductor device of the present invention is 99.99% by mass or more. In the copper wire containing an element (dopant) other than copper, the ball side configuration of each end of the copper wire is stabilized during bonding, but if the copper purity is less than the above lower limit, the copper wire is too hard because the dopant is too much. Accordingly, the electrode pad of the semiconductor element is damaged during bonding, and thereby there are caused defects of the degradation of the moisture resistance reliability, the degradation of the high temperature storage life, and the decrease in the high temperature operating life, and the like due to insufficient connection. From such viewpoints, the copper purity is preferably 99.999% by mass or more.

The elemental sulfur content of the copper wire is 5 ppm by mass or less. If the elemental sulfur content exceeds the above upper limit, the defects of degradation of the moisture resistance reliability, degradation of the high temperature storage life, and decrease in the high temperature operating life and the like are caused. From such viewpoints, the elemental sulfur content is preferably 1 ppm by mass or less, and more preferably 0.5 ppm by mass or less.

In the second semiconductor device of the present invention, such a copper wire electrically connects the electrical joints provided on the lead frame or circuit board to the electrode pad provided on the semiconductor element and formed from palladium. This allows to prevent corrosion at the junction between the electrode pad of the semiconductor element and the copper wire, and thereby the semiconductor device excellent in high temperature storage life, high temperature operating life, and moisture resistance reliability can be provided.

The wire diameter of the copper wire is not particularly limited, but is preferably 25 μm or less, and more preferably 23 μm or less. If the wire diameter of the copper wire exceeds the above upper limit, there is a tendency that integration degree of the semiconductor device is difficult to increase. Additionally, from the viewpoints of stabilization of the ball configuration of each end of the copper wire and improvement of the connection reliability of the junction part, the wire diameter of the copper wire is preferably 18 μm or more.

The wire used in the second semiconductor device of the present invention can be obtained by casting a copper alloy in a melting furnace, milling an ingot thereof using a roll, wire-drawing the resultant using a die, and performing post-heat treatment in which the wire is heated with continuous sweep.

In the second semiconductor device of the present invention, the semiconductor element and the copper wire are encapsulated by an encapsulating member. The encapsulating member used is not particularly limited as long as one which is used as an encapsulating member for the general semiconductor devices. Example thereof includes the cured product of an epoxy resin composition comprising an epoxy resin, a curing agent, and an inorganic filler, and where necessary, a corrosion inhibitor, a curing accelerator, and the like.

Examples of the epoxy resins used for the second semiconductor device of the present invention include those like epoxy resins used for the first semiconductor of the present invention. They may be used singly or in combination of two or more. Among such epoxy resins, from the viewpoints that the warpage of the semiconductor device in which the encapsulating member is formed only on a single side of the lead frame or circuit board on which the semiconductor element is mounted (hereinafter referred to as a “single-sided encapsulated semiconductor device”) is reduced, that the corrosion of the copper wire on the electrode pad portion of the semiconductor element is prevented, and that the moisture resistance reliability of the semiconductor device is improved, preferred are epoxy resins represented by the following formula (6):

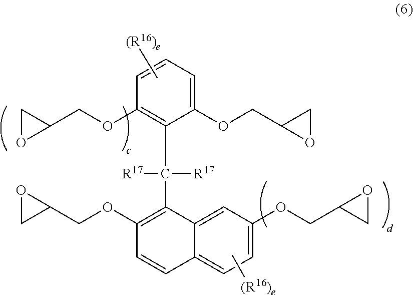

[in the formula (6), R¹⁶ represents a hydrogen atom or a hydrocarbon group having 1 to 4 carbon atoms and may be the same or different when there are a plurality of R¹⁶, R¹⁷'s each independently represent a hydrogen atom or a hydrocarbon group having 1 to 4 carbon atoms, c and d are each independently 0 or 1, and e is an integer of from 0 to 6],

epoxy resins represented by the following formula (9):

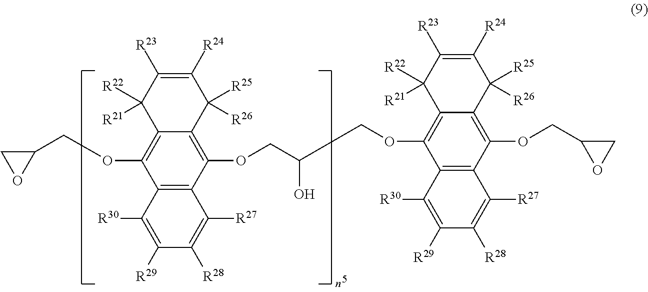

[in the formula (9), R²¹ to R³⁰ each independently represent a hydrogen atom or an alkyl group having 1 to 6 carbon atoms, and n⁵ is an integer of from 0 to 5],

epoxy resins represented by the following formula (10):

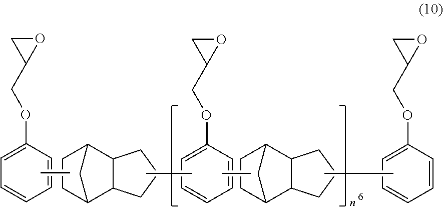

[in the formula (10), n⁶ represents a polymerization degree and an average value thereof is a positive number of from 0 to 4], and

epoxy resins represented by the following formula (5):

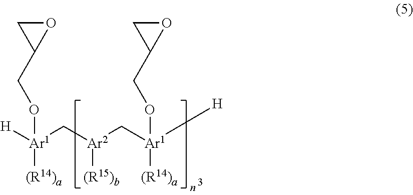

[in the formula (5), Ar¹ represents a phenylene group or a naphthylene group, a binding position of the glycidyl ether groups may be α-position or β-position when Ar¹ is the naphthylene group, Ar² represents a phenylene group, a biphenylene group, or a naphthylene group, R¹⁴ and R¹⁵ each independently represent a hydrocarbon group having 1 to 10 carbon atoms, a is an integer of from 0 to 5, b is an integer of from 0 to 8, and n³ represents a polymerization degree and an average value thereof is a positive number between 1 and 3 both inclusive],
and from the viewpoint that the linear expansion coefficient al of the encapsulating member decreases and thus the warpage of the single-sided encapsulated semiconductor device is reduced, more preferred are the epoxy resins represented by the formula (5) wherein Ar² is the naphthylene group.

Additionally, from the viewpoint of the curability of the epoxy resin composition, preferred are those having an epoxy equivalent between 100 g/eq and 500 g/eq both inclusive, and from the viewpoints of low viscosity and excellent fluidity, more preferred are epoxy resins represented by the following formula (3):

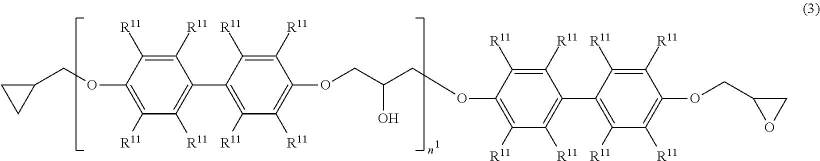

[in the formula (3), a plurality of R¹¹ each independently represent a hydrogen atom or a hydrocarbon group having 1 to 4 carbon atoms, and n¹ represents a polymerization degree and an average value thereof is 0 or a positive number of 5 or less], and epoxy resins represented by the following formula (4):

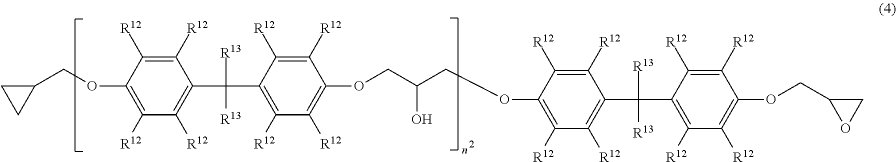

[in the formula (4), a plurality of R¹² and R¹² each independently represent a hydrogen atom or a hydrocarbon group having 1 to 4 carbon atoms, and n² represents a polymerization degree and an average value thereof is 0 or a positive number of 5 or less].

The epoxy resins represented by the formulas (3), (4), (5), (6), (9) and (10) may be each used in combination with another epoxy resin. From the viewpoint that the effects described above can be achieved together, it is especially preferred to use at least one epoxy resin selected from the group consisting of those represented by the formulas (5), (6), (9) and (10), and at least one epoxy resin selected from the group consisting of those represented by the formulas (3) and (4) in combination.

In the epoxy resin composition used for the second semiconductor device of the present invention, the content ratio of the epoxy resin is preferably between 3% by mass and 15% by mass both inclusive, and more preferably between 5% by mass and 13% by mass both inclusive, based on the total amount of the epoxy resin composition. If the content ratio of the epoxy resin is less than the above lower limit, the solder resistance of the encapsulating member tends to decrease. On the other hand, if the content ratio exceeds the above upper limit, the solder resistance of the encapsulating member and the fluidity of the epoxy resin composition tend to decrease.

The content ratio of the at least one epoxy resin selected from the group consisting of those represented by the formulas (5), (6), (9) and (10) is preferably 20% by mass or more, more preferably 30% by mass or more, and especially preferably 50% by mass or more, based on the total amount of the epoxy resin composition. If the content ratio of such an epoxy resin is less than the above lower limit, the warpage of the single-sided encapsulated semiconductor device tends to be easily caused.

Furthermore, the content ratio of the at least one epoxy resin selected from the group consisting of those represented by the formulas (3) and (4) is preferably 15% by mass or more, more preferably 30% by mass or more, and especially preferably 50% by mass or more, based on the total amount of the epoxy resin composition. If the content ratio of such an epoxy resin is less than the above lower limit, there are tendencies that the fluidity of the epoxy resin composition decreases and that the inorganic filler is difficult to be highly filled.

Especially, when the at least one epoxy resin selected from the group consisting of those represented by the formulas (5), (6), (9) and (10), and the at least one epoxy resin selected from the group consisting of those represented by the formulas (3) and (4) are used in combination, the content ratio of the former epoxy resin is preferably between 20% by mass and 85% by mass both inclusive, more preferably between 30% by mass and 70% by mass both inclusive, and especially preferably between 40% by mass and 60% by mass both inclusive, based on the total amount of these epoxy resins. If the content ratio of the former epoxy resin is less than the above lower limit, the warpage of the single-sided encapsulated semiconductor device tends to be easily caused. On the other hand if the content ratio exceeds the above upper limit, there are tendencies that the fluidity of the epoxy resin composition decreases and that the inorganic filler is difficult to be highly filled.

The epoxy resin composition used for the second semiconductor device of the present invention comprises a curing agent. Such a curing agent is not particularly limited as long as reacting with the epoxy resin to form a cured product. For example, any of polyaddition type, catalyst type, and condensation type curing agents can be used. Examples of the polyaddition type, catalyst type, and condensation type curing agents used for the second semiconductor device of the present invention include those like the polyaddition type, catalyst type, and condensation type curing agents used for the first semiconductor device of the present invention, respectively.

Among them, the phenol resin-based curing agents are preferred from the viewpoint of the balance among flame resistance, moisture resistance, electric characteristics, curability, storage stability and the like. Examples of the phenol resin-based curing agents include those like the phenol resin-based curing agents used for the first semiconductor device of the present invention. They may be used singly or in combination of two or more.

Among such phenol resin-based curing agents, preferred are phenol resins represented by the following formula (7):

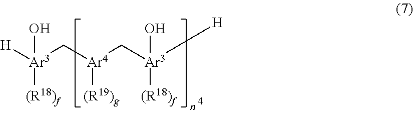

[in the formula (7), Ar³ represents a phenylene group or a naphthylene group, a binding position of the hydroxyl groups may be α-position or β-position when Ar³ is the naphthylene group, Ar⁴ represents a phenylene group, a biphenylene group, or a naphthylene group, R¹⁸ and R¹⁹ each independently represent a hydrocarbon group having 1 to 10 carbon atoms, f is an integer of from 0 to 5, g is an integer of from 0 to 8, and an average value of n⁴ is a positive number between 1 and 3 both inclusive]
from the viewpoints that the warpage of the single-sided encapsulated semiconductor device is reduced, that the corrosion of the copper wire on the electrode pad portion of the semiconductor element is prevented, and that the moisture resistance is reliability improved; and more preferred are phenol resins represented by the formula (7) wherein Ar⁴ is a naphthylene group from the viewpoint that the linear expansion coefficient al of the encapsulating member decreases and thus the warpage of the single-sided encapsulated semiconductor device is reduced.

Additionally, from the viewpoint of the curability of the epoxy resin composition, preferred are those having a hydroxyl equivalent between 90 g/eq and 250 g/eq both inclusive, and from the viewpoint that the epoxy resin composition having low viscosity and excellent fluidity can be obtained, more preferred are phenol novolac resins and the dicyclopentadiene type phenol resins represented by the following formula (11):

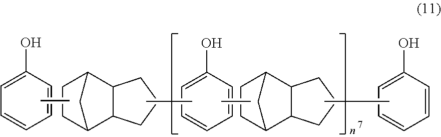

[in the formula (11), n⁷ represents a polymerization degree and an average value thereof is 0 or a positive number of 4 or less].

The phenol resins represented by the formula (7), the phenol novolac resins described above, and the dicyclopentadiene type phenol resins represented by the formula (11) may be each used in combination with another curing agent. From the viewpoint that both effects described above can be achieved together, it is especially preferred to use at least one curing agent selected from the group consisting of the phenol resins represented by the formula (7) and at least one curing agent selected from the group consisting of the phenol novolac resins and the dicyclopentadiene type phenol resins represented by the formula (11) in combination.

In the epoxy resin composition used for the second semiconductor device of the present invention, the content ratio of the curing agent is preferably between 0.8% by mass and 10% by mass both inclusive, and more preferably between 1.5% by mass and 8% by mass both inclusive, based on the total amount of the epoxy resin composition. If the content ratio of the curing agent is less than the above lower limit, the fluidity of the epoxy resin composition tends to decrease. On the other hand, if the content ratio exceeds the above upper limit, the solder resistance of the encapsulating member tends to decrease.

The content ratio of the phenol resin represented by the formula (7) is preferably 20% by mass or more, more preferably 30% by mass or more, and especially preferably 50% by mass or more, based on the total amount of the curing agent. If the content ratio of the phenol resin is less than the above lower limit, the warpage of the single-sided encapsulated semiconductor device tends to be easily caused.

The content ratio of the phenol novolac resin or the dicyclopentadiene type phenol resin represented by the formula (11) is preferably 20% by mass or more, more preferably 30% by mass or more, and especially preferably 50% by mass or more, based on the total amount of the curing agent. If the content ratio of the phenol resin is less than the lower above limit, the fluidity of the epoxy resin composition tends to decrease.

Especially, when at least one curing agent selected from the phenol resins represented by the formula (7) and at least one curing agent selected from the phenol novolac resins and the dicyclopentadiene type phenol resins represented by the formula (11) are used in combination, the content ratio of the phenol resin represented by the formula (7) is preferably between 20% by mass and 80% by mass both inclusive, more preferably between 30% by mass and 70% by mass both inclusive, and especially preferably between 40% by mass and 60% by mass both inclusive, based on the total amount of these curing agents. If the content ratio of the phenol resin represented by the formula (7) is less than the above lower limit, the warpage of the single-sided encapsulated semiconductor device tends to be easily caused. On the other hand, if the content ratio is more than the upper limit, the fluidity of the epoxy resin composition tends to decrease.

In the second semiconductor device of the present invention, when the phenol resin-based curing agent is used as the curing agent, the blend ratio of the epoxy resin to the phenol resin-based curing agent is preferably an equivalent ratio of the number of the epoxy groups (EP) of the overall epoxy resin to the number of the phenolic hydroxyl groups (OH) of the overall phenol resin-based curing agent i.e., (EP)/(OH), between 0.8 and 1.3 both inclusive. If the equivalent ratio is less than the above lower limit, the curability of the epoxy resin composition tends to decrease. On the other hand, if the equivalent ratio exceeds the above upper limit, the physical properties of the encapsulating member tend to degrade.

In the second semiconductor device of the present invention, use of the particular epoxy resin and curing agent as described above allows to reduced the warpage of the single-sided encapsulated semiconductor device. Additionally, the separation at the junction between the electrode pad of the semiconductor element and the copper wire caused by this warpage can be prevented, and thereby the corrosion resistance at the junction can be improved. However, even when the single-sided encapsulated semiconductor device has the reduced warpage, if the electrode pad of the semiconductor element is stressed during wire-bonding, the coming-off occurs at the junction between the electrode pad and the copper wire, and thereby the corrosion of the junction may be caused.

Therefore, in the epoxy resin composition used for the second semiconductor device of the present invention, it is preferred to comprise at least one corrosion inhibitor selected from the group consisting of compounds containing an elemental calcium and compounds containing an elemental magnesium, for the purpose of further preventing such corrosion of the junction, especially the corrosion of the palladium electrode pad of the semiconductor element.

Examples of such a compound containing an elemental calcium include calcium carbonate, calcium borate, calcium metasilicate, and the like. Among them, preferred are the calcium carbonate from the viewpoints of the content of impurity, the water resistance, and the low water absorption ratio, and more preferred are precipitated calcium carbonate synthesized by a carbon dioxide gas reaction method.

Meanwhile, examples of the compound containing an elemental magnesium include hydrotalcites, magnesium oxide, magnesium carbonate and the like. Among them, from the viewpoints of the content of impurity and the low water absorption ratio, preferred are the hydrotalcites represented by the following formula (8):

M_{α}Al_{β}(OH)_{2α+3β-2γ}(CO₃)_{γ}·δH₂O (8)

[in the formula (8), M represents a metallic element comprising at least Mg; α, β and γ are numbers meeting conditions of 2≦α≦8, 1≦β≦3, and 0.5≦γ≦2, respectively; and δ is an integer of 0 or more].
Examples of the concrete hydrotalcite include Mg₆Al₂ (OH)₁₆(CO₃).mH₂O, Mg₃ZnAl₂(OH)₁₂(CO₃).mH₂O, and the like.

In addition, among the hydrotalcites represented by the formula (8), more preferred are those having a mass loss ratio A (% by mass) at 250° C. and a mass loss ratio B (% by mass) at 200° C., as measured by a thermogravimetric analysis, which meet a condition represented by following formula (I):

A−b≦5% by mass (I)

and further preferred are those having a mass loss ratio A and a mass loss ratio B which meet a condition represented by the following formula (Ia):

A−B≦4% by mass (Ia)

If the difference between the mass loss ratios (A−B) exceeds the above upper limit, because of too much interlayer water, there is a tendency that an ionic impurity cannot be sufficiently trapped and thus the moisture and heat resistance of the semiconductor device cannot be sufficiently improved. Note that the mass loss ratio can be measured, for example, by heating the hydrotalcite in a nitrogen atmosphere at a rate of temperature rise of 20° C./min and conducting the thermogravimetric analysis.

In the epoxy resin composition used for the second semiconductor device of the present invention, the content ratio of the corrosion inhibitor is preferably between 0.01% by mass and 2% by mass both inclusive based on the total amount of the epoxy resin composition. If the content ratio of the corrosion inhibitor is less than the above lower limit, the effects of the addition of the corrosion inhibitor are not sufficiently achieved, and especially, there is a tendency that the corrosion of palladium electrode pad of the semiconductor element cannot be prevented. Consequently, the moisture resistance reliability of the semiconductor device tends to degrade. On the other hand, if the content ratio exceeds the above upper limit, there is a tendency that the moisture absorption ratio increases and the solder crack resistance decreases. Especially when the calcium carbonate or hydrotalcite is used as the corrosion inhibitor, from the same viewpoints as above, the content ratio is preferably between 0.05% by mass and 2% by mass both inclusive based on the total amount of the epoxy resin composition.

The epoxy resin composition used for the second semiconductor device of the present invention preferably comprises an inorganic filler. Examples of such an inorganic filler include those like the inorganic fillers used for the first semiconductor device of the present invention. These fillers may be used singly or in combination of two or more. Among them, the fused silica is especially preferred from the viewpoints of the excellent moisture resistance and the ability of further decreasing the linear expansion coefficient. The shape of the inorganic filler is not particularly limited. For example, any of crashed and spherical fillers can be used. From the viewpoint of improvement of fluidity, however, it is preferred that the filler has as high sphericity as possible and has a broad particle size distribution, and fused spherical silica is especially preferred. Furthermore, the inorganic filler may be surface-treated with a coupling agent or may be previously treated with an epoxy or phenol resin. Examples of such a treatment method include the method in which the inorganic filler is mixed with the coupling agent or the epoxy or phenol resin using a solvent and then the solvent is removed, the method in which the coupling agent or the epoxy or phenol resin is directly added to the inorganic filler and the mixing treatment is carried out using a mixer, and the like.

A particle diameter of the filler used for the second semiconductor device of the present invention is, in a mode diameter equivalent, preferably between 30 μm and 50 μm both inclusive, and more preferably between 35 μm and 45 μm both inclusive. The use of the filler having the mode diameter within the above range allows to apply the present invention to a semiconductor device having a narrow wire pitch. The content ratio of coarse particles having a diameter of 55 μm or more is preferably 0.2% by mass or less, and more preferably 0.1% by mass or less. When the content of the coarse particle is within the above range, the defect that the coarse particles are sandwiched between the wires and push down the wires, i.e., wire sweep, can be prevented. Such a filler having a predetermined particle size distribution can be the commercial filler as it is, or can be obtained by mixing the plural kinds of the fillers or sieving the filler.

In the epoxy resin composition used for the second semiconductor device of the present invention, the content ratio of the filler is preferably between 84% by mass and 92% by mass both inclusive, and more preferably between 87% by mass and 89% by mass both inclusive, based on the total amount of the epoxy resin composition. If the content ratio of the filler is less than the above lower limit, the solder resistance of the encapsulating member tends to decrease. On the other hand, if the content ratio exceeds the above upper limit, the fluidity of the epoxy resin composition may decrease, whereby the insufficient filling during molding may be caused or defect such as wire sweep in the semiconductor device due to rise in viscosity may be caused.

A curing accelerator is preferably added to the epoxy resin composition used for the second semiconductor device of the present invention. Examples of such a curing accelerator include those like the curing accelerators used for the first semiconductor device of the present invention. The content ratio of the curing accelerator is also the same as one described for the first semiconductor device of the present invention.

Additionally, in the epoxy resin composition used for the second semiconductor device of the present invention, where further necessary, various additives such as inorganic ion exchangers, coupling agents, coloring agents, components for reducing stress, mold release agents, and antioxidants may be appropriately added in the same way as in the case of the first semiconductor device of the present invention.

The epoxy resin composition used for the second semiconductor device of the present invention can be produced by mixing each of the above-mentioned components at ordinary temperature, melt-kneading them, or the like in the same manner as in the case of the first semiconductor device of the present invention.

A glass transition temperature (Tg) of the cured product of the epoxy resin composition used for the second semiconductor device of the present invention is preferably between 135° C. and 175° C. both inclusive. If the Tg of the cured product is less than the above lower limit, there is a tendency that the heat resistance of the resin is reduced and thereby the high temperature storage life is degraded. On the other hand, if the Tg exceeds the above upper limit, there is a tendency that the water absorption ratio is reduced and thereby the moisture resistance reliability is degraded.

A linear expansion coefficient α1 of the cured product is preferably between 7 ppm/° C. and 11 ppm/° C. both inclusive in the temperature range not exceeding the glass transition temperature of the cured product. When the linear expansion coefficient α1 is within the above range, reduced is the warpage caused by the difference between the linear expansion ratios of the cured product and the lead frame or circuit board in the single-sided encapsulated semiconductor device, and additionally reduction of the stress applied on the wire bonding portion of the lead frame or on the electrode pad of the circuit board tends to enhance the connection reliability, especially the high temperature storage life and moisture resistance reliability.

The second semiconductor device of the present invention comprises the lead frame having the die pad portion or the circuit board, the semiconductor element mounted on the die pad portion of the lead frame or on the circuit board, the copper wire that electrically connects the electrical joints provided on the lead frame or the circuit board to the electrode pad provided on the semiconductor element, and the encapsulating member which encapsulates the semiconductor element and the copper wire. The configuration thereof includes one like the configuration of the first semiconductor device of the present invention.

<Third Semiconductor Device>

Next, a third semiconductor device of the present invention will be described. The third semiconductor device of the present invention comprises a lead frame having a die pad portion or a circuit board, one or more semiconductor elements mounted on the die pad portion of the lead frame or on the circuit board, a copper wire that electrically connects electrical joints provided on the lead frame or the circuit board to an electrode pad provided on the semiconductor element, and an encapsulating member which encapsulates the semiconductor element and the copper wire, wherein the electrode pad provided on the semiconductor element has a thickness of 1.2 μm or more; the copper wire has a copper purity of 99.999% by mass or more, an elemental sulfur content of 5 ppm by mass or less, and an elemental chlorine content of 0.1 ppm by mass or less; the encapsulating member has a glass transition temperature between 135° C. and 190° C. both inclusive, and the encapsulating member has a linear expansion coefficient between 5 ppm/° C. and 9 ppm/° C. both inclusive in a temperature range not exceeding the glass transition temperature.

The wire-bonding on the electrode pad having a thickness of 1.2 μm or more which are provided on the semiconductor element by use of the copper wire having high purity, low elemental sulfur content, and low elemental chlorine content, and the subsequent encapsulation by use of the encapsulating member having a predetermined glass transition temperature and linear expansion coefficient allow to provide the semiconductor device excellent in temperature cycle property, high temperature storage life, high temperature operating life, and moisture resistance reliability without damaging the electrode pad and a low dielectric insulating film of the semiconductor device.

The lead frame or circuit board used in the third semiconductor device of the present invention is not particularly limited. Examples thereof include those as used in the first semiconductor device of the present invention.

Examples of the semiconductor element used in the third semiconductor device of the present invention include those provided with an electrode pad having a thickness of 1.2 μm or more, such as, for example, an integrated circuit, a large scale integrated circuit, a transistor, a thyristor, a diode, a solid state image sensor, and the like. Examples of the material for the electrode pad of the semiconductor element include aluminum, palladium, copper, gold, and the like. Such a electrode pad of the semiconductor element can be formed on the surface of the semiconductor element by, for example, depositing a metal, which is a material, in a thickness of 1.2 μm or more.

Among such semiconductor elements described above, the semiconductor element provided with the low dielectric insulating film are preferred for the third semiconductor device of the present invention. Because the low dielectric insulating film has low mechanical strength, as described above, in the semiconductor element provided with the low dielectric insulating film, it is necessary to ensure that the impact during wire-bonding is not transmitted to the low dielectric insulating film by increasing the thickness of the electrode pad or the like. In the third semiconductor device of the present invention, even if the thickness of the electrode pad of the semiconductor device is increased, the high temperature storage life, high temperature operating life, and moisture resistance reliability can be improved without damaging the electrode pad and the low dielectric insulating film. Thus, the present invention can be suitably applied to a semiconductor device which is formed by the semiconductor element provided with the low dielectric insulating film. Note that the low dielectric insulating film used for the third semiconductor device of the present invention is called a low-K insulating film, which is generally an interlayer insulating film having a specific dielectric constant between 2.2 and 3.0 both inclusive. Examples of such a low dielectric insulating film include SiOF, SiOC, and PAE (polyarylene ether) films and the like.

The copper purity of the copper wire used in the third semiconductor device of the present invention is 99.999% by mass or more. In the copper wire containing an element (dopant) other than copper, the ball side configuration of each end of the copper wire is stabilized during bonding, but if the copper purity is less than the above lower limit, the copper wire is too hard because the dopant is too much. Accordingly, an open defect is caused at the junction part in the HAST test (Highly Accelerated Stress Test), and thus the moisture resistance reliability degrades.

The elemental sulfur content of the copper wire is 5 ppm by mass or less. If the elemental sulfur content exceeds the above upper limit, the electrode pad of the semiconductor element are damaged, and thereby there are caused defects of the degradation of the moisture resistance reliability, the degradation of the high temperature storage life, the decrease in the high temperature operating life, and the like due to insufficient connection. From such viewpoints, the elemental sulfur content is preferably 1 ppm by mass or less, and more preferably 0.5 ppm by mass or less.

Additionally, the elemental chlorine content of the copper wire is 0.1 ppm by mass or less. If the elemental chlorine content exceeds the above upper limit, there are caused defects of the degradation of the moisture resistance reliability, the degradation of the high temperature storage life, and the decrease in the high temperature operating life, and the like. From such viewpoints, the elemental sulfur content is preferably 0.09 ppm by mass or less.

In the third semiconductor device of the present invention, the electrical joints provided on the lead frame or circuit board are electrically connected to the electrode pad having a thickness of 1.2 μm or more which is provided on the semiconductor element by use of the copper wire described above. Accordingly, the connection defect at the junction between the electrode pad of the semiconductor element and the copper wire can be prevented, and thereby the semiconductor device excellent in high temperature storage life, high temperature operating life, and moisture resistance reliability can be provided.

The wire diameter of the copper wire is not particularly limited, but is preferably 25 μm or less, and more preferably 23 μm or less. If the wire diameter of the copper wire is more than the above upper limit, there is a tendency that integration degree of the semiconductor device is difficult to be improved. From the viewpoints of rise in resistance value, degradation of the high temperature storage life and high temperature operating life, and wire sweep due to the smaller junction area, the wire diameter of the copper wire is preferably 18 μm or more.

The copper wire used in the third semiconductor device of the present invention can be obtained by the method like those for producing the copper wire used in the second semiconductor device of the present invention.

In the third semiconductor device of the present invention, the semiconductor element and the copper wire are encapsulated by an encapsulating member. The encapsulating member used has a glass transition temperature (Tg) between 135° C. and 190° C. both inclusive. If the Tg of the encapsulating member is less than the above lower limit, the temperature cycle property, high temperature storage life, high temperature operating life, and the moisture resistance reliability of the semiconductor device degrade. On the other hand, if the Tg exceeds the above upper limit, the moisture resistance reliability and high temperature operating life of the semiconductor device degrade. From such viewpoints, the Tg of the encapsulating member is preferably between 140° C. and 185° C. both inclusive.

Further, a linear expansion coefficient al of the encapsulating member used in the third semiconductor device of the present invention is between 5 ppm/° C. and 9 ppm/° C. both inclusive in a temperature range not exceeding the glass transition temperature. If the linear expansion coefficient α1 is less than the above lower limit, the warpage at room temperature of the semiconductor device in which the encapsulating member is formed only on a single side of the lead frame or circuit board on which the semiconductor element is mounted (hereinafter referred to as a “single-sided encapsulated semiconductor device”) increases to stress the semiconductor element, and thereby the high temperature storage life and high temperature operating life degrade. On the other hand, if the linear expansion coefficient exceeds the above upper limit, the stress due to the difference from the coefficient of the semiconductor element causes separation and cracking in a temperature cycle test.

In the third semiconductor device of the present invention, the encapsulating members used for conventional semiconductor devices can be used as long as having a glass transition temperature and a linear expansion coefficient al which are within the ranges described above. Example of such a encapsulating member includes a cured product of an epoxy resin composition comprising an epoxy resin, a curing agent, and an inorganic filler, and where necessary, a corrosion inhibitor, a curing accelerator, and the like.

Examples of the epoxy resin used for the third semiconductor device of the present invention include those like the epoxy resins used for the first semiconductor device of the present invention. They may be used singly or in combination of two or more. Among such epoxy resins, from the viewpoint of the curability of the epoxy resin composition, preferred are those having an epoxy equivalent between 100 g/eq and 500 g/eq both inclusive.

In the epoxy resin composition for the third semiconductor device of the present invention, the content ratio of the epoxy resin is preferably between 3% by mass and 15% by mass both inclusive, and more preferably between 5% by mass and 13% by mass both inclusive, based on the total amount of the epoxy resin composition. If the content ratio of the epoxy resin is less than the above lower limit, the solder resistance of the encapsulating member tends to decrease. On the other hand, if the content ratio exceeds the above upper limit, the solder resistance of the encapsulating member and the fluidity of the epoxy resin composition tend to decrease.

The epoxy resin composition used for the third semiconductor device of the present invention comprises a curing agent. Such a curing agent is not particularly limited as long as reacting with the epoxy resin to form a cured product. For example, any of polyaddition type, catalyst type, and condensation type curing agents can be used. Examples of the polyaddition type, catalyst type, and condensation type curing agents used for the third semiconductor device of the present invention include those like the polyaddition type, catalyst type, and condensation type curing agents used for the first semiconductor device of the present invention, respectively.

Among them, the phenol resin-based curing agents are preferred from the viewpoint of the balance among flame resistance, moisture resistance, electric characteristics, curability, storage stability and the like. Examples of the phenol resin-based curing agents include those like the phenol resin-based curing agents used for the first semiconductor device of the present invention. They may be used singly or in combination of two or more. Among such curing agents, from the viewpoint of the curability of the epoxy resin composition, preferred are those having a hydroxyl equivalent between 90 g/eq and 250 g/eq both inclusive.

In the epoxy resin composition used for the third semiconductor device of the present invention, the content ratio of the curing agent is preferably between 0.8% by mass and 10% by mass both inclusive, and more preferably between 1.5% by mass and 8% by mass both inclusive, based on the total amount of the epoxy resin composition. If the content ratio of the curing agent is less than the above lower limit, the fluidity of the epoxy resin composition tends to decrease. On the other hand, if the content ratio exceeds the above upper limit, the solder resistance of the encapsulating member tends to decrease.

In the third semiconductor device of the present invention, when the phenol resin-based curing agent is used as the curing agent, the blend ratio of the epoxy resin to the phenol resin-based curing agent is preferably an equivalent ratio of the number of the epoxy groups (EP) of the overall epoxy resin to the number of the phenolic hydroxyl groups (OH) of the overall phenol resin-based curing agent, i.e., (EP)/(OH), between 0.8 and 1.3 both inclusive. If the equivalent ratio is less than the above lower limit, the curability of the epoxy resin composition tends to decrease. On the other hand, if the equivalent ratio exceeds the above upper limit, the physical properties of the encapsulating member tend to degrade.

The epoxy resin composition used for the third semiconductor device of the present invention preferably comprises an inorganic filler. Examples of such an inorganic filler include those like the inorganic fillers used for the first semiconductor device of the present invention. They may be used singly or in combination of two or more. Among them, the fused silica is preferred from the viewpoint of the excellent moisture resistance and the ability of further decreasing the linear expansion coefficient. The shape of the inorganic filler is not particularly limited. For example, any of crashed and spherical fillers can be used. From the viewpoint that the content of the fillers in the epoxy resin composition can be increased and thus the melt viscosity of the epoxy resin composition can be prevented from rising, preferred are those having a spherical shape, and especially preferred is fused spherical silica. Furthermore, the inorganic filler may be surface-treated with a coupling agent or may be previously treated with an epoxy or phenol resin. Examples of such a treatment method include the method in which the inorganic filler is mixed with the coupling agent or the epoxy or phenol resin using a solvent and then the solvent is removed, the method in which the coupling agent or the epoxy or phenol resin is directly added to the inorganic filler and the mixing treatment is carried out using a mixer, and the like.

A particle diameter of the filler used for the third semiconductor device of the present invention is, in a mode diameter equivalent, preferably between 8 μm and 50 μm both inclusive, and more preferably between 10 μm and 45 μm both inclusive. The use of the filler having the mode diameter within the above range allows to apply the present invention to a semiconductor device having a narrow wire pitch. The content ratio of coarse particles having a diameter of 55 μm or more is preferably 0.2% by mass or less, and more preferably 0.1% by mass or less. When the content of the coarse particles is within the above range, the defect that the coarse particles are sandwiched between the wires and push down the wires, i.e., wire sweep, can be prevented. Such a filler having a predetermined particle size distribution can be the commercial filler as it is or can be obtained by mixing the plural kinds of the fillers or sieving the fillers.

Additionally, in the third semiconductor device of the present invention, the filler having the particle size as described above is preferably used in combination with a fine filler having an average particle diameter between 0.1 μm and 1 μm both inclusive. This allows to increase the content ratio of the fillers without decreasing the fluidity of the epoxy resin composition.

In the epoxy resin composition used for the third semiconductor device of the present invention, the content ratio of the inorganic filler is preferably between 87% by mass and 92% by mass both inclusive, and more preferably between 88.5% by mass and 90% by mass both inclusive, based on the total amount of the epoxy resin composition. If the content ratio of the filler is less than the above lower limit, the temperature cycle property and moisture resistance reliability tend to decrease. On the other hand, if the content ratio exceeds the above upper limit, the fluidity of the epoxy resin composition decreases, and thereby the insufficiently filling during molding or the defect such as wire sweep in the semiconductor device due to rise in viscosity may be caused.

A curing accelerator is preferably added to the epoxy resin composition used for the third semiconductor device of the present invention. Examples of such a curing accelerator include those like the curing accelerator used for the first semiconductor device of the present invention. The content ratio of the curing accelerators is also the same as one described for the first semiconductor device of the present invention.

Additionally, in the epoxy resin composition used for the third semiconductor device of the present invention, where further necessary, various additives such as inorganic ion exchangers, coupling agents, coloring agents, components for reducing stress, mold release agents, and antioxidants may be appropriately added, in the same way as in the case of the first semiconductor device of the present invention.

The epoxy resin composition used for the third semiconductor device of the present invention can be produced by mixing each of the above-mentioned components at ordinary temperature, melt-kneading them, or the like in the same manner as in the case of the first semiconductor device of the present invention.

The third semiconductor device of the present invention comprises the lead frame having the die pad portion or the circuit board, the semiconductor element mounted on the die pad portion of the lead frame or on the circuit board, the copper wire that electrically connects the electrical joints provided on the lead frame or the circuit board to the electrode pad provided on the semiconductor element, and the encapsulating member which encapsulates the semiconductor element and the copper wire. The configuration thereof includes one like the configuration of the first semiconductor device of the present invention.

### <Configuration and Production Method of Semiconductor Device>

The first, second and third semiconductor devices of the present invention each comprise the lead frame having the die pad portion or the circuit board, the semiconductor element mounted on the die pad portion of the lead frame or on the circuit board, the copper wire that electrically connects the electrical joints provided on the lead frame or circuit board to the electrode pad provided on the semiconductor element, and the encapsulating member which encapsulates the semiconductor element and the copper wire. The configuration thereof can be any one of the conventionally-known semiconductor devices, such as a dual inline package (DIP), plastic leaded chip carrier (PLCC), quad flat package (QFP), low profile quad flat package (LQFP), small outline J-lead package (SOJ), thin small outline package (TSOP), thin quad flat package (TQFP), tape carrier package (TCP), ball grid array (BGA), chip size package (CSP), quad flat non-leaded package (QFN), small outline non-leaded package (SON), lead frame-BGA (LF-BGA), and mold array package type BGA (MAP-BGA).

FIG. 1 is a cross sectional view showing an example of the first, second and third semiconductor devices (QFN) of the present invention, which are each obtained by encapsulating the semiconductor element mounted on the die pad of the lead frame. On a die pad 3a of a lead frame 3, a semiconductor element 1 is fixed with use of a cured die bonding material 2. An electrode pad 6 of the semiconductor element 1 and a wire bonding portion 3b of the lead frame 3 are electrically connected by a copper wire 4. An encapsulating member 5 is formed, for example, from the cured product of the epoxy resin composition described above, and this encapsulating member 5 is formed substantially only on the single side of the die pad 3a of the lead frame 3 on which the semiconductor element 1 is mounted. Furthermore, a single semiconductor element 1 may be mounted on the die pad 3 of the lead frame 3 as shown in FIG. 1, or two or more semiconductor elements 1 may be mounted in parallel or in a stack (not shown).

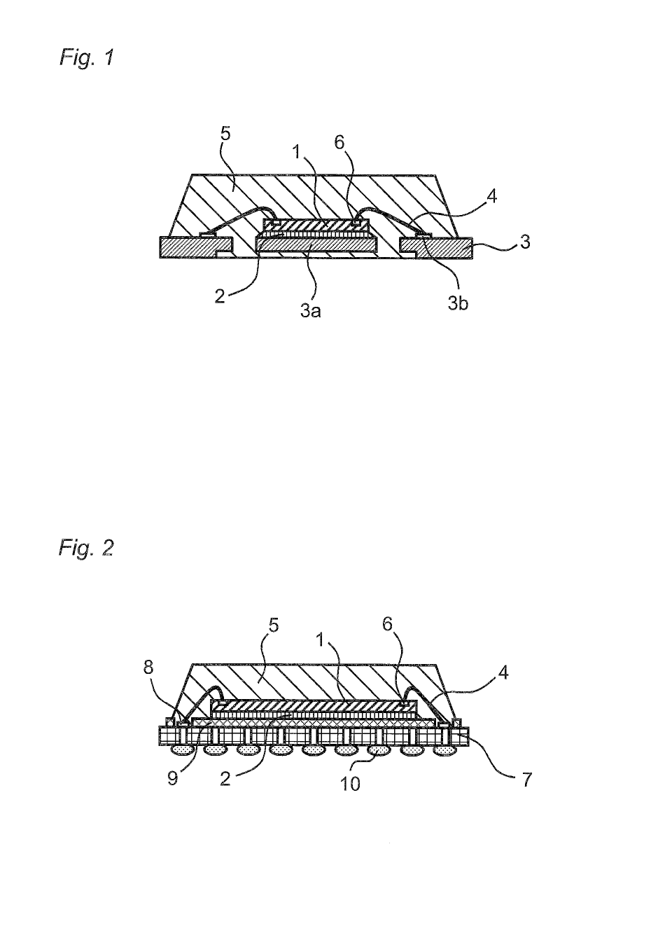

FIG. 2 is a cross sectional view showing another example of the first, second and third semiconductor devices (BGA) of the present invention, which are each obtained by encapsulating the semiconductor element mounted on the circuit board. On a circuit board 7, a semiconductor element 1 is fixed with use of a cured die bonding material 2. The reference number 9 denotes a solder mask. An electrode pad 6 of the semiconductor element 1 and an electrode pad 8 on the circuit board 7 are electrically connected by a copper wire 4. An encapsulating member 5 is formed, for example, from the cured product of the epoxy resin composition described above. This encapsulating member 5 is formed only on the single side of the circuit board 7 on which the semiconductor element 1 is mounted, and on the opposite side, solder balls 10 are formed. The solder ball 10 is electrically connected to the electrode pad 8 on the circuit board 7, inside the circuit board 7. Furthermore, a single semiconductor element 1 may be mounted on the circuit board 7 as shown in FIG. 2, or two or more semiconductor elements 1 may be mounted in parallel or in a stack (not shown).

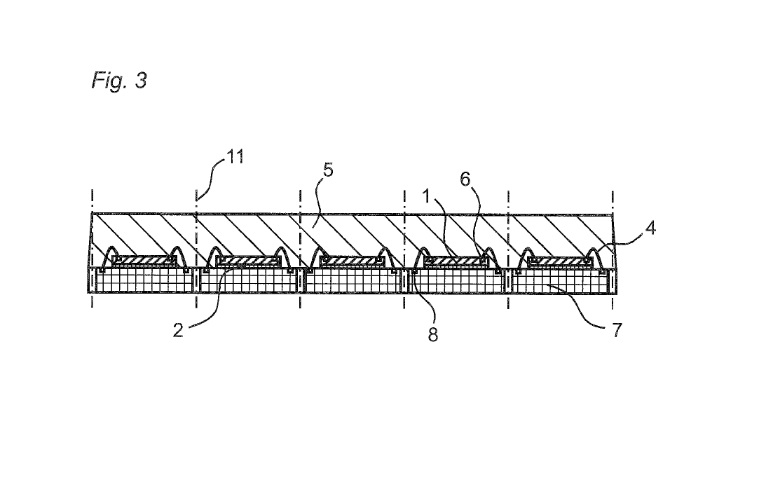

FIG. 3 is a cross sectional view showing the schema of still another example of the first, second and third semiconductor devices (MAP type BGA) of the present invention, which are obtained by encapsulating all together a plurality of semiconductor elements mounted on the circuit board in parallel and then singlating them, the semiconductor device in this figure being after batch encapsulation (before singulation). On a circuit board 7, a plurality of semiconductor elements 1 are fixed in parallel with use of a cured die bonding material 2. Each of electrode pads 6 of each of the semiconductor elements 1 is electrically connected to each of electrode pads 8 on the circuit board 7 by a copper wire 4. The encapsulating member 5 is formed, for example, from the cured product of the epoxy resin composition described above, and this encapsulating member 5 is formed through the batch encapsulation only on the single side of the circuit board 7 on which the plurality of semiconductor elements 1 are mounted. Furthermore, at the time after singulation by a dicing operation, a single semiconductor element 1 may be mounted on the circuit board 7 as shown in FIG. 3, or two or more elements 1 may be mounted in parallel or in a stack (not shown). The reference number 11 denotes a dicing line.

In the first semiconductor device of the present invention, the copper wire 4 has the predetermined wire diameter and has, on the surface thereof, the coating layer formed from the metal material containing palladium, and the encapsulating member 5 is formed from the epoxy resin composition. In the second semiconductor device of the present invention, the electrode pad 6 of the semiconductor device 1 is formed from palladium, and the copper wire 4 has the predetermined copper purity and elemental sulfur content. In the third semiconductor device of the present invention, the thickness of the electrode pad 6 of the semiconductor element 1 is 1.2 μm or more, the copper wire 4 has the predetermined copper purity, elemental sulfur content, and elemental chlorine content, and the encapsulating member 5 has the predetermined glass transition temperature and linear expansion coefficient.

Such semiconductor devices can be produced by, but not limited to, for example, the following method: First, the semiconductor element is mounted at a predetermined position of the die pad of the lead frame or the circuit board by a conventionally-known method. Next, the electrical joints provided on the lead frame or circuit board and a predetermined electrode pad provided on the semiconductor element are wire-bonded using a predetermined copper wire to be electrically connected. Then the semiconductor element and the copper wire are encapsulated by a predetermined encapsulating member formed by curing and molding the epoxy resin composition described above and the like through a conventionally-known molding method such as transfer molding, compression molding, and injection molding. In the case of batch encapsulation as shown in FIG. 3, the resultant is subsequently singulated by a dicing operation. Although the semiconductor device obtained by such a method may be mounted as it is on electronic device and the like, it is preferred to mount them on electric device and the like after completely curing the encapsulating member by heating it at 80 to 200° C. (preferably 80 to 180° C.) for 10 minutes to 10 hours.

### EXAMPLES

Hereinafter, the present invention will be more concretely described based on the examples and comparative examples. However, the present invention is not limited to the following Examples.

First, the first semiconductor device of the present invention will be described based on Examples A1 to A30 and Comparative Examples A1 to A10. Components of the epoxy resin compositions used herein are described below.

<Epoxy Resins>

E-1: Biphenyl type epoxy resin (epoxy resin represented by the formula (3) in which R¹¹'s in the 3-position and 5-position are each a methyl group and R¹¹'s in the 2-position and 6-position are each a hydrogen atom, “YX-4000H” available from Japan Epoxy Resins Co., Ltd., melting point 105° C., epoxy equivalent 190, chlorine ion content 5.0 ppm)

E-2: Bisphenol A type epoxy resin (epoxy resin represented by the formula (4) in which R¹² is a hydrogen atom and R¹³ is a methyl group, “YL-6810” available from Japan Epoxy Resins Co., Ltd., melting point 45° C., epoxy equivalent 172, chlorine ion content 2.5 ppm)

E-3: Phenol aralkyl type epoxy resin having a biphenylene skeleton (epoxy resin represented by the formula (5) in which Ar¹ is a phenylene group, Ar² is a biphenylene group, a is 0, and b is 0, “NC3000” available from Nippon Kayaku Co., Ltd., softening point 58° C., epoxy equivalent 274, chlorine ion content 9.8 ppm)

E-4: Naphthol aralkyl type epoxy resin having a phenylene skeleton (epoxy resin represented by the formula (5) in which Ar¹ is a naphthylene group, Ar² is a phenylene group, a is 0, and b is 0, “ESN-175” available from Tohto Kasei Co., Ltd., softening point 65° C., epoxy equivalent 254, chlorine ion content 8.5 ppm)

E-5: Epoxy resin represented by the formula (6) (epoxy resin which is the mixture of 50% by mass of the component represented by the formula (6) in which R¹² is a hydrogen group, c is 0, d is 0, and e is 0, 40% by mass of the component represented by the formula (6) in which R¹⁷ is a hydrogen group, c is 1, d is 0, and e is 0, and 10% by mass of the component represented by the formula (6) in which R¹⁷ is a hydrogen group, c is 1, d is 1, and e is 0, “HP4700” available from Dainippon Ink and Chemicals, Inc., softening point 72° C., epoxy equivalent 205, chlorine ion content 2.0 ppm)

E-6: ortho-cresol novolac type epoxy resin (“EOCN1020” available from Nippon Kayaku Co., Ltd., softening point 55° C., epoxy equivalent 196, chlorine ion content 5.0 ppm)

E-7: Biphenyl type epoxy resin (epoxy resin represented by the formula (3) in which R¹¹'s in the 3-position and 5-position are each a methyl group, and R¹¹'s in the 2-position and 6-position are each a hydrogen atom, “YX-4000H” available from Japan Epoxy Resins Co., Ltd., melting point 105° C., epoxy equivalent 190, chlorine ion content 12.0 ppm)

E-8: Bisphenol A type epoxy resin (epoxy resin represented by the formula (4) in which R¹² is a hydrogen atom and R¹³ is a methyl group, “1001” available from Japan Epoxy Resins Co., Ltd., melting point 45° C., epoxy equivalent 460, chlorine ion content 25 ppm)

### <Curing Agents>

H-1: Phenol novolac resin (“PR-HF-3” available from Sumitomo Bakelite Co., Ltd., softening point 80° C., hydroxyl equivalent 104, chlorine ion content 1.0 ppm)

H-2: Phenol aralkyl resin having a phenylene skeleton (compound represented by the formula (7) in which Ar³ is a phenylene group, Ar⁴ is a phenylene group, f is 0, and g is 0, “XLC-4L” available from Mitsui Chemicals, Inc., softening point 62° C., hydroxyl equivalent 168, chlorine ion content 2.5 ppm)

H-3: Phenol aralkyl resin having a biphenylene skeleton (compound represented by the formula (7) in which Ar³ is a phenylene group, Ar⁴ is a biphenylene group, f is 0, and g is 0, “MEH-7851SS” available from Meiwa Plastic Industries, Ltd., softening point 65° C., hydroxyl equivalent 203, chlorine ion content 1.0 ppm)

H-4: Naphthol aralkyl resin having a phenylene skeleton (compound represented by the formula (7) in which Ar³ is a naphthylene group, Ar⁴ is a phenylene group, f is 0, and g is 0, “SN-485” available from Tohto Kasei Co., Ltd., softening point 87° C., hydroxyl equivalent 210, chlorine ion content 1.5 ppm)

H-5: Naphthol aralkyl resin having a phenylene skeleton (compound represented by the formula (7) in which Ar³ is a naphthylene group, Ar⁴ is a phenylene group, f is 0, and g is 0, “SN-170L” available from Tohto Kasei Co., Ltd., softening point 69° C., hydroxyl equivalent 182, chlorine ion content 15.0 ppm)

### <Fillers>

Fused spherical silica 1: mode diameter 30 μm, specific surface area 3.7 m²/g, content of coarse particles having a diameter of 55 μm or more: 0.01 parts by mass (“HS-203” available from Micron Co., Ltd.)

Fused spherical silica 2: mode diameter 37 μm, specific surface area 2.8 m²/g, content of coarse particles having a diameter of 55 μm or more: 0.1 parts by mass (obtained by sieving “HS-105” available from Micron Co., Ltd. using a 300 mesh sieve to remove the coarse particles)

Fused spherical silica 3: mode diameter 45 μm, specific surface area 2.2 m²/g, content of coarse particles having a diameter of 55 μm or more: 0.1 parts by mass (obtained by sieving “FB-820” available from Denki Kagaku Kogyo K.K. using a 300 mesh sieve to remove the coarse particles)

Fused spherical silica 4: mode diameter 50 μm, specific surface area 1.4 m²/g, content of coarse particles having a diameter of 55 μm or more: 0.03 parts by mass (obtained by sieving “FB-950” available from Denki Kagaku Kogyo K.K. using a 300 mesh sieve to remove the coarse particles)

Fused spherical silica 5: mode diameter 55 μm, specific surface area 1.5 m²/g, content of coarse particles having a diameter of 55 μm or more: 0.1 parts by mass (obtained by sieving “FB-74” available from Denki Kagaku Kogyo K.K. using a 300 mesh sieve to remove the coarse particles)

Fused spherical silica 6: mode diameter 50 μm, specific surface area 3.0 m²/g, content of coarse particles having a diameter of 55 μm or more: 15.0 parts by mass (“FB-820” available from Denki Kagaku Kogyo K.K.)

Fused spherical silica 7: mode diameter 50 μm, specific surface area 1.5 m²/g, content of coarse particles having a diameter of 55 μm or more: 6.0 parts by mass (“FB-950” available from Denki Kagaku Kogyo K.K.)

### <Compounds Containing a Sulfur Atom>

Compound 1 containing a sulfur atom: 3-amino-5-mercapto-1,2,4-triazole (reagent) represented by the following formula (1a):

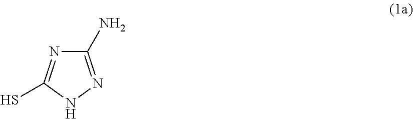

Compound 2 containing a sulfur atom: 3,5-dimercapto-1,2,4-triazole (reagent) represented by the following formula (1b):

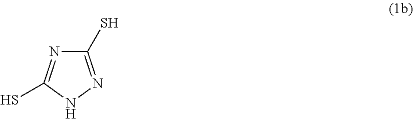

Compound 3 containing a sulfur atom: 3-hydroxy-5-mercapto-1,2,4-triazole (reagent) represented by the following formula (1c):

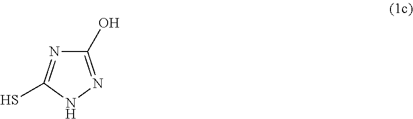

Compound 4 containing a sulfur atom: Trans-4,5-dihydroxy-1,2-dithiane (available from Sigma-Aldrich Corporation, molecular weight: 152.24) represented by the following formula (2a):

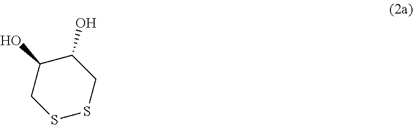

Compound 5 containing a sulfur atom: γ-mercaptopropyltrimethoxysilane

In addition to the components described above, triphenylphosphine (TPP) as a curing accelerator, epoxysilane (γ-glycidoxypropyltrimethoxysilane) as a coupling agent, carbon black as a coloring agent, and carnauba wax as a mold release agent were used.

Furthermore, the copper wires used in Examples A1 to A30 and Comparative Examples A1 to A10 are described below.

### <Copper Wires>

Copper wire 1: Wire obtained by coating the core wire with palladium with a corresponding thickness shown in Tables 1 to 6, the core wire having a corresponding wire diameter shown in Tables 1 to 6 and a copper purity of 99.99% by mass (“MAXSOFT” available from Kulicke & Soffa Industries, Inc.)

Copper wire 2: Wire obtained by coating the core wire with palladium with a corresponding thickness shown in Tables 1 to 6, the core wire having a corresponding wire diameter shown in Tables 1 to 6 and a copper purity of 99.999% by mass and being doped with silver at 0.001% by mass (“TC-A” available from Tatsuta Electric Wire & Cable Co., Ltd.)

Copper wire 3: Copper wire having a corresponding wire diameter shown in Tables 1 to 6 and a copper purity of 99.99% by mass (“TC-E” available from Tatsuta Electric Wire & Cable Co., Ltd.)

### (1) Production of Epoxy Resin Composition for Encapsulating Member

### Example A1

The epoxy resin E-3 (8 parts by mass), the curing agent H-3 (6 parts by mass), the fused spherical silica 2 (85 parts by mass) as a filler, the compound 1 containing a sulfur atom (0.05 parts by mass), triphenylphosphine (0.3 parts by mass) as a curing accelerator, epoxysilane (0.2 parts by mass) as a coupling agent, carbon black (0.25 parts by mass) as a coloring agent, and carnauba wax (0.2 parts by mass) as a mold release agent were mixed at ordinary temperature using a mixer and then roll-milled at 70 to 100° C. After cooling, the resultant was pulverized to give an epoxy resin composition for an encapsulating member.

### Examples A2 to A30

Epoxy resin compositions for encapsulating members were prepared in the same manner as in Example A1, except that the formulations were changed to those shown in Tables 1 to 6.

### Comparative Examples A1 to A10

Epoxy resin compositions for encapsulating members were prepared in the same manner as in Example A1, except that the formulations were changed to those shown in Tables 1, 2, and 4.

### (2) Measurement of Physical Properties of Epoxy Resin Composition

The physical properties of the epoxy resin compositions obtained in Examples A1 to A30 and Comparative Examples A1 to A10 were measured by the following methods. The results are shown in Tables 1 to 6.

<Spiral Flow>

The epoxy resin composition was injected into a mold for the measurement of spiral flow in accordance with EMMI-1-66 under the conditions of a mold temperature of 175° C., an injection pressure of 6.9 MPa, and a curing time of 120 seconds using a low-pressure transfer molding machine (“KTS-15” available from Kohtaki Precision Machine Co., Ltd.), and the flow length (unit: cm) was measured. If the length is 80 cm or less, molding defects such as unfilled packages may occur.

<Moisture Absorption Ratio>

The epoxy resin composition was injected and molded under the conditions of a mold temperature of 175° C., an injection pressure of 9.8 MPa, and a curing time of 120 seconds using a low-pressure transfer molding machine (“KTS-30” available from Kohtaki Precision Machine Co., Ltd.) to produce a disc test piece having a diameter of 50 mm and a thickness of 3 mm. Then the test piece was heated at 175° C. for 8 hours and subjected to post-curing treatment. The mass of the test piece before moisture absorption treatment and the mass thereof after wetting treatment under the environment with 85° C. and a relative humidity of 60% for 168 hours were measured to calculate the moisture absorption ratio (unit: % by mass) of the test piece.

<Shrinkage Ratio>

The epoxy resin composition was injected and molded under the conditions of a mold temperature of 175° C., an injection pressure of 9.8 MPa, and a curing time of 120 seconds using a low-pressure transfer molding machine (“TEP-50-30” available from Fujiwa Seiki Co., Ltd.) to produce a test piece having a diameter of 100 mm and a thickness of 3 mm. Then the piece was heated at 175° C. for 8 hours and subjected to post-curing treatment. The inside diameter of the mold cavity at 175° C. and the external diameter of the test piece at room temperature (25° C.) were measured and the shrinkage ratio was calculated in accordance with the following equation:

Shrinkage ratio (%)={(inside diameter of mold cavity at 175° C.)−(external diameter of test piece at 25° C. after post-curing)}/(inside diameter of mold cavity at 175° C.)×100 (%)

### (3) Production and Evaluation of Semiconductor Device

Semiconductor devices were produced as described below using the epoxy resin compositions obtained in Examples A1 to A30 and Comparative Examples A1 to A10 and the copper wires shown in Tables 1 to 9, and the properties of the semiconductor devices were evaluated. The results are shown in Tables 1 to 6.

<Wire Sweep Ratio>

A TEG (TEST ELEMENT GROUP) chip provided with aluminum electrode pads (3.5 mm×3.5 mm, pad pitch 80 μm) was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and terminals of a substrate (electrical joints) were wire-bonded with a wire pitch of 80 μm using the copper wires shown in Tables 1 to 6. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from TOWA Corporation) to produce a 352 pin BGA package. This package was post-cured at 175° C. for 4 hours to give a semiconductor device.

After cooling to room temperature, the semiconductor device was observed using a soft X-ray fluoroscopy (PRO-TEST100 available from Softex Co., Ltd.) and the sweep ratio of the wire was shown as the ratio (unit: %) of (sweep degree)/(wire length). The value for the wire part which exhibited the largest value is recorded in Tables 1 to 6. If the value exceeds 5%, it means that adjacent wires likely to contact with each other.

<Concentration of Chlorine Ion in Encapsulating Member>

From the post-cured 352 pin BGA package used for measuring the wire sweep ratio as described above, only the encapsulating member was cut out. The resultant was pulverized using a grinding mill for 3 minutes and sieved with a 200 mesh sieve to prepare passed particles as a sample. 5 g of the resultant sample and 50 g of distilled water were placed in an autoclave made of Teflon (registered trademark) and the vessel was sealed. The sample was subjected to treatment at a temperature of 125° C. and a relative humidity of 100% RH for 20 hours (pressure cooker treatment). Next, after cooling to room temperature, the extraction water was centrifuged and filtered through a 20 μm filter. The concentration of chlorine ion was measured using a capillary electrophoresis apparatus (“CAPI-3300” from Otsuka Electronics Co., Ltd.). The resultant concentration of chlorine ion (unit: ppm) was the value measured for the chlorine ion which was extracted from 5 g of the sample and diluted tenfold. Accordingly, the concentration was converted to the chlorine ion content per unit mass of the encapsulating member in accordance with the following equation:

Chlorine ion content per unit mass of the sample (unit: ppm)=(Concentration of chlorine ion measured by capillary electrophoresis apparatus)×50÷5.

Note that the measurement of the concentration of chlorine ion in the encapsulating member was carried out only for Examples A1, A4, A10, and A22 to A30 as a representative of a plurality of the similar resin compositions forming the encapsulating member.

<Solder Resistance>

A chip provided with aluminum electrode pads (3.5 mm×3.5 mm, with SiN coating layer) was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the chip and terminals of a substrate (electrical joints) were wire-bonded with a wire pitch of 80 μm using the copper wires shown in Tables 1 to 6. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from IOWA Corporation) to produce a 352 pin BGA package. This package was post-cured at 175° C. for 4 hours to give a semiconductor device.

After wet-treating 10 of the semiconductor devices at 60° C. and a relative humidity of 60% for 168 hours, the resultants were subjected to IR reflow treatment (maximum temperature 260° C.) three times. The presence or absence of delamination and cracking inside the packages after the treatment was observed using a scanning acoustic tomograph (“mi-scope hyper II” available from Hitachi Construction Machinery Fine Tech Co., Ltd.). Package exhibiting either one of delamination and cracking was determined as “defective,” and the number of the defective package was measured.

<High Temperature Storage Life>

A TEG chip (3.5 mm×3.5 mm) provided with aluminum electrode pads was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and terminals of a substrate (electrical joints) were wire-bonded with a wire pitch of 80 μm using the copper wires shown in Tables 1 to 6 such that the pads and the terminals were daisy-chain connected. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from IOWA Corporation) to produce a 352 pin BGA package. This package was post-cured at 175° C. for 8 hours to give a semiconductor device.

While this semiconductor device was stored at a high temperature of 200° C., the electrical resistance value between the wires was measured every 24 hours. The package exhibiting the increase of the value by 20% compared to the initial value was determined as “defective,” and the time period taken to become defective (unit: hour) was measured. The defect period was shown by a time period taken to generate at least one defective device in the case of n=5. When no defects were generated in all of the packages even after 192 hour storage, the result was recorded as “192<.”

<High Temperature Operating Life>

A TEG chip (3.5 mm×3.5 mm) provided with aluminum electrode pads was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and terminals of a substrate (electrical joints) were wire-bonded with a wire pitch of 80 μm using the copper wires shown in Tables 1 to 6 such that the pads and the terminals were daisy-chain connected. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from IOWA Corporation) to produce a 352 pin BGA package. This package was post-cured at 175° C. for 8 hours to give a semiconductor device.

A DC current of 0.5 A was applied to both ends of the daisy-chain connected portion of this semiconductor device. While the resultant was stored as it is at a high temperature of 185° C., the electrical resistance value between the wires was measured every 12 hours. The package exhibiting the increase of the value by 20% compared to the initial value was determined as “defective,” and the time period taken to become defective (unit: hour) was measured. The defect period was shown by a time period taken to generate at least one defective device in the case of n=4.

<Migration Resistance>

A TEG chip provided with aluminum electrode pads (3.5 mm×3.5 mm, exposed aluminum circuit (no protective film)) was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and leads (electrical joints) of the lead frame were wire-bonded with a wire pitch of 80 μm using the copper wires shown in Tables 1 to 6. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from IOWA Corporation) to produce a 352 pin BGA package. This package was post-cured at 175° C. for 8 hours to give a semiconductor device.

A DC bias voltage of 20V was applied between the adjacent terminals, which were not connected to each other, of this semiconductor device under the conditions of 85° C./85% RH for 168 hours, and the variation in the resistance value between the terminals was measured. The test was conducted under the condition of n=5, and the package exhibiting the decrease of the resistance value to 1/10 of the initial value was determined as “occurrence of migration.” The defect time was shown by the average value in the case of n=5. When the resistance value didn't decrease to 1/10 of the initial value even after 168 hour voltage application for all of the packages, the result was recorded as “168<.”

<Moisture Resistance Reliability>

A TEG chip forming an aluminum circuit (3.5 mm×3.5 mm, exposed aluminum circuit (no protective film)) was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads and terminals of a substrate (electrical joints) were wire-bonded with a wire pitch of 80 μm using the copper wires shown in Tables 1 to 6. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from TOWA Corporation) to produce a 352 pin BGA package. This package was post-cured at 175° C. for 8 hours to give a semiconductor device.

For this semiconductor device, the HAST (Highly Accelerated temperature and humidity Stress Test) was conducted in accordance with IEC 68-2-66. Specifically, the semiconductor device was treated under the condition of 130° C., 85% RH, 20V application, and 168 hours, and the presence or absence of open defect of the circuit was measured. The measurements were made on a total of 20 circuits of 4 terminals/1 package×5 packages and the evaluations were made by the number of defective circuits.

TABLE 1

| Examples | | | Comparative Examples | | | |
|---|---|---|---|---|---|---|
| A1 | A2 | A3 | A1 | A2 | A3 | A4 |

Formulations of Epoxy Resin Compositions for Encapsulant

| | | | | | | | |
|---|---|---|---|---|---|---|---|
| E-1 | | | | | | | |
| E-2 | | | | | | | |
| E-3 | 8 | 8 | 8 | 8 | 8 | 8 | 8 |
| E-4 | | | | | | | |
| E-5 | | | | | | | |
| E-6 | | | | | | | |
| E-7 | | | | | | | |
| E-8 | | | | | | | |
| H-1 | | | | | | | |
| H-2 | | | | | | | |
| H-3 | 6 | 6 | 6 | 6 | 6 | 6 | 6 |
| H-4 | | | | | | | |
| H-5 | | | | | | | |
| Fused spherical silica 1 | | | | | | | |
| Fused spherical silica 2 | 85 | 85 | 85 | 85 | 85 | 85 | 85 |
| Fused spherical silica 3 | | | | | | | |
| Fused spherical silica 4 | | | | | | | |
| Fused spherical silica 5 | | | | | | | |
| Fused spherical silica 6 | | | | | | | |
| Fused spherical silica 7 | | | | | | | |
| Compound 1 containing sulfur atom | 0.05 | 0.05 | 0.05 | 0.05 | | | |
| Compound 2 containing sulfur atom | | | | | | | |
| Compound 3 containing sulfur atom | | | | | | | |
| Compound 4 containing sulfur atom | | | | | | | |
| Compound 5 containing sulfur atom | | | | | | | |
| TPP | 0.3 | 0.3 | 0.3 | 0.3 | 0.3 | 0.3 | 0.3 |
| Epoxysilane | 0.2 | 0.2 | 0.2 | 0.2 | 0.25 | 0.25 | 0.25 |
| Carbon black | 0.25 | 0.25 | 0.25 | 0.25 | 0.25 | 0.25 | 0.25 |
| Carnauba wax | 0.2 | 0.2 | 0.2 | 0.2 | 0.2 | 0.2 | 0.2 |

Copper Wire

| Kind of copper wire | | 1 | 1 | 2 | 3 | 1 | 2 | 3 |
|---|---|---|---|---|---|---|---|---|
| Copper purity of core wire | | 99.99 | 99.99 | 99.999 | 99.99 | 99.99 | 99.999 | 99.99 |
| Dopant metal in core wire | | — | — | Silver | — | — | Silver | — |
| Diameter of core wire | [μm] | 22 | 22 | 22 | 22 | 22 | 22 | 22 |
| Thickness of coating layer | [μm] | 0.015 | 0.005 | 0.005 | — | 0.015 | 0.005 | — |

Evaluation Results

| | | | | | | | | |
|---|---|---|---|---|---|---|---|---|
| Spiral flow | [cm] | 120 | 120 | 120 | 120 | 125 | 125 | 125 |
| Moisture absorption ratio | [% by mass] | 0.09 | 0.09 | 0.09 | 0.09 | 0.09 | 0.09 | 0.09 |
| Shrinkage ratio | [%] | 0.30 | 0.30 | 0.30 | 0.30 | 0.31 | 0.31 | 0.31 |
| Wire sweep ratio | [%] | 3.0 | 3.0 | 3.0 | 3.0 | 3.1 | 3.1 | 3.1 |
| Solder resistance | [number of defectives] | 0 | 0 | 0 | 0 | 8 | 7 | 7 |
| High temperature storage life (200° C.) | [hr] | 192< | 192< | 192< | 48 | 192< | 192< | 48 |
| High temperature operating life | [hr] | 120 | 120 | 144 | 24 | 24 | 48 | 24 |
| Migration resistance | [hr] | 168< | 168< | 168< | 48 | 168< | 24 | 24 |
| Moisture resistance reliability | [number of defectives] | 0 | 0 | 0 | 7 | 10 | 10 | 10 |
| Concentration of chlorine ion in | [ppm] | 3.0 | — | — | — | — | — | — |
| encapsulant | | | | | | | | |

TABLE 2

| | | | | | | Comparative | |
|---|---|---|---|---|---|---|---|
| Examples | | | | | | Examples | |
| A4 | A5 | A6 | A7 | A8 | A9 | A5 | A6 |

Formulations of Epoxy Resin Compositions for Encapsulant

| | | | | | | | | |
|---|---|---|---|---|---|---|---|---|
| E-1 | | | | | | | | |
| E-2 | 1.9 | 1.9 | 1.9 | 1.9 | 1.9 | 1.9 | 1.9 | 1.9 |
| E-3 | | | | | | | | |
| E-4 | 4.3 | 4.3 | 4.3 | 4.3 | 4.3 | 4.3 | 4.3 | 4.3 |
| E-5 | | | | | | | | |
| E-6 | | | | | | | | |
| E-7 | | | | | | | | |
| E-8 | | | | | | | | |
| H-1 | | | | | | | | |
| H-2 | | | | | | | | |
| H-3 | | | | | | | | |
| H-4 | 5.7 | 5.7 | 5.7 | 5.7 | 5.7 | 5.7 | 5.7 | 5.7 |
| H-5 | | | | | | | | |
| Fused spherical silica 1 | | | | | | | | |
| Fused spherical silica 2 | 87 | 87 | 87 | 87 | 87 | 87 | 87 | 87 |
| Fused spherical silica 3 | | | | | | | | |
| Fused spherical silica 4 | | | | | | | | |
| Fused spherical silica 5 | | | | | | | | |
| Fused spherical silica 6 | | | | | | | | |
| Fused spherical silica 7 | | | | | | | | |
| Compound 1 containing sulfur atom | 0.15 | | | | | | | |
| Compound 2 containing sulfur atom | | 0.05 | 0.15 | | | | | |
| Compound 3 containing sulfur atom | | | | 0.15 | | | | |
| Compound 4 containing sulfur atom | | | | | 0.15 | | | |
| Compound 5 containing sulfur atom | | | | | | 0.15 | | |
| TPP | 0.3 | 0.3 | 0.3 | 0.3 | 0.3 | 0.3 | 0.3 | 0.3 |
| Epoxysilane | 0.2 | 0.3 | 0.2 | 0.2 | 0.2 | 0.2 | 0.35 | 0.35 |
| Carbon black | 0.25 | 0.25 | 0.25 | 0.25 | 0.25 | 0.25 | 0.25 | 0.25 |
| Carnauba wax | 0.2 | 0.2 | 0.2 | 0.2 | 0.2 | 0.2 | 0.2 | 0.2 |

Copper Wire

| Kind of copper wire | | 1 | 1 | 1 | 1 | 1 | 1 | 1 | 3 |
|---|---|---|---|---|---|---|---|---|---|
| Copper purity of core wire | | 99.99 | 99.99 | 99.99 | 99.99 | 99.99 | 99.99 | 99.99 | 99.99 |
| Dopant metal in core wire | | — | — | — | — | — | — | — | — |
| Diameter of core wire | [μm] | 22 | 22 | 22 | 22 | 22 | 22 | 22 | 22 |
| Thickness of coating layer | [μm] | 0.015 | 0.015 | 0.015 | 0.015 | 0.015 | 0.015 | 0.015 | — |

Evaluation Results

| | | | | | | | | | |
|---|---|---|---|---|---|---|---|---|---|
| Spiral flow | [cm] | 135 | 135 | 140 | 140 | 140 | 150 | 135 | 135 |
| Moisture absorption ratio | [% by mass] | 0.09 | 0.10 | 0.09 | 0.09 | 0.09 | 0.12 | 0.09 | 0.09 |
| Shrinkage ratio | [%] | 0.18 | 0.19 | 0.18 | 0.18 | 0.18 | 0.22 | 0.20 | 0.20 |
| Wire sweep ratio | [%] | 3.2 | 3.0 | 3.3 | 3.0 | 3.4 | 3.4 | 3.3 | 3.3 |
| Solder resistance | [number of defectives] | 0 | 0 | 0 | 0 | 0 | 0 | 7 | 7 |
| High temperature storage life | [hr] | 192< | 192< | 192< | 192< | 192< | 168 | 168 | 48 |
| (200° C.) | | | | | | | | | |
| High temperature operating life | [hr] | 96 | 96 | 96 | 84 | 72 | 72 | 36 | 24 |
| Migration resistance | [hr] | 168< | 168< | 168< | 168< | 168< | 144 | 144 | 48 |
| Moisture resistance reliability | [number of defectives] | 0 | 0 | 0 | 0 | 0 | 0 | 7 | 7 |
| Concentration of chlorine ion in | [ppm] | 4.4 | — | — | — | — | — | — | — |
| encapsulant | | | | | | | | | |

TABLE 3

| Examples | | | | | | |
|---|---|---|---|---|---|---|
| A10 | A11 | A12 | A13 | A14 | A15 | A16 |

Formulations of Epoxy Resin Compositions for Encapsulant

| | | | | | | | |
|---|---|---|---|---|---|---|---|
| E-1 | | | | | | | |
| E-2 | 1.5 | 1.5 | 1.5 | 1.5 | 1.5 | 1.5 | 1.5 |
| E-3 | 6.1 | 6.1 | 6.1 | 6.1 | 6.1 | 6.1 | 6.1 |
| E-4 | | | | | | | |
| E-5 | | | | | | | |
| E-6 | | | | | | | |
| E-7 | | | | | | | |
| E-8 | | | | | | | |
| H-1 | | | | | | | |
| H-2 | | | | | | | |
| H-3 | | | | | | | |
| H-4 | 6.4 | 6.4 | 6.4 | 6.4 | 6.4 | 6.4 | 6.4 |
| H-5 | | | | | | | |
| Fused spherical silica 1 | 85 | | | | | | |
| Fused spherical silica 2 | | 85 | | | | | |
| Fused spherical silica 3 | | | 85 | | | | |
| Fused spherical silica 4 | | | | 85 | | | |
| Fused spherical silica 5 | | | | | 85 | | |
| Fused spherical silica 6 | | | | | | 85 | |
| Fused spherical silica 7 | | | | | | | 85 |
| Compound 1 containing sulfur atom | 0.05 | 0.05 | 0.05 | 0.05 | 0.05 | 0.05 | 0.05 |
| Compound 2 containing sulfur atom | | | | | | | |
| Compound 3 containing sulfur atom | | | | | | | |
| Compound 4 containing sulfur atom | | | | | | | |
| Compound 5 containing sulfur atom | | | | | | | |
| TPP | 0.3 | 0.3 | 0.3 | 0.3 | 0.3 | 0.3 | 0.3 |
| Epoxysilane | 0.2 | 0.2 | 0.2 | 0.2 | 0.2 | 0.2 | 0.2 |
| Carbon black | 0.25 | 0.25 | 0.25 | 0.25 | 0.25 | 0.25 | 0.25 |
| Carnauba wax | 0.2 | 0.2 | 0.2 | 0.2 | 0.2 | 0.2 | 0.2 |

Copper Wire

| Kind of copper wire | | 1 | 1 | 1 | 1 | 1 | 1 | 1 |
|---|---|---|---|---|---|---|---|---|
| Copper purity of core wire | | 99.99 | 99.99 | 99.99 | 99.99 | 99.99 | 99.99 | 99.99 |
| Dopant metal in core wire | | — | — | — | — | — | — | — |
| Diameter of core wire | [μm] | 22 | 22 | 22 | 22 | 22 | 22 | 22 |
| Thickness of coating layer | [μm] | 0.015 | 0.015 | 0.015 | 0.015 | 0.015 | 0.015 | 0.015 |

Evaluation Results

| | | | | | | | | |
|---|---|---|---|---|---|---|---|---|
| Spiral flow | [cm] | 200 | 170 | 175 | 180 | 180 | 165 | 210 |
| Moisture absorption ratio | [% by mass] | 0.11 | 0.10 | 0.09 | 0.08 | 0.10 | 0.10 | 0.09 |
| Shrinkage ratio | [%] | 0.23 | 0.20 | 0.20 | 0.20 | 0.20 | 0.20 | 0.20 |
| Wire sweep ratio | [%] | 3.0 | 3.0 | 3.5 | 3.8 | 4.1 | 5.5 | 4.5 |
| Solder resistance | [number of defectives] | 1 | 1 | 0 | 0 | 1 | 1 | 0 |
| High temperature storage life (200° C.) | [hr] | 168 | 168 | 168 | 168 | 168 | 168 | 168 |
| High temperature operating life | [hr] | 144 | 120 | 144 | 144 | 120 | 96 | 120 |
| Migration resistance | [hr] | 144 | 144 | 144 | 144 | 144 | 144 | 144 |
| Moisture resistance reliability | [number of defectives] | 0 | 0 | 0 | 0 | 0 | 0 | 0 |
| Concentration of chlorine ion in encapsulant | [ppm] | 3.2 | — | — | — | — | — | — |

TABLE 4

| Examples | | Comparative Examples | | | |
|---|---|---|---|---|---|
| A17 | A18 | A7 | A8 | A9 | A10 |

Formulations of Epoxy Resin Compositions for Encapsulant

| | | | | | | |
|---|---|---|---|---|---|---|
| E-1 | 1.5 | 1.5 | 1.5 | 1.5 | 1.5 | 1.5 |
| E-2 | 6.1 | 6.1 | 6.1 | 6.1 | 6.1 | 6.1 |
| E-3 | | | | | | |
| E-4 | | | | | | |
| E-5 | | | | | | |
| E-6 | | | | | | |
| E-7 | | | | | | |
| E-8 | | | | | | |
| H-1 | | | | | | |
| H-2 | | | | | | |
| H-3 | | | | | | |
| H-4 | 6.4 | 6.4 | 6.4 | 6.4 | 6.4 | 6.4 |
| H-5 | | | | | | |
| Fused spherical silica 1 | | | | | | |
| Fused spherical silica 2 | 85 | 85 | 85 | 85 | 85 | 85 |
| Fused spherical silica 3 | | | | | | |
| Fused spherical silica 4 | | | | | | |
| Fused spherical silica 5 | | | | | | |
| Fused spherical silica 6 | | | | | | |
| Fused spherical silica 7 | | | | | | |
| Compound 1 containing sulfur atom | 0.05 | 0.05 | 0.05 | | 0.05 | |
| Compound 2 containing sulfur atom | | | | | | |
| Compound 3 containing sulfur atom | | | | | | |
| Compound 4 containing sulfur atom | | | | | | |
| Compound 5 containing sulfur atom | | | | | | |
| TPP | 0.3 | 0.3 | 0.3 | 0.3 | 0.3 | 0.3 |
| Epoxysilane | 0.2 | 0.2 | 0.2 | 0.25 | 0.2 | 0.25 |
| Carbon black | 0.25 | 0.25 | 0.25 | 0.25 | 0.25 | 0.25 |
| Carnauba wax | 0.2 | 0.2 | 0.2 | 0.2 | 0.2 | 0.2 |

Copper Wire

| Kind of copper wire | | 1 | 1 | 1 | 1 | 3 | 3 |
|---|---|---|---|---|---|---|---|
| Copper purity of core wire | | 99.99 | 99.99 | 99.99 | 99.99 | 99.99 | 99.99 |
| Dopant metal in core wire | | — | — | — | — | — | — |
| Diameter of core wire | [μm] | 20 | 25 | 30 | 22 | 22 | 22 |
| Thickness of coating layer | [μm] | 0.015 | 0.015 | 0.015 | 0.015 | — | — |

Evaluation Results

| | | | | | | | |
|---|---|---|---|---|---|---|---|
| Spiral flow | [cm] | 170 | 170 | 170 | 175 | 170 | 175 |
| Moisture absorption ratio | [% by mass] | 0.10 | 0.10 | 0.10 | 0.10 | 0.10 | 0.10 |
| Shrinkage ratio | [%] | 0.20 | 0.20 | 0.20 | 0.22 | 0.20 | 0.22 |
| Wire sweep ratio | [%] | 3.8 | 2.5 | Wire bonding | 3.0 | 3.1 | 3.0 |
| Solder resistance | [number of defectives] | 1 | 0 | was not | 10 | 1 | 10 |
| High temperature storage life (200° C.) | [hr] | 168 | 168 | performed | 168 | 48 | 168 |
| High temperature operating life | [hr] | 120 | 144 | due to contact | 48 | 60 | 48 |
| Migration resistance | [hr] | 144 | 144 | of ball portion | 144 | 24 | 48 |
| Moisture resistance reliability | [number of defectives] | 0 | 0 | | 10 | 10 | 10 |
| Concentration of chlorine ion in encapsulant | [ppm] | — | — | — | — | — | — |

TABLE 5

| Examples | | | | | | | |
|---|---|---|---|---|---|---|---|
| A19 | A20 | A21 | A22 | A23 | A24 | A25 | A26 |

Formulations of Epoxy Resin Compositions for Encapsulant

| | | | | | | | | |
|---|---|---|---|---|---|---|---|---|
| E-1 | | | | 5.3 | 2.7 | | | 4.1 |
| E-2 | | | | | | | | |
| E-3 | | | | | | | 6.5 | |
| E-4 | 6.5 | 6.5 | 6.5 | | | | | |
| E-5 | | | | | 2.7 | 7.2 | | |
| E-6 | | | | | | | | 1.7 |
| E-7 | | | | | | | | |
| E-8 | | | | | | | | |
| H-1 | 1.3 | 1.3 | 1.3 | | | 3.7 | | 2.1 |
| H-2 | | | | 4.7 | 4.6 | | 2.2 | 2 |
| H-3 | 3.1 | 3.1 | 3.1 | | | | | |
| H-4 | | | | | | | 2.2 | |
| H-5 | | | | | | | | |
| Fused spherical silica 1 | | | | 89 | 89 | | | |
| Fused spherical silica 2 | | | | | | | | |
| Fused spherical silica 3 | 88 | 88 | 88 | | | 88 | 88 | 89 |
| Fused spherical silica 4 | | | | | | | | |
| Fused spherical silica 5 | | | | | | | | |
| Fused spherical silica 6 | | | | | | | | |
| Fused spherical silica 7 | | | | | | | | |
| Compound 1 containing sulfur atom | | | | 0.05 | 0.05 | | | |
| Compound 2 containing sulfur atom | 0.15 | 0.15 | 0.15 | | | 0.15 | 0.15 | 0.15 |
| Compound 3 containing sulfur atom | | | | | | | | |
| Compound 4 containing sulfur atom | | | | | | | | |
| Compound 5 containing sulfur atom | | | | | | | | |
| TPP | 0.3 | 0.3 | 0.3 | 0.3 | 0.3 | 0.3 | 0.3 | 0.3 |
| Epoxysilane | 0.2 | 0.2 | 0.2 | 0.2 | 0.2 | 0.2 | 0.2 | 0.2 |
| Carbon black | 0.25 | 0.25 | 0.25 | 0.25 | 0.25 | 0.25 | 0.25 | 0.25 |
| Carnauba wax | 0.2 | 0.2 | 0.2 | 0.2 | 0.2 | 0.2 | 0.2 | 0.2 |

Copper Wire

| Kind of copper wire | | 1 | 1 | 1 | 1 | 1 | 2 | 2 | 2 |
|---|---|---|---|---|---|---|---|---|---|
| Copper purity of core wire | | 99.99 | 99.99 | 99.99 | 99.99 | 99.99 | 99.99 | 99.99 | 99.99 |
| Dopant metal in core wire | | — | — | — | — | — | Silver | Silver | Silver |
| Diameter of core wire | [μm] | 22 | 20 | 25 | 22 | 22 | 22 | 22 | 22 |
| Thickness of coating layer | [μm] | 0.005 | 0.015 | 0.015 | 0.015 | 0.015 | 0.005 | 0.005 | 0.005 |

Evaluation Results

| | | | | | | | | | |
|---|---|---|---|---|---|---|---|---|---|
| Spiral flow | [cm] | 110 | 110 | 110 | 150 | 140 | 110 | 120 | 140 |
| Moisture absorption ratio | [% by mass] | 0.10 | 0.10 | 0.10 | 0.11 | 0.10 | 0.13 | 0.10 | 0.15 |
| Shrinkage ratio | [%] | 0.25 | 0.25 | 0.25 | 0.25 | 0.18 | 0.17 | 0.20 | 0.27 |
| Wire sweep ratio | [%] | 4.0 | 4.5 | 2.8 | 3.8 | 4.0 | 4.0 | 4.0 | 4.2 |
| Solder resistance | [number of defectives] | 0 | 0 | 0 | 2 | 2 | 3 | 0 | 2 |
| High temperature storage life | [hr] | 192< | 192< | 192< | 168 | 168 | 192< | 192< | 168 |
| (200° C.) | | | | | | | | | |
| High temperature operating life | [hr] | 144 | 120 | 168 | 120 | 120 | 144 | 144 | 144 |
| Migration resistance | [hr] | 168< | 168< | 168< | 144 | 144 | 168< | 168< | 120 |
| Moisture resistance reliability | [number of defectives] | 0 | 0 | 0 | 1 | 1 | 0 | 0 | 0 |
| Concentration of chlorine ion | [ppm] | — | — | — | 3.5 | 3.4 | 3.1 | 3.0 | 3.9 |
| in encapsulant | | | | | | | | | |

TABLE 6

| Examples | | | | | | |
|---|---|---|---|---|---|---|
| A1 | A4 | A10 | A27 | A28 | A29 | A30 |

Formulations of Epoxy Resin Compositions for Encapsulant

| | | | | | | | |
|---|---|---|---|---|---|---|---|
| E-1 | | | | | | | |
| E-2 | | 1.9 | 1.5 | | | | |
| E-3 | 8 | | 6.1 | | | 6.1 | |
| E-4 | | 4.3 | | | | | |
| E-5 | | | | | 2.7 | | |
| E-6 | | | | | | | |
| E-7 | | | | 5.3 | 2.7 | | 5.3 |
| E-8 | | | | | | 1.5 | |
| H-1 | | | | | | | |
| H-2 | | | | 4.7 | 4.6 | | |
| H-3 | 6 | | | | | | |
| H-4 | | 5.7 | 6.4 | | | 6.4 | |
| H-5 | | | | | | | 4.7 |
| Fused spherical silica 1 | | | 85 | 89 | 89 | | 89 |
| Fused spherical silica 2 | 85 | 87 | | | | 85 | |
| Fused spherical silica 3 | | | | | | | |
| Fused spherical silica 4 | | | | | | | |
| Fused spherical silica 5 | | | | | | | |
| Fused spherical silica 6 | | | | | | | |
| Fused spherical silica 7 | | | | | | | |
| Compound 1 containing sulfur atom | 0.05 | 0.15 | 0.05 | 0.05 | 0.05 | 0.05 | 0.05 |
| Compound 2 containing sulfur atom | | | | | | | |
| Compound 3 containing sulfur atom | | | | | | | |
| Compound 4 containing sulfur atom | | | | | | | |
| Compound 5 containing sulfur atom | | | | | | | |
| TPP | 0.3 | 0.3 | 0.3 | 0.3 | 0.3 | 0.3 | 0.3 |
| Epoxysilane | 0.2 | 0.2 | 0.2 | 0.2 | 0.2 | 0.2 | 0.2 |
| Carbon black | 0.25 | 0.25 | 0.25 | 0.25 | 0.25 | 0.25 | 0.25 |
| Carnauba wax | 0.2 | 0.2 | 0.2 | 0.2 | 0.2 | 0.2 | 0.2 |

Copper Wire

| Kind of copper wire | | 1 | 1 | 1 | 1 | 1 | 1 | 2 |
|---|---|---|---|---|---|---|---|---|
| Copper purity of core wire | | 99.99 | 99.99 | 99.99 | 99.99 | 99.99 | 99.99 | 99.999 |
| Dopant metal in core wire | | — | — | — | — | — | — | Silver |
| Diameter of core wire | [μm] | 22 | 22 | 22 | 22 | 22 | 22 | 22 |
| Thickness of coating layer | [μm] | 0.015 | 0.015 | 0.015 | 0.015 | 0.015 | 0.015 | 0.005 |

Evaluation Results

| | | | | | | | | |
|---|---|---|---|---|---|---|---|---|
| Spiral flow | [cm] | 120 | 135 | 200 | 140 | 135 | 120 | 140 |
| Moisture absorption ratio | [% by mass] | 0.09 | 0.09 | 0.11 | 0.11 | 0.10 | 0.12 | 0.11 |
| Shrinkage ratio | [%] | 0.30 | 0.18 | 0.23 | 0.26 | 0.19 | 0.24 | 0.26 |
| Wire sweep ratio | [%] | 3.0 | 3.2 | 3.0 | 3.8 | 4.0 | 3.0 | 3.8 |
| Solder resistance | [number of defectives] | 0 | 0 | 1 | 2 | 2 | 1 | 2 |
| High temperature storage life | [hr] | 192< | 192< | 168 | 120 | 120 | 120 | 120 |
| (200° C.) | | | | | | | | |
| High temperature operating life | [hr] | 120 | 96 | 144 | 96 | 96 | 96 | 108 |
| Migration resistance | [hr] | 168< | 168< | 144 | 96 | 96 | 96 | 120 |
| Moisture resistance reliability | [number of defectives] | 0 | 0 | 0 | 1 | 1 | 3 | 3 |
| Concentration of chlorine ion | [ppm] | 3.0 | 4.4 | 3.2 | 5.8 | 5.2 | 18.0 | 12.0 |
| in encapsulant | | | | | | | | |

As apparent from the results shown in Tables 1 to 6, the first semiconductor device of the present invention (Examples A1 to A30) had the excellent wire sweep ratio, solder resistance, high temperature storage life, high temperature operating life, migration resistance, and moisture resistance reliability.

Next, the second semiconductor device of the present invention will be described based on Examples B1 to B10 and Comparative Examples B1 to B4. Components of the epoxy resin compositions used herein are described below.

<Epoxy Resins>

EA-1: Biphenyl type epoxy resin (epoxy resin represented by the formula (3) in which R¹¹'s in the 3-position and 5-position are each a methyl group and R¹¹'s in the 2-position and 6-position are each a hydrogen atom, “YX-4000” available from Japan Epoxy Resins Co., Ltd., melting point 105° C., epoxy equivalent 190)

EA-2: Bisphenol A type epoxy resin (epoxy resin represented by the formula (4) in which R¹² is a hydrogen atom and R¹³ is a methyl group, “YL-6810” available from Japan Epoxy Resins Co., Ltd., melting point 45° C., epoxy equivalent 172)

EB-1: Polyfunctional epoxy resin having a naphthalene skeleton (epoxy resin comprising 50% by mass of the component represented by the formula (6) in which c is 0, d is 0, e is 0, and R¹⁷ is a hydrogen group, 40% by mass of the component represented by the formula (6) in which c is 1, d is 0, e is 0, and R¹⁷ is a hydrogen group, and 10% by mass of the component represented by the formula (6) in which c is 1, d is 1, e is 0, and R¹⁷ is a hydrogen group, “HP4770” available from DIC Corporation, melting point 72° C., epoxy equivalent 205)

EB-2: Dihydroanthracenediol type crystalline epoxy resin (epoxy resin represented by the formula (9) in which all of R²¹ to R³⁰ are a hydrogen atom and n⁵ is 0, “YX8800” available from Japan Epoxy Resins Co., Ltd., melting point 110° C., epoxy equivalent 181)

EB-3: Dicyclopentadiene type epoxy resin (epoxy resin represented by the formula (10), “HP7200” available from DIC Corporation, melting point 64° C., epoxy equivalent 265)

<Curing Agents>

HA-1: Phenol novolac resin (“PR-HF-3” available from Sumitomo Bakelite Co., Ltd., softening point 80° C., hydroxyl equivalent 104)

HA-2: Dicyclopentadiene type phenol resin (phenol resin represented by the formula (11), (“MGH-700” available from Nippon Kayaku Co., Ltd., softening point 87° C., hydroxyl equivalent 165)

HB-1: Phenol aralkyl resin having a biphenylene skeleton (phenol aralkyl resin represented by the formula (7) in which f is 0, g is 0, Ar³ is a phenylene group, and Ar⁴ is a biphenylene group, “MEH-7851SS” available from Meiwa Plastic Industries, Ltd., softening point 65° C., hydroxyl equivalent 203)

HB-2: Naphthol aralkyl resin with a phenylene skeleton (naphthol aralkyl resin represented by the formula (7) in which f is 0, g is 0, Ar³ is a naphthylene group, and Ar⁴ is a phenylene group, “SN-485” available from Tohto Kasei Co., Ltd., softening point 87° C., hydroxyl equivalent 210)

<Fillers>

Fused spherical silica 1: mode diameter 45 μm, specific surface area 2.2 m²/g, content ratio of coarse particles having a diameter of 55 μm or more: 0.1% by mass (obtained by sieving “FB-820” available from Denki Kagaku Kogyo K.K. using a 300 mesh sieve to remove the coarse particles)

### <Corrosion Inhibitors>

Hydrotalcite 1: “DHT” available from Kyowa Chemical Industry Co., Ltd., mass loss ratio A at 250° C. 13.95% by mass, mass loss ratio B (% by mass) at 200° C. 4.85% by mass, A−B=9.09% by mass, mass loss ratios A and B measured by a thermogravimetric analysis

Hydrotalcite 2: “IXE-750” available from Toagosei Co., Ltd., half-calcined hydrotalcite (Mg₆Al₂(OH)₁₆(CO₂).mH₂O) which was heat treated at 230° C. for an hour, pH buffering range of 5.5, thermogravimetric mass loss ratio A at 250° C. 8.76% by mass, thermogravimetric mass loss ratio B (% by mass) at 200° C. 4.12% by mass, A−B=4.64% by mass, mass loss ratios A and B measured by a thermogravimetric analysis

Calcium carbonate: “NS#100” available from Nitto Funka Kogyo K.K.

Precipitated calcium carbonate: “CS-B” available from Ube Material Industries, Ltd., which synthesized by a carbon dioxide gas reaction method

In addition to the components described above, triphenylphosphine (TPP) as a curing accelerator, epoxysilane (γ-glycidoxypropyltrimethoxysilane) as a coupling agent, carbon black as a coloring agent, and carnauba wax as a mold release agent were used.

Furthermore, the copper wires used in Examples B1 to B10 and Comparative Examples B1 to B4 are described below.

<Copper Wires>

4NS: “MAXSOFT” available from Kulicke & Soffa Industries, Inc., copper purity 99.99% by mass, elemental sulfur content 7 ppm by mass, wire diameter 25 μm

4N: “TC-E” available from Tatsuta Electric Wire & Cable Co., Ltd., copper purity 99.99% by mass, elemental sulfur content 3.8 ppm by mass, wire diameter 25 μm

5N: “TC-A” available from Tatsuta Electric Wire & Cable Co., Ltd., copper purity 99.999% by mass, elemental sulfur content 0.1 ppm by mass, wire diameter 25 μm

5.5N: “TC-A5.5” available from Tatsuta Electric Wire & Cable Co., Ltd., copper purity 99.9995% by mass, elemental sulfur content 0.1 ppm by mass, wire diameter 25 μm

### Example B1

### (1) Production of Epoxy Resin Composition for Encapsulating Member

The epoxy resins EA-1 (2.92 parts by mass) and EB-2 (2.92 parts by mass), the curing agents HA-1 (2.48 parts by mass) and HB-2 (2.48 parts by mass), the fused spherical silica 1 (88 parts by mass) as a filler, the hydrotalcite 1 (0.2 parts by mass) as a corrosion inhibitor, triphenylphosphine (TPP) (0.3 parts by mass) as a curing accelerator, epoxysilane (0.2 parts by mass) as a coupling agent, carbon black (0.3 parts by mass) as a coloring agent, and carnauba wax (0.2 part by mass) as a mold release agent were mixed at ordinary temperature using a mixer and then roll-milled at 70 to 100° C. After cooling, the resultant was pulverized to give an epoxy resin composition for an encapsulating member.

### (2) Measurement of Physical Properties of Epoxy Resin Composition

The physical properties of the resultant epoxy resin composition were measured by the following methods. The results are shown in Table 7.

<Spiral Flow>

The epoxy resin composition was injected into a mold for the measurement of spiral flow in accordance with EMMI-1-66 under the conditions of a mold temperature of 175° C., an injection pressure of 6.9 MPa, and a curing time of 120 seconds using a low-pressure transfer molding machine (“KTS-15” available from Kohtaki Precision Machine Co., Ltd.), and the flow length (unit: cm) was measured. If the length is 80 cm or less, molding defects such as unfilled packages may occur.

<Moisture Absorption Ratio>

The epoxy resin composition was injected and molded under the conditions of a mold temperature of 175° C., an injection pressure of 9.8 MPa, and a curing time of 120 seconds using a low-pressure transfer molding machine (“KTS-30” available from Kohtaki Precision Machine Co., Ltd.) to produce a disc test piece having a diameter of 50 mm and a thickness of 3 mm. Then the test piece was heated at 175° C. for 8 hours and subjected to post-curing treatment. The mass of the test piece before moisture absorption treatment and the mass thereof after wetting treatment under the environment with 85° C. and a relative humidity of 60% for 168 hours were measured to calculate the moisture absorption ratio (unit: % by mass) of the test piece.

<Glass Transition Temperature>

The epoxy resin composition was injected under the conditions of a mold temperature of 175° C., an injection pressure of 9.8 MPa, and a curing time of 180 seconds using a low-pressure transfer molding machine (“KTS-30” available from Kohtaki Precision Machine Co., Ltd.) to mold a test piece with 10 mm×4 mm×4 mm, and then the test piece was heated at 175° C. for 8 hours and subjected to post-curing treatment. The TMA analysis was performed on the resultant test piece at a rate of temperature rise of 5° C./min using a thermomechanical analyzer (“TMA-100” available from Seiko Instruments Inc.). The temperature of the intersection of the tangents to the resultant TMA curve for 60° C. and 240° C. was read off and this temperature was used as the glass transition temperature (unit: ° C.).

<Linear Expansion Coefficient α1>

The epoxy resin composition was injected and molded under the conditions of a mold temperature of 175° C., an injection pressure of 7.4 MPa, and a curing time of 2 minutes using a low-pressure transfer molding machine (“KTS-30” available from Kohtaki Precision Machine Co., Ltd.) to produce a test piece having a length of 15 mm, a width of 5 mm, and a thickness of 3 mm, and then the test piece was subjected to post-curing treatment at 175° C. for 8 hours. The TMA analysis was performed on the resultant test piece at a rate of temperature rise of 5° C./min using a thermomechanical analyzer (“TMA-120” available from Seiko Instruments & Electronics Ltd.). The average linear expansion coefficient al (unit: ppm/° C.) in the temperature range from 25° C. to a temperature of 10° C. below the glass transition temperature of the resultant TMA curve was calculated.

<Shrinkage Ratio>

The epoxy resin composition was injected and molded under the conditions of a mold temperature of 175° C., an injection pressure of 9.8 MPa, and a curing time of 120 seconds using a low-pressure transfer molding machine (“TEP-50-30” available from Fujiwa Seiki Co., Ltd.) to produce a test piece having a diameter of 100 mm and a thickness of 3 mm. Then the piece was heated at 175° C. for 8 hours and subjected to post-curing treatment. The inside diameter of the mold cavity at 175° C. and the external diameter of the test piece at room temperature (25° C.) were measured and the shrinkage ratio was calculated in accordance with the following equation:

Shrinkage ratio (%)={(inside diameter of mold cavity at 175° C.)−(external diameter of test piece at 25° C. after post-curing)}/(inside diameter of mold cavity at 175° C.)×100 (%)

### (3) Production of Semiconductor Device

A TEG (TEST ELEMENT GROUP) chip (3.5 mm×3.5 mm) provided with palladium electrode pads was bonded to a die pad portion of a 352 pin BGA (substrate: bismaleimide triazine resin/glass cloth substrate having a thickness of 0.56 mm, package size: 30 mm×30 mm, thickness: 1.17 mm), and the palladium electrode pads of the TEG chip and the electrode pads of the substrate were wire-bonded with a wire pitch of 80 μm using the copper wire 4N such that they were daisy-chain connected. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from TOWA Corporation) to produce a 352 pin BGA package. This package was subjected to post-curing treatment at 175° C. for 4 hours to give a semiconductor device.

### (4) Evaluation of Properties of Semiconductor Device

The properties of the produced semiconductor device were evaluated by the following methods. The results are shown in Table 7.

<High Temperature Storage Life>

While the resultant semiconductor device was stored under an environment of 200° C., the electrical resistance value between the wires was measured every 24 hours. The semiconductor device exhibiting the increase of the value by 20% compared to the initial value was determined as “defective,” and the time period taken to become defective (unit: hour) was measured. The measurements were made on the 5 semiconductor devices, and the shortest time period taken to become defective was recorded in Table 7. When no defects were generated in all of the semiconductor devices even after 192 hour storage, the result was recorded as “192<.”

<High Temperature Operating Life>

A DC current of 0.5 A was applied to both ends of the daisy-chain connected copper wires of the resultant semiconductor device. While the semiconductor device was stored as it is under an environment of 185° C., the electrical resistance value between the wires was measured every 12 hours. The semiconductor device exhibiting the increase of the value by 20% compared to the initial value was determined as “defective,” and the time period taken to become defective (unit: hour) was measured. The measurements were made on the 4 semiconductor devices, and the shortest time period taken to become defective was recorded in Table 7.

<Moisture Resistance Reliability>

For the resultant semiconductor device, the HAST (Highly Accelerated temperature and humidity Stress Test) was conducted in accordance with IEC 68-2-66. The test conditions were 130° C., 85% RH, applied voltage 20V, and 168 hour treatment. The presence or absence of open defect of the circuit for 4 terminals per semiconductor device was observed, and a total of 20 circuits from 5 semiconductor devices were observed to determine the number of defective circuits.

### Examples B2 to B4, and B10

Semiconductor devices were produced in the same manner as in Example B1, except that epoxy resin compositions for encapsulating members were prepared according to the formulations shown in Table 7. The properties of the resultant semiconductor devices were evaluated in the same manner as in Example B1. The results are shown in Table 7.

### Examples B5 to B6

Semiconductor devices were produced in the same manner as in Example B2, except that the copper wire 4N was replaced with the copper wire 5N or 5.5N. The properties of the resultant semiconductor devices were evaluated in the same manner as in Example B1. The results are shown in Table 7.

### Example B7

A semiconductor device was produced in the same manner as in Example B4, except that the copper wire 4N was replaced with the copper wire 5.5N. The properties of the resultant semiconductor device were evaluated in the same manner as in Example B1. The results are shown in Table 7.

### Examples B8 to B9

Semiconductor devices were produced in the same manner as in Example B5, except that epoxy resin compositions for encapsulating members were prepared according to the formulations shown in Table 7. The properties of the resultant semiconductor devices were evaluated in the same manner as in Example B1. The results are shown in Table 7.

### Comparative Example B1

A semiconductor device was produced in the same manner as in Example B2, except that the copper wire 4N was replaced with the copper wire 4NS. The properties of the resultant semiconductor device were evaluated in the same manner as in Example B1. The results are shown in Table 8.

### Comparative Examples B2 to B4

Semiconductor devices were produced in the same manner as in Examples B2, B5, and B10, respectively, except that the TEG chip provided with palladium electrode pads was replaced with a TEG (TEST ELEMENT GROUP) chip (3.5 mm×3.5 mm) provided with aluminum electrode pads. The properties of the resultant semiconductor devices were evaluated in the same manner as in Example B1. The results are shown in Table 8.

TABLE 7

| Examples | | | | | | | | | |
|---|---|---|---|---|---|---|---|---|---|
| B1 | B2 | B3 | B4 | B5 | B6 | B7 | B8 | B9 | B10 |

Epoxy Resin Compositions

| | | | | | | | | | | | |
|---|---|---|---|---|---|---|---|---|---|---|---|
| Formulation | [parts by mass] | | | | | | | | | | |
| EA-1 | | 2.92 | 2.92 | 2.92 | 2.92 | 2.92 | 2.92 | 2.92 | | 3.48 | 7.0 |
| EA-2 | | | | | | | | | 3.69 | | |
| EB-1 | | | | | | | | | | 1.58 | |
| EB-2 | | 2.92 | 2.92 | 2.92 | 2.92 | 2.92 | 2.92 | 2.92 | | | |
| EB-3 | | | | | | | | | | 3.48 | |
| HA-1 | | 2.48 | 2.48 | 2.48 | 2.48 | 2.48 | 2.48 | 2.48 | | 2.69 | 3.8 |
| HA-2 | | | | | | | | | 1.66 | | |
| HB-1 | | | | | | | | | 3.87 | 1.15 | |
| HB-2 | | 2.48 | 2.48 | 2.48 | 2.48 | 2.48 | 2.48 | 2.48 | | | |
| Fused spherical silica 1 | | 88 | 88 | 86.2 | 86.2 | 88 | 88 | 86.2 | 88 | 88 | 88 |
| Hydrotalcite 1 | | 0.2 | | | | | | | | | |
| Hydrotalcite 2 | | | 0.2 | | | 0.2 | 0.2 | | 0.2 | 0.2 | 0.2 |
| Calcium carbonate | | | | 2 | | | | | | | |
| Precipitated calcium carbonate | | | | | 2 | | | 2 | | | |
| TPP | | 0.3 | 0.3 | 0.3 | 0.3 | 0.3 | 0.3 | 0.3 | 0.3 | 0.3 | 0.3 |
| Epoxysilane | | 0.2 | 0.2 | 0.2 | 0.2 | 0.2 | 0.2 | 0.2 | 0.2 | 0.2 | 0.2 |
| Carbon black | | 0.3 | 0.3 | 0.3 | 0.3 | 0.3 | 0.3 | 0.3 | 0.3 | 0.3 | 0.3 |
| Carnauba wax | | 0.2 | 0.2 | 0.2 | 0.2 | 0.2 | 0.2 | 0.2 | 0.2 | 0.2 | 0.2 |
| Total | | 100 | 100 | 100 | 100 | 100 | 100 | 100 | 100 | 100 | 100 |
| Physical properties | | | | | | | | | | | |
| Spiral flow | [cm] | 200 | 200 | 180 | 180 | 200 | 200 | 180 | 220 | 170 | 180 |
| Moisture absorption ratio | [% by mass] | 0.14 | 0.14 | 0.16 | 0.16 | 0.14 | 0.14 | 0.16 | 0.16 | 0.15 | 0.18 |
| Linear expansion | [ppm/° C.] | 7 | 7 | 8 | 8 | 7 | 7 | 8 | 10 | 11 | 12 |
| coefficient α1 | | | | | | | | | | | |
| Glass transition temperature | [° C.] | 145 | 145 | 135 | 135 | 145 | 145 | 135 | 145 | 145 | 125 |
| Shrinkage ratio | [%] | 0.10 | 0.10 | 0.12 | 0.12 | 0.10 | 0.10 | 0.12 | 0.12 | 0.14 | 0.16 |

Wire

| Copper purity | | 4N | | | | 5N | 5.5N | | 5N | | 4N |
|---|---|---|---|---|---|---|---|---|---|---|---|
| Elemental sulfur content | [ppm by mass] | 3.8 | | | | 0.1 | 0.1 | | 0.1 | | 3.8 |
| Material of Electrode Pad of | | Pd | Pd | Pd | Pd | Pd | Pd | Pd | Pd | Pd | Pd |
| Semiconductor Element | | | | | | | | | | | |

Evaluation Results

| | | | | | | | | | | | |
|---|---|---|---|---|---|---|---|---|---|---|---|
| High temperature | [hr] | 168 | 168 | 144 | 144 | 192< | 192< | 168 | 192< | 192< | 120 |
| storage life (200° C.) | | | | | | | | | | | |
| High temperature | [hr] | 144 | 144 | 120 | 120 | 168 | 168 | 144 | 168 | 168 | 96 |
| operating life | | | | | | | | | | | |
| Moisture resistance reliability | [number of defectives] | 0 | 0 | 0 | 0 | 0 | 0 | 0 | 0 | 0 | 0 |

TABLE 8

| Comparative Examples | | | |
|---|---|---|---|
| B1 | B2 | B3 | B4 |

Epoxy Resin Compositions

| | | | | | |
|---|---|---|---|---|---|
| Formulation | [parts by mass] | | | | |
| EA-1 | | 2.92 | 2.92 | 2.92 | 7.0 |
| EA-2 | | | | | |
| EB-1 | | | | | |
| EB-2 | | 2.92 | 2.92 | 2.92 | |
| EB-3 | | | | | |
| HA-1 | | 2.48 | 2.48 | 2.48 | 3.8 |
| HA-2 | | | | | |
| HB-1 | | | | | |
| HB-2 | | 2.48 | 2.48 | 2.48 | |
| Fused spherical silica 1 | | 88 | 88 | 88 | 88 |
| Hydrotalcite 1 | | | | | |
| Hydrotalcite 2 | | 0.2 | 0.2 | 0.2 | 0.2 |
| Calcium carbonate | | | | | |
| Precipitated calcium carbonate | | | | | |
| TPP | | 0.3 | 0.3 | 0.3 | 0.3 |
| Epoxysilane | | 0.2 | 0.2 | 0.2 | 0.2 |
| Carbon black | | 0.3 | 0.3 | 0.3 | 0.3 |
| Carnauba wax | | 0.2 | 0.2 | 0.2 | 0.2 |
| Total | | 100 | 100 | 100 | 100 |
| Physical properties | | | | | |
| Spiral flow | [cm] | 200 | 200 | 200 | 180 |
| Moisture absorption ratio | [% by mass] | 0.14 | 0.14 | 0.14 | 0.18 |
| Linear expansion coefficient α1 | [ppm/° C.] | 7 | 7 | 7 | 12 |
| Glass transition temperature | [° C.] | 145 | 145 | 145 | 125 |
| Shrinkage ratio | [%] | 0.10 | 0.10 | 0.10 | 0.16 |

Wire

| | | | | | |
|---|---|---|---|---|---|
| Copper purity | | 4NS | 4N | 5N | 4N |
| Elemental sulfur content | [ppm by mass] | 7 | 3.8 | 0.1 | 3.8 |
| Material of Electrode Pad of Semiconductor Element | | Pd | Al | Al | Al |

Evaluation Results

| | | | | | |
|---|---|---|---|---|---|
| High temperature storage life (200° C.) | [hr] | 48 | 72 | 72 | 72 |
| High temperature operating life | [hr] | 36 | 48 | 72 | 48 |
| Moisture resistance reliability | [number of defectives] | 6 | 15 | 10 | 16 |

As apparent from the results shown in Tables 7 to 8, when the palladium electrode pads of each of the semiconductor elements were wire-bonded by use of the copper wires having an elemental sulfur content of 5 ppm by mass or less (Examples B1 to B10), the resultant semiconductor devices had the excellent high temperature storage life, high temperature operating life, and moisture resistance reliability. On the other hand, when the palladium electrode pads of the semiconductor element were wire-bonded by use of the copper wire having an elemental sulfur content of 13 ppm by mass or less (Comparative Examples B1), the resultant semiconductor device was inferior in all of the high temperature storage life, high temperature operating life, and moisture resistance reliability. In addition, even when the aluminum electrode pads of each of the semiconductor elements were wire-bonded by use of the copper wires having an elemental sulfur content of 5 ppm by mass or less (Comparative Examples B2 to B4), the resultant semiconductor devices were inferior in all of the high temperature storage life, high temperature operating life, and moisture resistance reliability. In other words, it was confirmed that only when the palladium electrode pad of a semiconductor element were wire-bonded by a copper wire having a high copper purity and low elemental sulfur content as in the present invention, the excellent high temperature storage life, high temperature operating life and moisture resistance reliability could be achieved.

Comparing Comparative Examples B2 with B3, in the case of using the aluminum electrode pads as the electrode pads of each of the semiconductor elements, the higher the copper purity of the copper wire was, the better the high temperature operating life was, but there was no change in the high temperature storage life. On the other hand, comparing Examples B2 with B5 to B6, and B4 with B7, in the case of using palladium electrode pads as the electrode pads of each of the semiconductor elements, the higher the copper purity of the copper wire was, the better the high temperature operating life and high temperature storage life were. In other words, it was confirmed that the effect of rise in a copper purity of the copper wire was especially profound in the case of using a palladium electrode pad as the electrode pad of a semiconductor element.

Moreover, comparing Comparative Examples B2 with B4, in the case of using aluminum electrode pads as the electrode pads of each semiconductor element, even when the types of the epoxy resin and curing agent were changed, any of the high temperature storage life, high temperature operating life, and moisture resistance reliability did not change. On the other hand, in the case of using palladium electrode pads as the electrode pads of each semiconductor element, when the epoxy resins represented by the formulas (6), (9), or (10), and the curing agents represented by the formula (7) were contained (Examples B1 to B9), the high temperature storage life, high temperature operating life, and moisture resistance reliability were improved compared with the case in which the epoxy resins and the curing agents described above were not contained (Example B10). In other words, it was confirmed that the effect of the epoxy resins represented by the formulas (6), (9), or (10), and the curing agents represented by the formula (7) was especially profound in the case of using palladium electrode pads as the electrode pads of each semiconductor element.

Next, the third semiconductor device of the present invention will be described based on Examples C1 to C11 and Comparative Examples C1 to C11. Components of the epoxy resin compositions used herein are described below.

<Epoxy Resins>

E-1: Biphenyl type epoxy resin (“YX-4000” available from Japan Epoxy Resins Co., Ltd., melting point 105° C., epoxy equivalent 190)

E-2: Triphenol type epoxy resin (“1032H60” available from Japan Epoxy Resins Co., Ltd., softening point 59° C., epoxy equivalent 171)

E-3: Polyfunctional epoxy resin having a naphthalene skeleton (“HP4770” available from available from DIC Corporation, melting point 72° C., epoxy equivalent 205)

<Curing Agents>

H-1: Phenol novolac resin (“PR-HF-3” available from Sumitomo Bakelite Co., Ltd., softening point 80° C., hydroxyl equivalent 104)

H-2: Phenol aralkyl resin having a biphenylene skeleton (“MEH-7851SS” from Meiwa Plastic Industries, Ltd., softening point 65° C., hydroxyl equivalent 203)

H-3: Phenol aralkyl resin having a phenylene skeleton (“MEH-7800SS” from Meiwa Plastic Industries, Ltd., softening point 65° C., hydroxyl equivalent 175)

<Fillers>

Fused spherical silica 1: mode diameter 45 μm, specific surface area 2.2 m²/g, content ratio of coarse particles having a diameter of 55 μm or more: 0.1 parts by mass (obtained by sieving “FB-820” from Denki Kagaku Kogyo K.K. using a 300 mesh sieve to remove the coarse particles)

Fused spherical silica 2: average particle size 0.5 μm (“SO-25R” available from Admatechs Co., Ltd.)

<Curing Accelerators>

Curing accelerator 1: Triphenylphosphine (TPP, “PP360” available from K.I Chemical Industry Co., Ltd.)

Curing accelerator 2: Adduct of triphenylphosphine (TPP, “PP360” available from K.I Chemical Industry Co., Ltd.) with 1,4-benzoquinone

In addition to the components described above, epoxysilane (γ-glycidoxypropyltrimethoxysilane) as a coupling agent, carbon black as a coloring agent, and carnauba wax as a mold release agent were used.

Furthermore, the copper wires used in Examples C1 to C11 and Comparative Examples C1 to C11 are described below.

<Copper Wires>

4NC: “TPCW” available from Tanaka Denshi Kogyo K.K., copper purity 99.99% by mass, elemental sulfur content 4.0 ppm by mass, elemental chlorine content 2.0 ppm, wire diameter 25 μm

4NS: “MAXSOFT” available from Kulicke & Soffa Industries, Inc., copper purity 99.99% by mass, elemental sulfur content 7.0 ppm by mass, elemental chlorine content 0.01 ppm, wire diameter 25 μm

4N: “TC-E” available from Tatsuta Electric Wire & Cable Co., Ltd., copper purity 99.99% by mass, elemental sulfur content 3.8 ppm by mass, elemental chlorine content 0.12 ppm, wire diameter 25 μm

5N: “TC-A” available from Tatsuta Electric Wire & Cable Co., Ltd., copper purity 99.999% by mass, elemental sulfur content 0.1 ppm by mass, elemental chlorine content 0.08 ppm, wire diameter 25 μm

5.5N: “TC-A5.5” available from Tatsuta Electric Wire & Cable Co., Ltd., copper purity 99.9995% by mass, elemental sulfur content 0.1 ppm by mass, elemental chlorine content 0.005 ppm, wire diameter 25 μm

### Example C1

### (1) Production of Epoxy Resin Composition for Encapsulating Member

The epoxy resin E-1 (3.44 parts by mass) and the epoxy resin E-3 (3.44 parts by mass), the curing agent H-1 (3.62 parts by mass), the fused spherical silica 1 (78.5 parts by mass) and the fused spherical silica 2 (10.0 parts by mass) as fillers, triphenylphosphine (TPP) (0.3 parts by mass) as a curing accelerator, epoxysilane (0.2 parts by mass) as a coupling agent, carbon black (0.3 parts by mass) as a coloring agent, and carnauba wax (0.2 part by mass) as a mold release agent were mixed at ordinary temperature using a mixer and then roll-milled at 70 to 100° C. After cooling, the resultant was pulverized to give an epoxy resin composition for an encapsulating member.

### (2) Measurement of Physical Properties of Epoxy Resin Composition

The physical properties of the resultant epoxy resin composition were measured by the following methods. The results are shown in Table 9.

<Glass Transition Temperature>

The epoxy resin composition was injected under the conditions of a mold temperature of 175° C., an injection pressure of 9.8 MPa, and a curing time of 180 seconds using a low-pressure transfer molding machine (“KTS-30” available from Kohtaki Precision Machine Co., Ltd.) to mold a test piece with 10 mm×4 mm×4 mm, and then the test piece was heated at 175° C. for 8 hours and subjected to post-curing treatment. The TMA analysis was performed on the resultant test piece at a rate of temperature rise of 5° C./min using a “TMA-100” which available from Seiko Instruments Inc. The temperature of the intersection of the tangents to the resultant TMA curve for 60° C. and 240° C. was read off and this temperature was used as the glass transition temperature (unit: ° C.).

<Linear Expansion Coefficient α1>

The epoxy resin composition was injected and molded under the conditions of a mold temperature of 175° C., an injection pressure of 7.4 MPa, and a curing time of 2 minutes using a low-pressure transfer molding machine (“KTS-30” available from Kohtaki Precision Machine Co., Ltd.) to produce a test piece having a length of 15 mm, a width of 5 mm, and a thickness of 3 mm, and then the test piece was subjected to post-curing treatment at 175° C. for 8 hours. The TMA analysis was performed on the resultant test piece at a rate of temperature rise of 5° C./min using a thermomechanical analyzer (“TMA-120” available from Seiko Instruments & Electronics Ltd.). The average linear expansion coefficient al (unit: ppm/° C.) in the temperature range from 25° C. to a temperature of 10° C. below the glass transition temperature of the resultant TMA curve was calculated.

### (3) Evaluation of Pad Damage

A TEG (TEST ELEMENT GROUP) chip (3.5 mm×3.5 mm) provided with aluminum electrode pads having a thickness of 1.5 μm was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and terminals of a substrate (electrical joints) were wire-bonded with a wire pitch of 50 μm using the 5N copper wire such that the pads and the terminals were daisy-chain connected. Next, after withdrawing the wires at the side of the aluminum electrode pads of the TEG chip, the surface of the electrode pads of the TEG chip was observed. The case that the chip under the electrode pads was exposed were determined as “there was pad damage,” and the case that the ball remained or the chip under the electrode pads was not exposed was determined as “there was no pad damage.” The results are shown in Table 9.

### (4) Production of Semiconductor Device

A TEG (TEST ELEMENT GROUP) chip (3.5 mm×3.5 mm) provided with aluminum electrode pads having a thickness of 1.5 μm was bonded to a die pad portion of a 352 pin BGA (substrate: bismaleimide triazine resin/glass cloth substrate having a thickness of 0.56 mm, package size: 30 mm×30 mm, thickness: 1.17 mm), and the aluminum electrode pads of the TEG chip and terminals of a substrate (electrical joints) were wire-bonded with a wire pitch of 50 μm using the 5N copper wire such that the pads and the terminals were daisy-chain connected. The resultant was encapsulated by the epoxy resin composition and molding was performed under the conditions of a mold temperature of 175° C., an injection pressure of 6.9 MPa, and a curing time of 2 minutes using a low-pressure transfer molding machine (“Y Series” available from TOWA Corporation) to produce a 352 pin BGA package. This package was subjected to post-curing treatment at 175° C. for 4 hours to give a semiconductor device.

### (5) Evaluation of Properties of Semiconductor Device

The properties of the produced semiconductor device were evaluated with the following methods. The results are shown in Table 9.

<Temperature Cycle Property>

The resultant semiconductor device was stored at −60° C. for 30 minutes and then at 150° C. for 30 minutes, this treatment was repeated, and the presence or absence of the external cracking was observed. The repeat number (unit: cycle) of the occurrence of the external cracking (defect) of 50% or more of the resultant semiconductor devices was counted. When no defects were generated even after the temperature cycle test was conducted in 500 cycles, the result was recorded as “500<.”

<High Temperature Storage Life>

While the resultant semiconductor device was stored under an environment of 200° C., the electrical resistance value between the wires was measured every 24 hours. The semiconductor device exhibiting the increase of the value by 20% compared to the initial value was determined as “defective,” and the time period taken to become defective (unit: hour) was measured. The measurements were made on the 5 semiconductor devices, and the shortest time period taken to become defective was recorded in Table 9. When no defects were generated in all of the semiconductor devices even after 192 hour storage, the result was recorded as “192<.”

<High Temperature Operating Life>

A DC current of 0.5 A was applied to both ends of the daisy-chain connected copper wires of the resultant semiconductor device. While the semiconductor device was stored as it is under an environment of 185° C., the electrical resistance value between the wires was measured every 12 hours. The semiconductor device exhibiting the increase of the value by 20% compared to the initial value was determined as “defective,” and the time period taken to become defective (unit: hour) was measured. The measurements were made on the 4 semiconductor devices, and the shortest time period taken to become defective was recorded in Table 9.

<Moisture Resistance Reliability>

For the resultant semiconductor device, the HAST (Highly Accelerated temperature and humidity Stress Test) was conducted in accordance with IEC 68-2-66. The test conditions were 130° C., 85% RH, applied voltage 20V, and 168 hour treatment. The presence or absence of open defect of the circuit for 4 terminals per semiconductor device was observed, and a total of 20 circuits from 5 semiconductor devices were observed to determine the number of defective circuits.

### Examples C2 to C5

Semiconductor devices were produced in the same manner as in Example C1, except that epoxy resin compositions for encapsulating members were prepared according to the formulations shown in Table 9. The properties of the resultant semiconductor devices were evaluated in the same manner as in Example C1. The results are shown in Table 9.

### Example C6

The pad damage was evaluated and a semiconductor device was produced in the same manner as in Example C1, except that the copper wire 5N were replaced with the copper wire 5.5N. The properties of the resultant semiconductor device were evaluated in the same manner as in Example C1. The results are shown in Table 9.

### Example C7

The pad damage was evaluated and a semiconductor device was produced in the same manner as in Example C1, except that the TEG chip provided with aluminum electrode pads having a thickness of 1.5 μm was replaced with a TEG (TEST ELEMENT GROUP) chip (3.5 mm×3.5 mm) provided with aluminum electrode pads having a thickness of 1.2 μm. The properties of the resultant semiconductor device were evaluated in the same manner as in Example C1. The results are shown in Table 9.

### Example C8

The pad damage was evaluated and a semiconductor device was produced in the same manner as in Example C1, except that the TEG chip provided with aluminum electrode pads having a thickness of 1.5 μm was replaced with a TEG (TEST ELEMENT GROUP) chip (3.5 mm×3.5 mm) provided with aluminum electrode pads having a thickness of 2.0 μm. The properties of the resultant semiconductor device were evaluated in the same manner as in Example C1. The results are shown in Table 9.

### Comparative Example C1

The pad damage was evaluated and a semiconductor device was produced in the same manner as in Example C1, except that the TEG chip provided with aluminum electrode pads having a thickness of 1.5 μm was replaced with a TEG (TEST ELEMENT GROUP) chip (3.5 mm×3.5 mm) provided with aluminum electrode pads having a thickness of 1.0 μm. The properties of the resultant semiconductor device were evaluated in the same manner as in Example C1. The results are shown in Table 10.

### Comparative Examples C2 to C4

The pad damage was evaluated and semiconductor devices were produced in the same manner as in Example C1, except that the copper wire 5N were replaced with the copper wire 4NC, 4NS, or 4N. The properties of the resultant semiconductor devices were evaluated in the same manner as in Example C1. The results are shown in Table 10.

### Comparative Examples C5 to C7

Semiconductor devices were produced in the same manner as in Example C1, except that epoxy resin compositions for encapsulating members were prepared according to the formulations shown in Table 2. The properties of the resultant semiconductor devices were evaluated in the same manner as in Example C1. The results are shown in Table 10.

TABLE 9

| Examples | | | | | | | |
|---|---|---|---|---|---|---|---|
| C1 | C2 | C3 | C4 | C5 | C6 | C7 | C8 |

Epoxy Resin Compositions

| Formulation | [parts by mass] | | | | | | | | |
|---|---|---|---|---|---|---|---|---|---|
| E-1 | | 3.44 | 3.60 | | | 4.94 | 3.44 | 3.44 | 3.44 |
| E-2 | | | | 5.82 | 5.29 | | | | |
| E-3 | | 3.44 | 3.60 | | | | 3.44 | 3.44 | 3.44 |
| H-1 | | 3.62 | 3.80 | 2.34 | 2.11 | | 3.62 | 3.62 | 3.62 |
| H-2 | | | | 2.34 | 2.11 | | | | |
| H-3 | | | | | | 4.51 | | | |
| Fused spherical silica 1 | | 78.5 | 78.0 | 78.5 | 79.5 | 79.4 | 78.5 | 78.5 | 78.5 |
| Fused spherical silica 2 | | 10.0 | 10.0 | 10.0 | 10.0 | 10.0 | 10.0 | 10.0 | 10.0 |
| TPP | | 0.3 | 0.3 | 0.3 | 0.3 | | 0.3 | 0.3 | 0.3 |
| Adduct of TPP with | | | | | | 0.4 | | | |
| 1,4-benzoquinone | | | | | | | | | |
| Epoxysilane | | 0.2 | 0.2 | 0.2 | 0.2 | 0.2 | 0.2 | 0.2 | 0.2 |
| Carbon black | | 0.3 | 0.3 | 0.3 | 0.3 | 0.3 | 0.3 | 0.3 | 0.3 |
| Carnauba wax | | 0.2 | 0.2 | 0.2 | 0.2 | 0.2 | 0.2 | 0.2 | 0.2 |
| Total | | 100 | 100 | 100 | 100 | 100 | 100 | 100 | 100 |
| Content ratio of spherical silica | [%] | 88.5 | 88.0 | 88.5 | 89.5 | 89.4 | 88.5 | 88.5 | 88.5 |
| Physical properties | | | | | | | | | |
| Glass transition temperature | [° C.] | 140 | 135 | 185 | 190 | 135 | 140 | 140 | 140 |
| Linear expansion coefficient α1 | [ppm/° C.] | 9 | 9 | 6 | 5 | 7 | 9 | 9 | 9 |

Wire

| | | | | |
|---|---|---|---|---|
| Kind of copper wire | | 5N | 5.5N | 5N |
| Elemental sulfur content | [ppm by mass] | 0.1 | 0.1 | 0.1 |
| Elemental chlorine content | [ppm by mass] | 0.08 | 0.005 | 0.08 |

| | | | | |
|---|---|---|---|---|
| Thickness of Electrode Pad of | [μm] | 1.5 | 1.2 | 2.0 |
| Semiconductor Element | | | | |

Evaluation Result

| | | | | | | | | | |
|---|---|---|---|---|---|---|---|---|---|
| Pad damage | | Absent | Absent | Absent | Absent | Absent | Absent | Absent | Absent |
| Temperature cycle property | [cycles] | 500< | 480 | 500< | 500< | 500< | 500< | 500< | 500< |
| High temperature storage life | [hr] | 192< | 144 | 192< | 192< | 144 | 144 | 192< | 144 |
| (200° C.) | | | | | | | | | |
| High temperature operating life | [hr] | 168 | 96 | 168 | 168 | 96 | 120 | 168 | 96 |
| Moisture resistance reliability | [number of defectives] | 0 | 2 | 0 | 0 | 0 | 0 | 0 | 0 |

TABLE 10

| Comparative Examples | | | | | | |
|---|---|---|---|---|---|---|
| C1 | C2 | C3 | C4 | C5 | C6 | C7 |

Epoxy Resin Compositions

| Formulation | [parts by mass] | | | | | | | |
|---|---|---|---|---|---|---|---|---|
| E-1 | | 3.44 | 3.44 | 3.44 | 3.44 | | 4.57 | |
| E-2 | | | | | | 6.20 | | 4.18 |
| E-3 | | 3.44 | 3.44 | 3.44 | 3.44 | | | |
| H-1 | | 3.62 | 3.62 | 3.62 | 3.62 | 3.01 | | 1.67 |
| H-2 | | | | | | | 4.88 | 1.67 |
| H-3 | | | | | | 1.29 | | |
| Fused spherical silica 1 | | 78.5 | 78.5 | 78.5 | 78.5 | 78.5 | 79.4 | 81.0 |
| Fused spherical silica 2 | | 10.0 | 10.0 | 10.0 | 10.0 | 10.0 | 10.0 | 10.0 |
| TPP | | 0.3 | 0.3 | 0.3 | 0.3 | 0.3 | | 0.3 |
| Adduct of TPP with 1,4-benzoquinone | | | | | | | 0.4 | |
| Epoxysilane | | 0.2 | 0.2 | 0.2 | 0.2 | 0.2 | 0.2 | 0.2 |
| Carbon black | | 0.3 | 0.3 | 0.3 | 0.3 | 0.3 | 0.3 | 0.3 |
| Carnauba wax | | 0.2 | 0.2 | 0.2 | 0.2 | 0.2 | 0.2 | 0.2 |
| Total | | 100 | 100 | 100 | 100 | 100 | 100 | 100 |
| Content ratio of spherical silica | [%] | 88.5 | 88.5 | 88.5 | 88.5 | 88.5 | 89.4 | 91.4 |
| Physical properties | | | | | | | | |
| Glass transition temperature | [° C.] | 140 | 140 | 140 | 140 | 195 | 125 | 190 |
| Linear expansion coefficient α1 | [ppm/° C.] | 9 | 9 | 9 | 9 | 7 | 8 | 4 |

Wire

| Kind of copper wire | | 5N | 4NC | 4NS | 4N | 5N |
|---|---|---|---|---|---|---|
| Elemental sulfur content | [ppm by mass] | 0.1 | 4.0 | 7.0 | 3.8 | 0.1 |
| Elemental chlorine content | [ppm by mass] | 0.08 | 2.0 | 0.01 | 0.12 | 0.08 |

| | | | |
|---|---|---|---|
| Thickness of Electrode Pad of | [μm] | 1.0 | 1.5 |
| Semiconductor Element | | | |

Evaluation Result

| | | | | | | | | |
|---|---|---|---|---|---|---|---|---|
| Pad damage | | Present | Absent | Present | Absent | Absent | Absent | Absent |
| Temperature cycle property | [cycles] | 500< | 500< | 500< | 500< | 500< | 96 | 500< |
| High temperature storage life | (200° C.) [hr] | 72 | 72 | 48 | 144 | 144 | 72 | 48 |
| High temperature operating life | [hr] | 48 | 72 | 36 | 48 | 48 | 48 | 24 |
| Moisture resistance reliability | [number of defectives] | 15 | 15 | 15 | 12 | 15 | 2 | 7 |

As apparent from the results shown in Tables 9 to 10, in the case of wire bonding of the aluminum electrode pads with a thickness of 1.2 μm or more provided on each of the semiconductor elements by use of the copper wires with a copper purity of 99.999% by mass or more, an elemental sulfur content of 5 ppm by mass or less, and an elemental chlorine content of 0.1 ppm or less (Examples C1 to C8), the electrode pads of the semiconductor elements were not damaged and the resultant semiconductor devices had the excellent temperature cycle property, high temperature storage life, high temperature operating life, and moisture resistance reliability.

On the other hand, in the case of wire bonding of the electrode pads with a thickness of 1.0 μm provided on each of the semiconductor elements (Comparative Example C1), and the case of wire bonding of the electrode pads with a thickness of 1.5 μm provided on each semiconductor element by use of the copper wires with an elemental sulfur content of 7 ppm by mass (Comparative Example C3), the electrode pads of each semiconductor element were damaged, and the resultant semiconductor devices were inferior in the high temperature storage life, high temperature operating life, and moisture resistance reliability. In the case of wire bonding by use of the copper wires with an elemental chlorine content of 2 ppm by mass (Comparative Example C2), the electrode pads of the semiconductor element were not damaged, but the resultant semiconductor devices were inferior in the high temperature storage life, high temperature operating life, and moisture resistance reliability. In the case of wire bonding by use of the copper wires with a copper purity of 99.99% by mass (Comparative Example C4), the electrode pads of the semiconductor element were not damaged and the resultant semiconductor device had the excellent temperature cycle property and high temperature storage life, but it was inferior in the high temperature operating life and moisture resistance reliability. And in the case of encapsulating by use of the encapsulating member with a glass transition temperature of 195° C. (Comparative Example C5), the resultant semiconductor device was inferior in the high temperature operating life and moisture resistance reliability, while in the case of encapsulating by use of the encapsulating member with a glass transition temperature of 125° C. (Comparative Example C6), the resultant semiconductor device was inferior in the temperature cycle property, high temperature storage life, and high temperature operating life. In the case of using the encapsulating member with a linear expansion coefficient al of 4 ppm/° C. (Comparative Example C7), the resultant semiconductor device was inferior in the high temperature storage life, high temperature operating life, and moisture resistance reliability.

### Examples C9 to C11

The pad damage was evaluated and semiconductor devices were produced in the same manner as in Examples C1, C5, and C6, respectively, except that the TEG chip provided with the aluminum electrode pads was replaced with a JTEG Phase 10 chip (5.02 mm×5.02 mm) provided with aluminum electrode pads having a thickness of 1.5 μm and a low-K interlayer insulating film. The temperature cycle property of the resultant semiconductors were evaluated in the same manner as in Example C1. After the temperature cycle test, the semiconductor devices were cut using a cross-section polisher, and the presence or absence of cracking of the low-K interlayer insulating film was observed. The results are shown in Table 11.

### Comparative Examples C8 to C11

The pad damage was evaluated and semiconductor devices were produced in the same manner as in Comparative Examples C3 to C6, respectively, except that the TEG chip provided with the aluminum electrode pads was replaced with a JTEG Phase 10 chip (5.02 mm×5.02 mm) provided with aluminum electrode pads having a thickness of 1.5 μm and the low-K interlayer insulating film. The temperature cycle property of the resultant semiconductors were evaluated in the same manse as in Example C1. After the temperature cycle test, the semiconductor devices were cut using a cross-section polisher, and the presence or absence of cracking of the low-K interlayer insulating film was observed. The results are shown in Table 11.

TABLE 11

| Examples | | | Comparative Examples | | | |
|---|---|---|---|---|---|---|
| C9 | C10 | C11 | C8 | C9 | C10 | C11 |

Epoxy Resin Compositions

| Formulation | [parts by mass] | | | | | | | |
|---|---|---|---|---|---|---|---|---|
| E-1 | | 3.44 | 4.94 | 3.44 | 3.44 | 3.44 | | 4.57 |
| E-2 | | | | | | | 6.20 | |
| E-3 | | 3.44 | | 3.44 | 3.44 | 3.44 | | |
| H-1 | | 3.62 | | 3.62 | 3.62 | 3.62 | 3.01 | |
| H-2 | | | | | | | | 4.88 |
| H-3 | | | 4.51 | | | | 1.29 | |
| Fused spherical silica 1 | | 78.5 | 79.4 | 78.5 | 78.5 | 78.5 | 78.5 | 79.4 |
| Fused spherical silica 2 | | 10.0 | 10.0 | 10.0 | 10.0 | 10.0 | 10.0 | 10.0 |
| TPP | | 0.3 | | 0.3 | 0.3 | 0.3 | 0.3 | |
| Adduct of TPP with 1,4-benzoquinone | | | 0.4 | | | | | 0.4 |
| Epoxysilane | | 0.2 | 0.2 | 0.2 | 0.2 | 0.2 | 0.2 | 0.2 |
| Carbon black | | 0.3 | 0.3 | 0.3 | 0.3 | 0.3 | 0.3 | 0.3 |
| Carnauba wax | | 0.2 | 0.2 | 0.2 | 0.2 | 0.2 | 0.2 | 0.2 |
| Total | | 100 | 100 | 100 | 100 | 100 | 100 | 100 |
| Content ratio of spherical silica | [%] | 88.5 | 89.4 | 88.5 | 88.5 | 88.5 | 88.5 | 89.4 |
| Physical properties | | | | | | | | |
| Glass transition temperature | [° C.] | 140 | 135 | 140 | 140 | 140 | 195 | 125 |
| Linear expansion coefficient α1 | [ppm/° C.] | 9 | 7 | 9 | 9 | 9 | 7 | 8 |

Wire

| | | | | | | |
|---|---|---|---|---|---|---|
| Kind of copper wire | | 5N | 5.5N | 4NS | 4N | 5N |
| Elemental sulfur content | [ppm by mass] | 0.1 | 0.1 | 7.0 | 3.8 | 0.1 |
| Elemental chlorine content | [ppm by mass] | 0.08 | 0.005 | 0.01 | 0.12 | 0.08 |

| | | | |
|---|---|---|---|
| Thickness of Electrode Pad of | [μm] | 1.5 | 1.5 |
| Semiconductor Element | | | |

Evaluation Result

| | | | | | | | | |
|---|---|---|---|---|---|---|---|---|
| Pad damage | | Absent | Absent | Absent | Present | Present | Absent | Absent |
| Temperature cycle property | [cycles] | 500< | 500< | 500< | 500< | 500< | 500< | 20 |
| Damage of low-K layer | | Absent | Absent | Absent | Present | Present | Present | Present |

As apparent from the results shown in Table 11, even when the aluminum electrode pads having a thickness of 1.2 μm or more provided on each semiconductor element including the low-K interlayer insulating film were wire-bonded by use of the copper wire having a copper purity of 99.999% by mass or more, an elemental sulfur content of 5 ppm by mass or less, and an elemental chlorine content of 0.1 ppm or less (Example C9 to C11), the low-K interlayer insulating film were not damaged.

On the other hand, the damage of the low-K interlayer insulating film was observed in all of the following cases: the cases where the electrode pad having a thickness of 1.5 μm provided on each semiconductor element including the low-K interlayer insulating film were wire-bonded by use of the copper wire having an elemental sulfur content of 7 ppm by mass (Comparative Example C8), and by use of the copper wire having a copper purity of 99.99% by mass (Comparative Example C9); the cases of encapsulating by use of the encapsulating member having a glass transition temperature of 195° C. (Comparative Example 10), and by use of the encapsulating member having a glass transition temperature of 125° C. (Comparative Example 11).

As described above, according to the present invention, there can be obtained a semiconductor device in which a copper wire that electrically connects a circuit board to an electrode pad of a semiconductor element is difficult to exhibit migration, and which has excellent moisture resistance reliability and high temperature storage life. Thus, the first semiconductor device of the present invention is useful for industrial resin encapsulated semiconductor devices, especially single-sided and resin encapsulated semiconductor devices for surface mounting and the like.

Furthermore, according to the present invention, the junction between the electrode pad of the semiconductor element and the copper wire becomes difficult to corrode, the copper wire connecting electrical joints provided on a lead frame or circuit board to the electrode pad provided on the semiconductor element. Thus, since the second semiconductor device of the present invention has excellent high temperature storage life, high temperature operating life, and moisture resistance reliability, it is useful for industrial resin encapsulated semiconductor devices, especially resin encapsulated semiconductor devices used under a high temperature environment and a high temperature and high humidity environment such as the automotive applications, and the like.

Moreover, according to the present invention, there can be obtained a semiconductor device in which no electrode pad provided on the semiconductor element are damaged and which has excellent temperature cycle property, high temperature storage life, high temperature operating life, and moisture resistance reliability. Thus, since the third semiconductor device of the present invention is excellent in the properties described above, even when the semiconductor element is provided with the electrode pad having a thickness of 1.2 μm or more, it is useful for industrial resin encapsulated semiconductor devices, especially semiconductor devices using the semiconductor element provided with a low dielectric insulating film.

1. A semiconductor device comprising:
any one of a lead frame having a die pad portion and a circuit board;
one or more semiconductor elements mounted on any one of the die pad portion of the lead frame and the circuit board;
a copper wire that electrically connects electrical joints provided on any one of the lead frame and the circuit board to an electrode pad provided on the semiconductor element; and
an encapsulating member which encapsulates the semiconductor element and the copper wire, wherein
the electrode pad provided on the semiconductor element is formed from palladium, and
the copper wire has a copper purity of 99.99% by mass or more and an elemental sulfur content of 5 ppm by mass or less.

2. The semiconductor device according to claim 1, wherein the encapsulating member is a cured product of an epoxy resin composition.

3. The semiconductor device according to claim 2, wherein the epoxy resin composition comprises at least one corrosion inhibitor selected from the group consisting of compounds containing an elemental calcium and compounds containing an elemental magnesium in a ratio of not less than 0.01% by mass and not more than 2% by mass.

4. The semiconductor device according to claim 3, wherein the epoxy resin composition comprises calcium carbonate in a ratio of not less than 0.05% by mass and not more than 2% by mass.

5. The semiconductor device according to claim 4, wherein the calcium carbonate is precipitated calcium carbonate synthesized by a carbon dioxide gas reaction method.

6. The semiconductor device according to claim 2, wherein the epoxy resin composition comprises hydrotalcite in a ratio of not less than 0.05% by mass and not more than 2% by mass.

7. The semiconductor device according to claim 6, wherein the hydrotalcite is a compound represented by the following formula (8):
M_{α}Al_{β}(OH)_{2α+3β-2γ}(CO₃)_{γ}·δH₂O (8)
wherein, in the formula (8), M represents a metallic element comprising at least Mg, α, β and γ are numbers meeting conditions of 2≦α≦8, 1≦β≦3, and 0.5≦γ≦2, respectively, and δ is an integer of 0 or more.

8. The semiconductor device according to claim 6, wherein a mass loss ratio A (% by mass) at 250° C. and a mass loss ratio B (% by mass) at 200° C. of the hydrotalcite, which are measured by a thermogravimetric analysis, meet a condition represented by the following formula (I):
A−B5% by mass (I).

9. The semiconductor device according to claim 2, wherein the epoxy resin composition comprises at least one epoxy resin selected from the group consisting of
epoxy resins represented by the following formula (6): 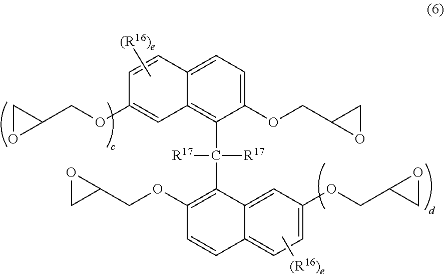
wherein, in the formula (6), R¹⁶ represents any one of a hydrogen atom and a hydrocarbon group having 1 to 4 carbon atoms, and may be the same or different when there are a plurality of R¹⁶, R¹⁷'s each independently represent any one of a hydrogen atom and a hydrocarbon group having 1 to 4 carbon atoms, c and d are each independently 0 or 1, and e is an integer of from 0 to 6,
epoxy resins represented by the following formula (9): 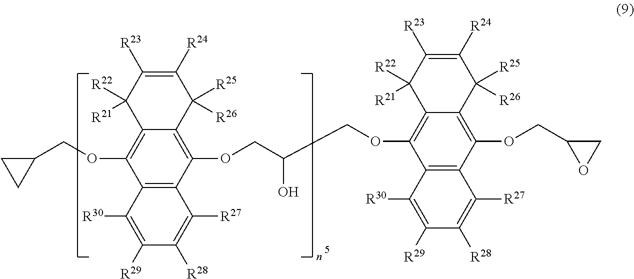
wherein, in the formula (9), R²¹ to R³⁰ each independently represent any one of a hydrogen atom and an alkyl group having 1 to 6 carbon atoms, and n⁵ is an integer of from 0 to 5,
epoxy resins represented by the following formula (10): 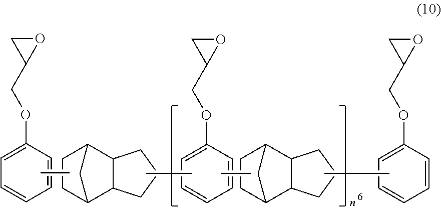
wherein, in the formula (10), an average value of n⁶ is a positive number of from 0 to 4, and
epoxy resins represented by the following formula (5): 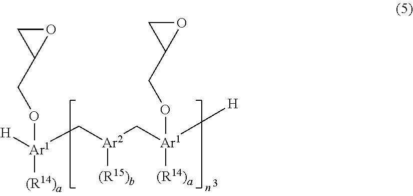
wherein, in the formula (5), Ar¹ represents any one of a phenylene group and a naphthylene group, each binding position of the glycidyl ether groups may be any one of α-position and β-position when Ar¹ is the naphthylene group, Ar² represents any one of a phenylene group, a biphenylene group, and a naphthylene group, R¹⁴ and R¹⁵ each independently represent a hydrocarbon group having 1 to 10 carbon atoms, a is an integer of from 0 to 5, b is an integer of from 0 to 8, and an average value of n³ is a positive number between 1 and 3 both inclusive.

10. The semiconductor device according to claim 2, wherein the epoxy resin composition comprises at least one curing agent selected from the group consisting of phenol resins represented by the following formula (7): 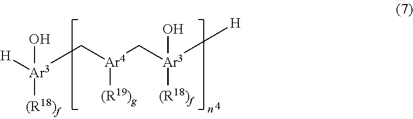
wherein, in the formula (7), Ar³ represents any one of a phenylene group and a naphthylene group, each binding position of the hydroxyl groups may be any one of α-position and β-position when Ar³ is the naphthylene group, Ar⁴ represents any one of a phenylene group, a biphenylene group, and a naphthylene group, R¹⁸ and R¹⁹ each independently represent a hydrocarbon group having 1 to 10 carbon atoms, f is an integer of from 0 to 5, g is an integer of from 0 to 8, and an average value of n⁴ is a positive number between 1 and 3 both inclusive.

11. The semiconductor device according to claim 2, wherein the cured product of the epoxy resin composition has a glass transition temperature between 135° C. and 175° C. both inclusive.

12. The semiconductor device according to claim 2, wherein the cured product of the epoxy resin composition has a linear expansion coefficient between 7 ppm/° C. and 11 ppm/° C. both inclusive in a temperature range not exceeding the glass transition temperature thereof.
